(19) United States
(12) Patent Application Publication
(10) Pub. No.: US 2023/0135917 A1
(43) Pub. Date: May 4, 2023

(54) LIGHT-EMITTING DEVICE AND METHOD OF MANUFACTURING THE SAME

(71) Applicant: Samsung Display Co., Ltd., Yongin-si (KR)

(72) Inventors: Sehun Kim, Yongin-si (KR); Changhee Lee, Yongin-si (KR); Jaekook Ha, Yongin-si (KR); Jingoo Kang, Yongin-si (KR); Youngmo Koo, Yongin-si (KR); Youngil Kim, Yongin-si (KR); Jiyoon Kim, Yongin-si (KR)

(21) Appl. No.: 17/903,956

(22) Filed: Sep. 6, 2022

(30) Foreign Application Priority Data
Sep. 28, 2021 (KR) 10-2021-0128342

(51) Int. Cl. H01L 51/50; H01L 51/56; H01L 51/00

(52) U.S. Cl. CPC H01L 51/5056; H01L 51/5072; H01L 51/56; H01L 51/006; H01L 51/0072

(57) ABSTRACT

A light-emitting device includes: a substrate; a cathode on the substrate; an anode on the cathode; and an organic layer arranged between the cathode and the anode and including an emission layer. The organic layer includes: an electron transport region between the emission layer and the cathode; and a hole transport region between the emission layer and the anode, wherein the hole transport region includes a first compound including a first repeating unit represented by Formula 1, a second compound represented by Formula 2, a fifth compound represented by Formula 5, or any combination thereof, wherein Formulas 1, 2, and 5 are respectively the same as described herein.

### CROSS-REFERENCE TO RELATED APPLICATION

This application claims priority from and the benefit of Korean Patent Application No. 10-2021-0128342, filed on Sep. 28, 2021, which is hereby incorporated by reference for all purposes as if fully set forth herein.

### BACKGROUND

### Field

Embodiments of the invention relate generally to a light-emitting device and a method of manufacturing the light-emitting device.

### Discussion of the Background

Organic light-emitting devices are self-emissive devices that have wide viewing angles, high contrast ratios, short response times, and excellent characteristics in terms of luminance, driving voltage, and response speed, compared to devices in the art.

In an example, an organic light-emitting device includes an organic emission layer between an anode and a cathode, and holes and electrons are injected from the anode and the cathode, respectively, to the organic emission layer. Carriers, such as holes and electrons, recombine in the emission layer region to produce excitons. These excitons transition from an excited state to a ground state, thereby generating light.

In another example, quantum dots may be used as materials that perform various optical functions (for example, a light conversion function, a light emission function, and the like) in optical members and various electronic apparatuses. The quantum dots are nano-sized semiconductor nanocrystals with a quantum confinement effect, and may have different energy bandgaps by adjusting the size and composition of the nanocrystals, and thus light of various emission wavelengths may be emitted.

The above information disclosed in this Background section is only for s understanding of the background of the inventive concepts, and, therefore, it may contain information that does not constitute prior art.

### SUMMARY

One or more inventive concepts consistent with one or more embodiments include a light-emitting device having high efficiency and a long lifespan and a method of manufacturing the light-emitting device.

Additional features of the inventive concepts will be set forth in the description which follows, and in part will be apparent from the description, or may be learned by practice of is the inventive concepts.

According to one or more embodiments, a light-emitting device includes: a substrate, a cathode disposed on the substrate, an anode facing the cathode, and an organic layer arranged between the cathode and the anode and including an emission layer,

wherein the organic layer includes: an electron transport region between the emission layer and the cathode, and a hole transport region between the emission layer and the anode, and the hole transport region includes a first compound including a first repeating unit represented by Formula 1, a second compound represented by Formula 2, a fifth compound represented by Formula 5, or any combination thereof;

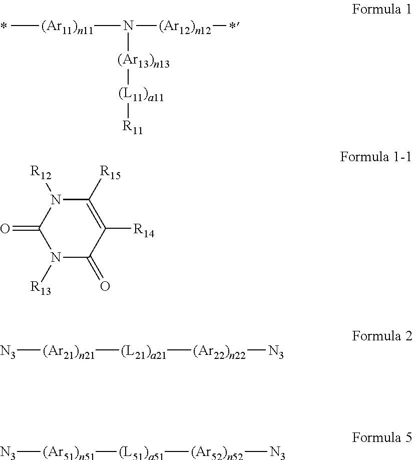

wherein, in Formulas 1, 1-1, 2, and 5,

Ar₁₁ to Ar₁₃, Ar₂₁, Ar₂₂, Ar₅₁, and Ar₅₂ are each independently a single bond, a C₁-C₆₀ alkylene group unsubstituted or substituted with at least one R₁₀ₐ, a C₂-C₆₀ alkenylene group unsubstituted or substituted with at least one R₁₀ₐ, a C₂-C₆₀ alkynylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,

n11 to n13, n21, n22, n51, and n52 are each independently an integer from 1 to 10,

L₁₁ and L₂₁ are each independently a single bond, *—C(R₁ₐ)(R_{1b})—*′, *—C(R₁ₐ)═*′, *═C(R₁ₐ)—*′, *—C(R₁ₐ)═C(R_{1b})—*′, *—C(═O)—*′, *—C(═S)—*′, *—C≡C—*′, *—B(R₁ₐ)—*′, *—N(R₁ₐ)—*′, *—O—*′, *—Si(R₁ₐ)(R_{1b})—*′, *—P(═O)(R₁ₐ)—*′, *—S—*′, *—S(═O)—*′, *—S(═O)₂—*′, or *—Ge(R₁ₐ)(R_{1b})—*′,

L₅₁ is the first repeating unit represented by Formula 1,

a11, a21, and a51 are each independently an integer from 1 to 20,

R₁₁ is a group represented by Formula 1-1, a C₃-C₆₀ carbocyclic group unsubstituted or substituted with at least one R₁₀ₐ, or a C₁-C₆₀ heterocyclic group unsubstituted or substituted with at least one R₁₀ₐ,

i) R₁₂ is a binding site to a neighboring atom in Formula 1, and R₁₃ is hydrogen, or ii) R₁₂ is hydrogen, and R₁₃ is a binding site to a neighboring atom in Formula 1,

R₁₄, R₁₅, R₁ₐ, and R_{1b} are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at is least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),

* and *′ each indicate a binding site to a neighboring atom, and

R₁₀ₐ and Q₁ to Q₃ are respectively the same as described herein.

According to one or more embodiments, a light-emitting device includes: a substrate, a cathode disposed on the substrate, an anode facing the cathode, x emitting units between the cathode and the anode, and x−1 charge generation layers, each arranged between two neighboring emitting units among the x emitting units and including an n-type charge generation layer and a p-type charge generation layer,

wherein x is an integer of 2 or more,

each of the x emitting units includes an electron transport region, an emission layer, and a hole transport region that are sequentially arranged from the cathode, and

the hole transport region includes a first compound including a first repeating unit represented by Formula 1, a second compound represented by Formula 2, a fifth compound represented by Formula 5, or any combination thereof;

where Formulas 1 and 2 may respectively be the same as described herein.

According to one or more embodiments, a method of manufacturing a light-emitting device includes: forming a first organic layer between a cathode and an anode; forming a second organic layer between the first organic layer and the anode; and forming a third organic layer between the second organic layer and the anode, wherein the forming of the third organic layer is performed by a solution process using a composition including a first compound including a first repeating unit represented by Formula 1, a second compound represented by Formula 2, or any combination thereof; wherein Formulas 1 and 2 may respectively be the same is as described herein.

It is to be understood that both the foregoing general description and the following detailed description are illustrative and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate illustrative embodiments of the invention, and together with the description serve to explain the inventive concepts.

FIGS. 1 and 2 are each a diagram schematically showing a structure of a light-emitting device according to an embodiment that is constructed according to principles of the invention.

FIGS. 3 and 4 are each a diagram schematically showing a structure of an electronic apparatus according to an embodiment.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing illustrative features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at is other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to is which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

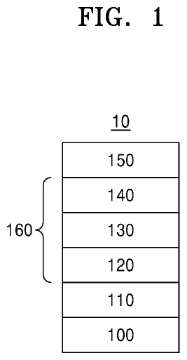

### Description of FIG. 1

Hereinafter, a light-emitting device 10 according to an embodiment that is constructed according to principles of the invention will be described with reference to FIG. 1.

Referring to FIG. 1, the light-emitting device 10 according to an embodiment includes:

a substrate 100; a cathode 110 disposed on the substrate 100; an anode 150 facing the cathode 110; and an organic layer 160 arranged between the cathode 110 and the anode 150 and including an emission layer 130,

wherein the organic layer 160 includes:

an electron transport region 120 between the emission layer 130 and the cathode 110; and

a hole transport region 140 between the emission layer 130 and the anode 150.

### Substrate 100

For use as the substrate 100, any substrate that is generally used in the related art may be used, and the substrate 100 may be an inorganic substrate or an organic substrate, each having excellent mechanical strength, thermal stability, transparency, surface smoothness, ease of handling, and water resistance.

In an embodiment, as the substrate 100, a glass substrate or a plastic substrate may be used. In one or more embodiments, the substrate 100 may be a flexible substrate, and for example, may include plastics with excellent heat resistance and durability, such as polyimide, polyethylene terephthalate (PET), polycarbonate, polyethylene napthalate, polyarylate (PAR), is polyetherimide, or any combination thereof.

### Cathode 110

The cathode 110 on the substrate 100 may be a reflective electrode, a semi-transmissive electrode, or a transmissive electrode. In an embodiment, when the cathode 110 is a transmissive electrode, a material for forming the cathode 110 may include indium tin oxide (ITO), indium zinc oxide (IZO), tin oxide (SnO₂), zinc oxide (ZnO), or any combination thereof. In one or more embodiments, when the cathode 110 is a semi-transmissive electrode or a reflective electrode, a material for forming the cathode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The cathode 110 may have a single-layered structure consisting of a single layer or a multi-layered structure including two or more layers. For example, the cathode 110 may have a three-layered structure of ITO/Ag/ITO.

### Electron Transport Region 120

The electron transport region 120 is arranged on the cathode 110.

The electron transport region 120 may have: i) a single-layered structure consisting of a single layer consisting of a single material, ii) a single-layered structure consisting of a single layer consisting of a plurality of different materials, or iii) a multi-layered structure including a plurality of layers including different materials.

The electron transport region 120 may include a buffer layer, a hole blocking layer, an electron control layer, an electron transport layer, an electron injection layer, or any combination thereof.

For example, the electron transport region 120 may have an electron injection layer/electron transport layer structure, a hole injection layer/electron transport layer/electron blocking layer structure, an electron injection layer/electron transport layer/electron control layer structure, or an electron injection layer/electron transport layer/buffer layer structure, wherein constituent layers of each structure are sequentially stacked from the cathode 110.

The electron transport region 120 may include a metal oxide, and a metal of the metal oxide may include Zn, Ti, Zr, Sn, W, Ta, Ni, Mo, Cu, Mg, Co, Mn, Y, Al, or any combination thereof. Also, the electron transport region 120 may include a metal sulfide, such as CuSCN and the like.

The electron transport region 120 (for example, an electron injection layer or an electron transport layer included in the electron transport region 120) may include a third compound represented by Formula 3:

MₚO_{q} Formula 3-

wherein, in Formula 3,

### M may be Zn, Ti, Zr, Sn, W, Ta, Ni, Mo, Cu, or V, and

p and q may each independently be an integer from 1 to 5.

The third compound may be represented by Formula 3-1:

Zn₍₁₋ᵣ₎M′ᵣO Formula 3-1

wherein, in Formula 3-1,
M′ may be Mg, Co, Ni, Zr, Mn, Sn, Y, Al, or any combination thereof, and
r may be a number greater than 0 and equal to or less than 0.5.

In an embodiment, the electron transport region 120 may include ZnO or ZnMgO.

In one or more embodiments, the electron transport region 120 may include a second compound represented by Formula 2. The second compound represented by Formula 2 is may be the same as described herein.

### Emission Layer 130

When the light-emitting device 10 is a full-color light-emitting device, the emission layer 130 may be patterned into a red emission layer, a green emission layer, and/or a blue emission layer, according to a subpixel. In an embodiment, the emission layer 130 may have a stacked structure in which two or more layers among a red emission layer, a green emission layer, and a blue emission layer contact each other or are separated from each other to emit white light. In one or more embodiments, the emission layer 130 may have a structure in which two or more materials among a red light-emitting material, a green light-emitting material, and a blue light-emitting material are mixed with each other in a single layer to emit white light.

In an embodiment, the emission layer 130 may include a host and a dopant. The dopant may include a phosphorescent dopant, a fluorescent dopant, or any combination thereof.

An amount of the dopant included in the emission layer 130 may be in a range of about 0.01 parts by weight to about 15 parts by weight based on 100 parts by weight of the host.

In one or more embodiments, the emission layer 130 may include a quantum dot.

In one or more embodiments, the emission layer 130 may include a delayed fluorescence material. The delayed fluorescence material may act as the host or the dopant in the emission layer 130.

A thickness of the emission layer 130 may be in a range of about 100 Å to about 1,000 Å, for example, about 200 Å to about 600 Å. When the thickness of the emission layer 130 is within these ranges, excellent luminescence characteristics may be obtained without a substantial increase in driving voltage.

### Host

In an embodiment, the host may include a compound represented by Formula is 301:

[Ar₃₀₁]_{xb11}-[(L₃₀₁)_{xb1}-R₃₀₁]_{xb21} Formula 301-

wherein, in Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ may each be the same as described in connection with Q₁.

For example, when xb11 in Formula 301 is 2 or more, two or more of Ar₃₀₁ may be bonded together via a single bond.

In one or more embodiments, the host may include a compound represented by Formula 301-1, a compound represented by Formula 301-2, or any combination thereof:

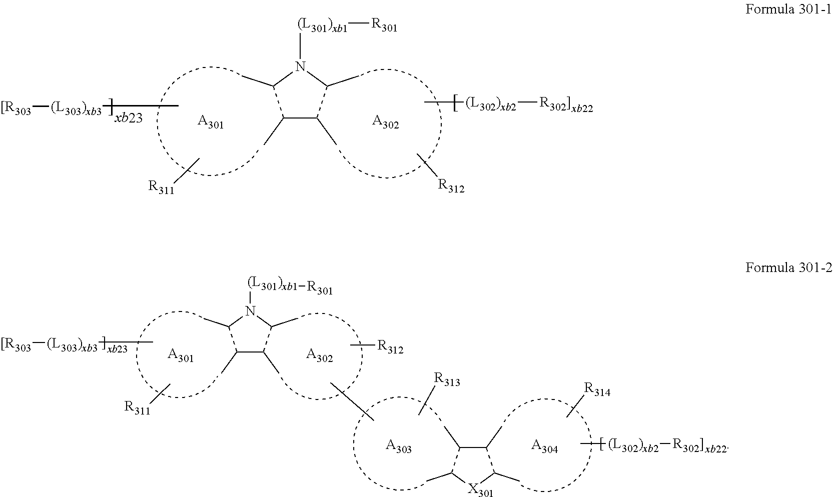

In Formulas 301-1 and 301-2,

ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N—[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each be the same as described herein,
L₃₀₂ to L₃₀₄ may each independently be the same as described in connection with L₃₀₁,

xb2 to xb4 may each independently be the same as described in connection with xb1, and

R₃₀₂ to R₃₀₅ and R₃₁₁ to R₃₁₄ may each be the same as described in connection with R₃₀₁.

In one or more embodiments, the host may include an alkali earth metal complex, a post-transition metal complex, or any combination thereof. In one or more embodiments, the host may include a Be complex (for example, Compound H55), an Mg complex, a Zn complex, or any combination thereof.

In one or more embodiments, the host may include one of Compounds H1 to H126, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri(carbazol-9-yl)benzene (TCP), or any combination thereof:

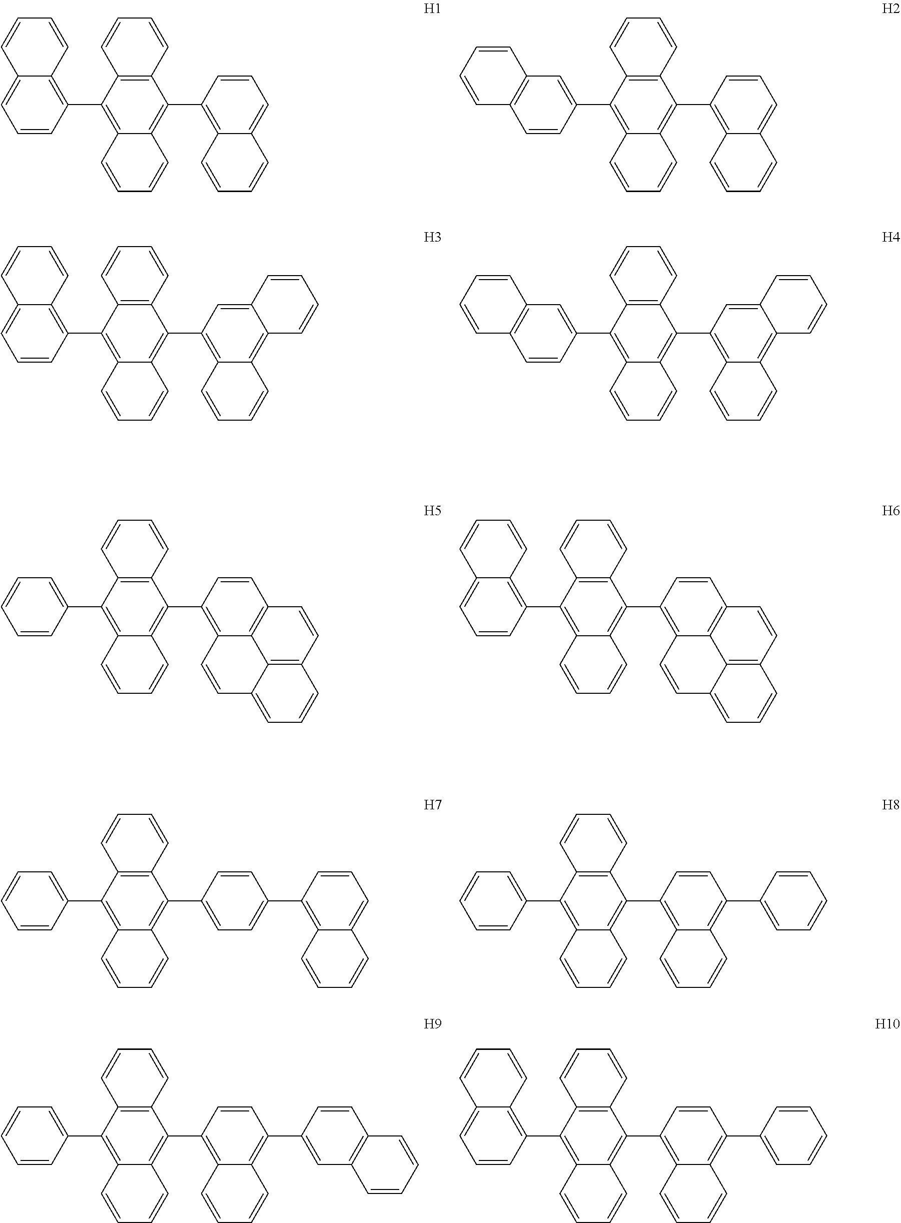

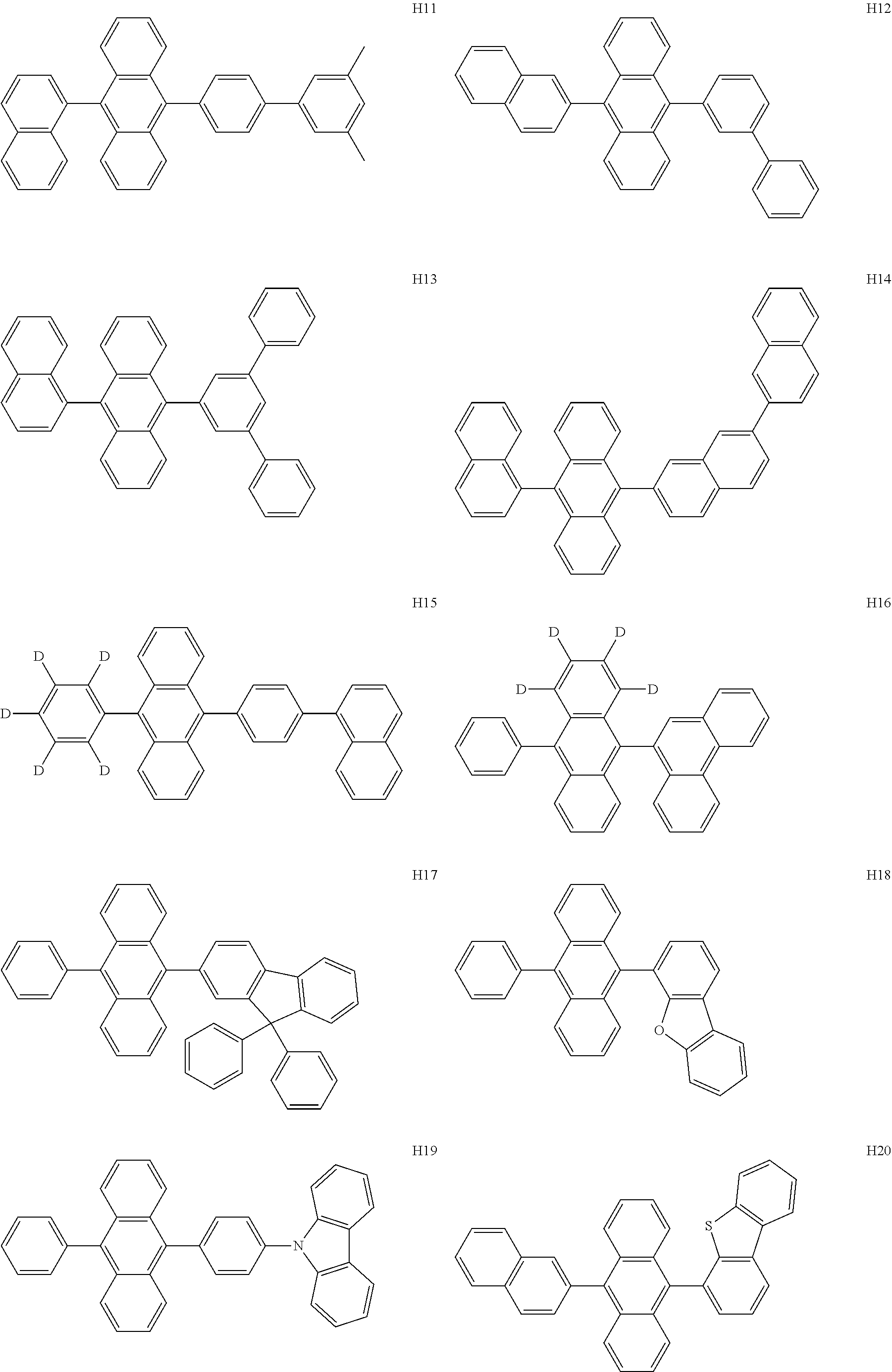

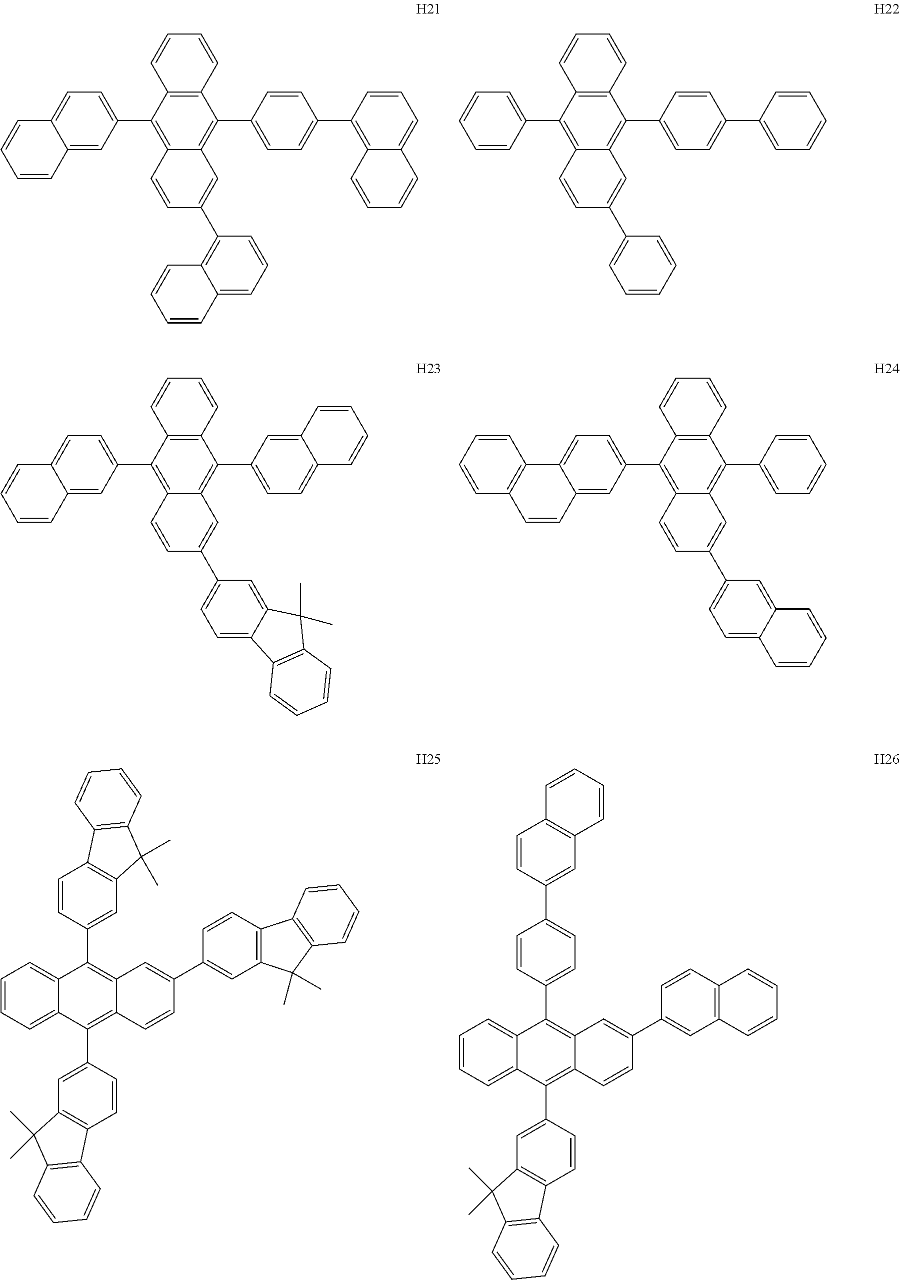

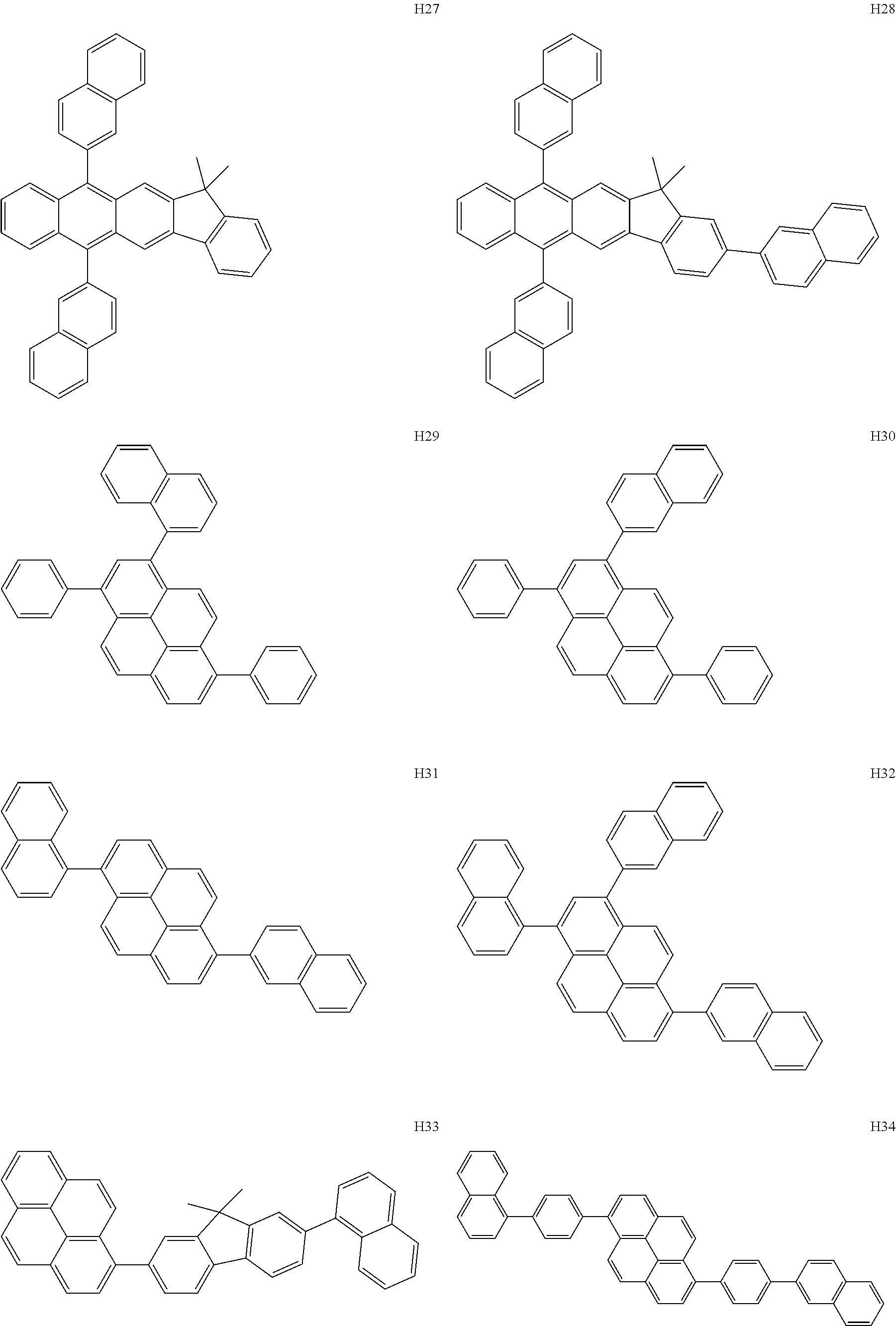

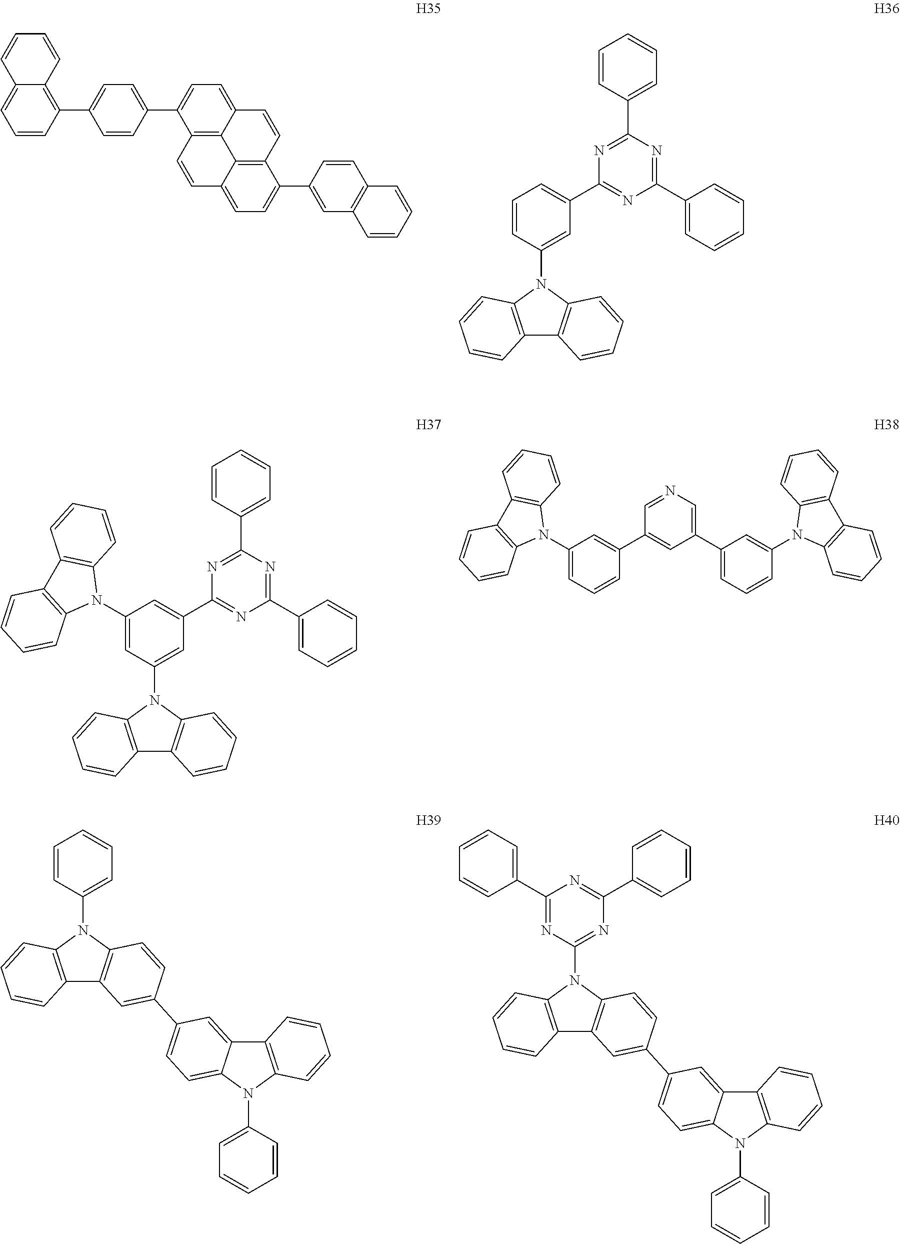

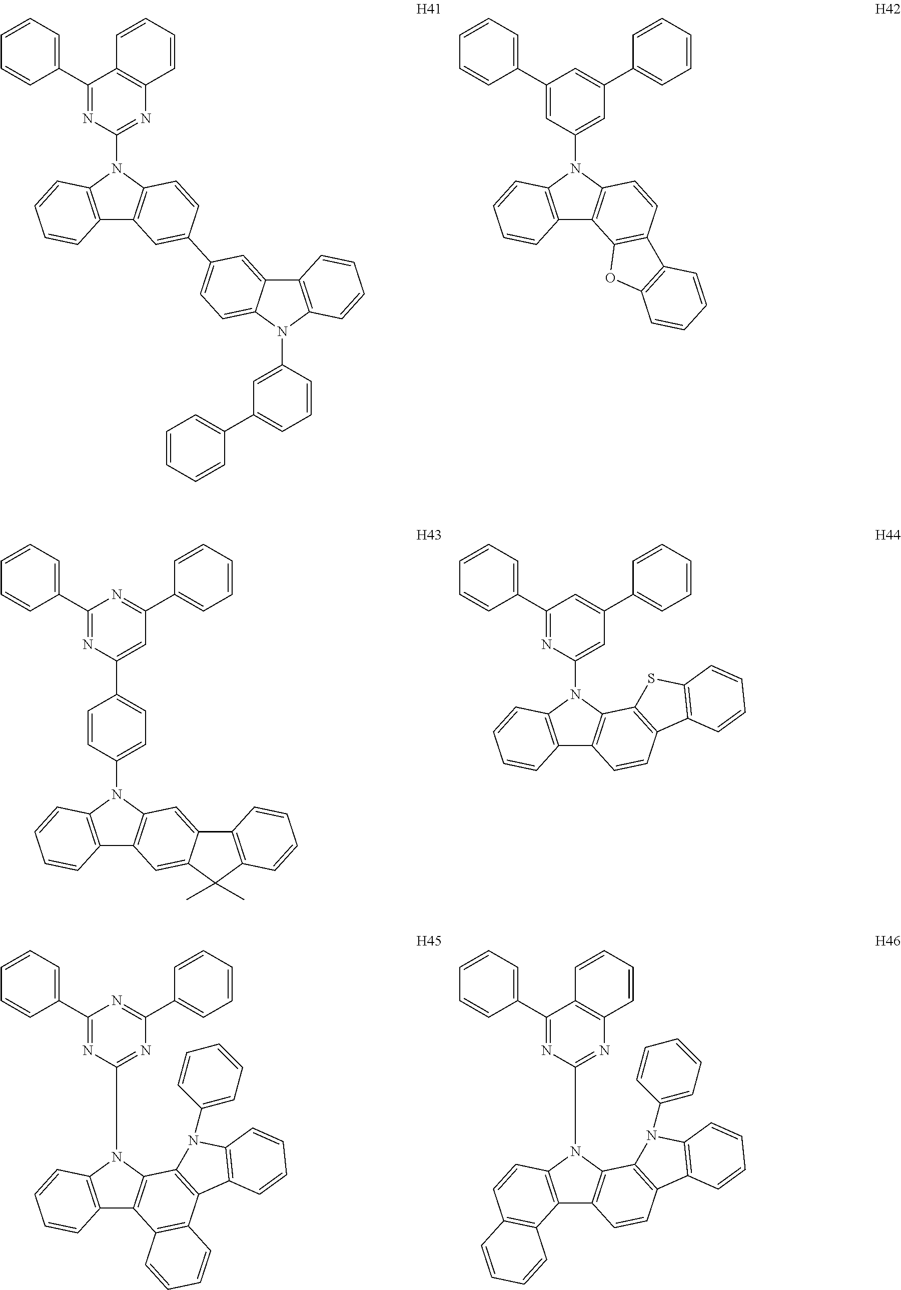 [SMILES: c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1 ; c1ccc(-c2nc(-c3ccccc3)nc(-n3c4ccccc4c4c5ccccc5c5c6ccccc6n(-c6ccccc6)c5c43)n2)cc1 ; c1ccc(-c2nc(-n3c4ccc5ccccc5c4c4ccc5c6ccccc6n(-c6ccccc6)c5c43)nc3ccccc23)cc1]

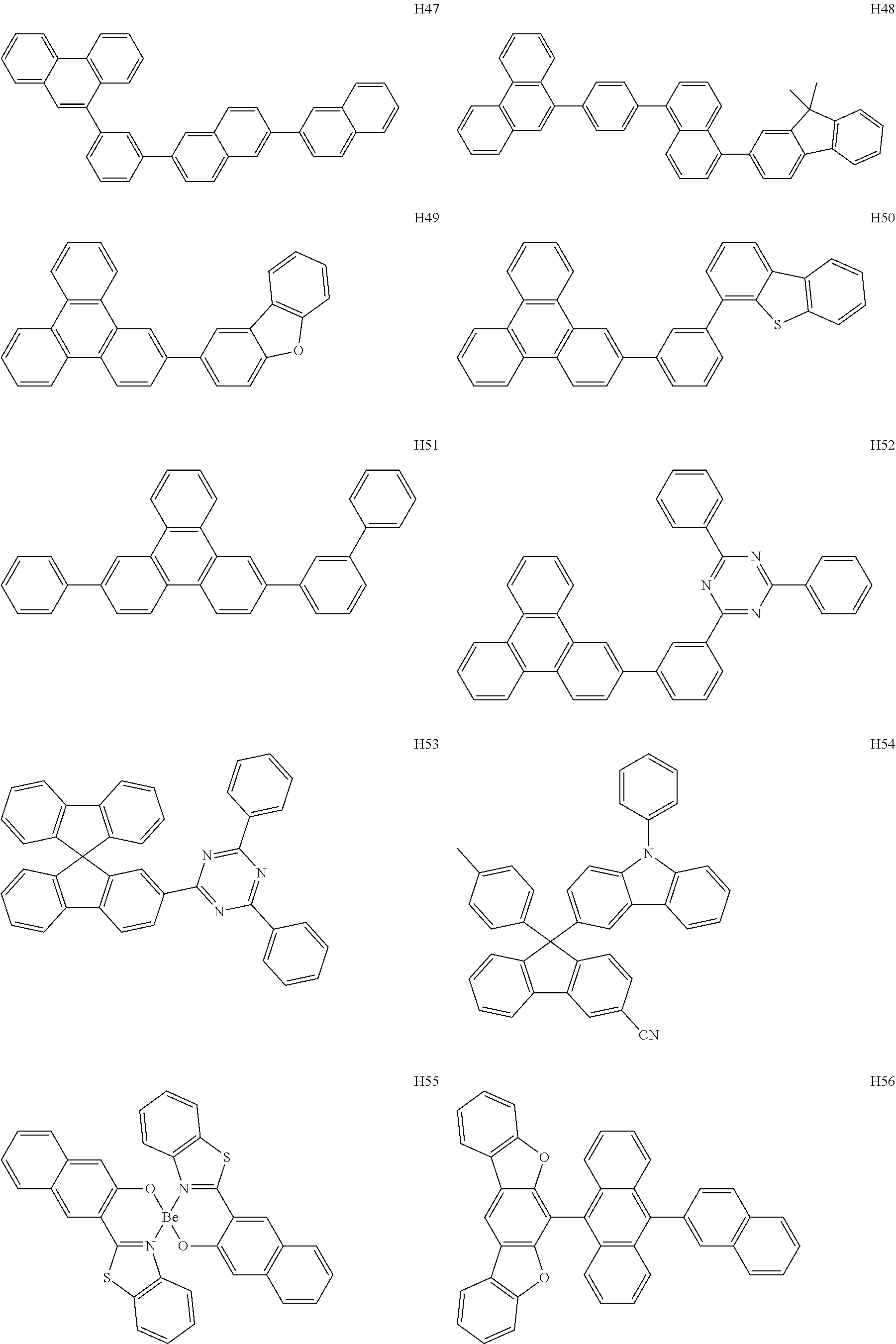

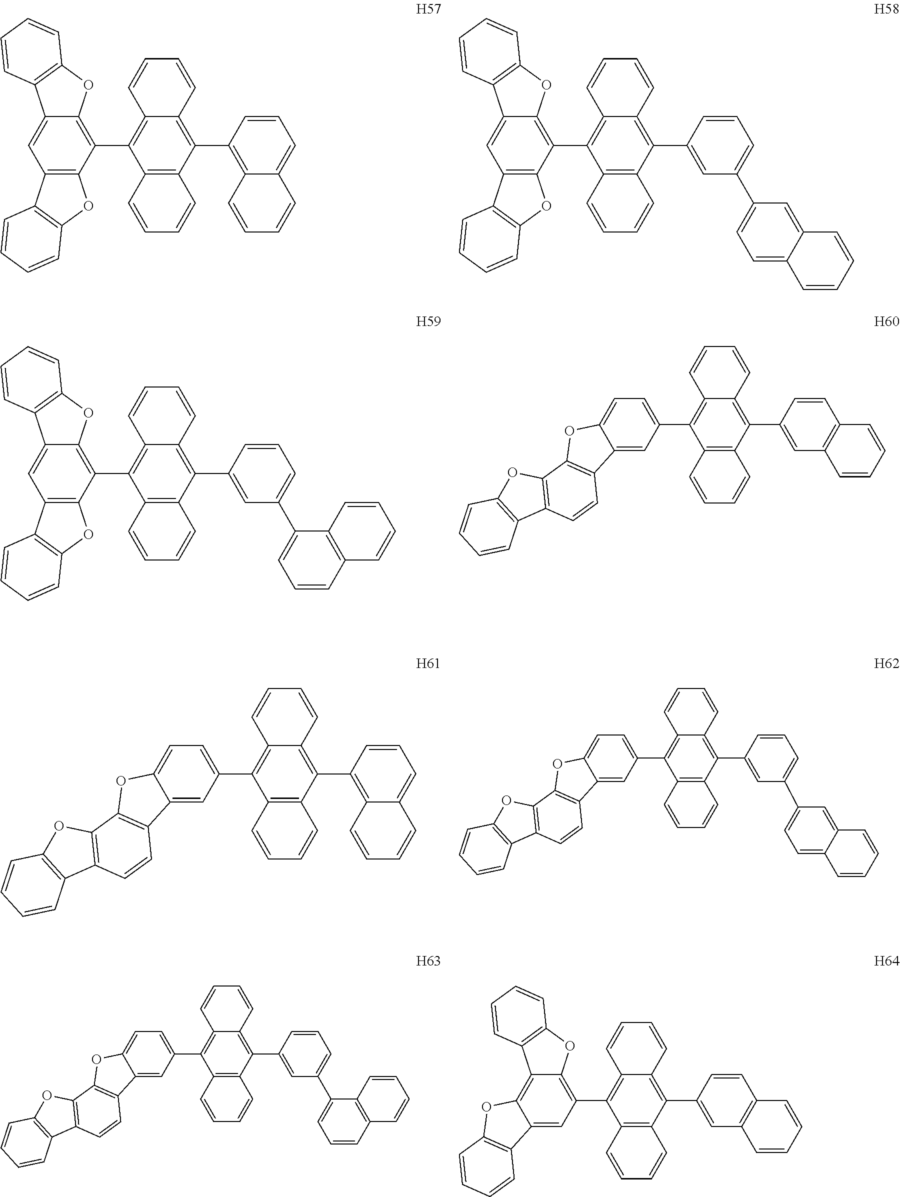

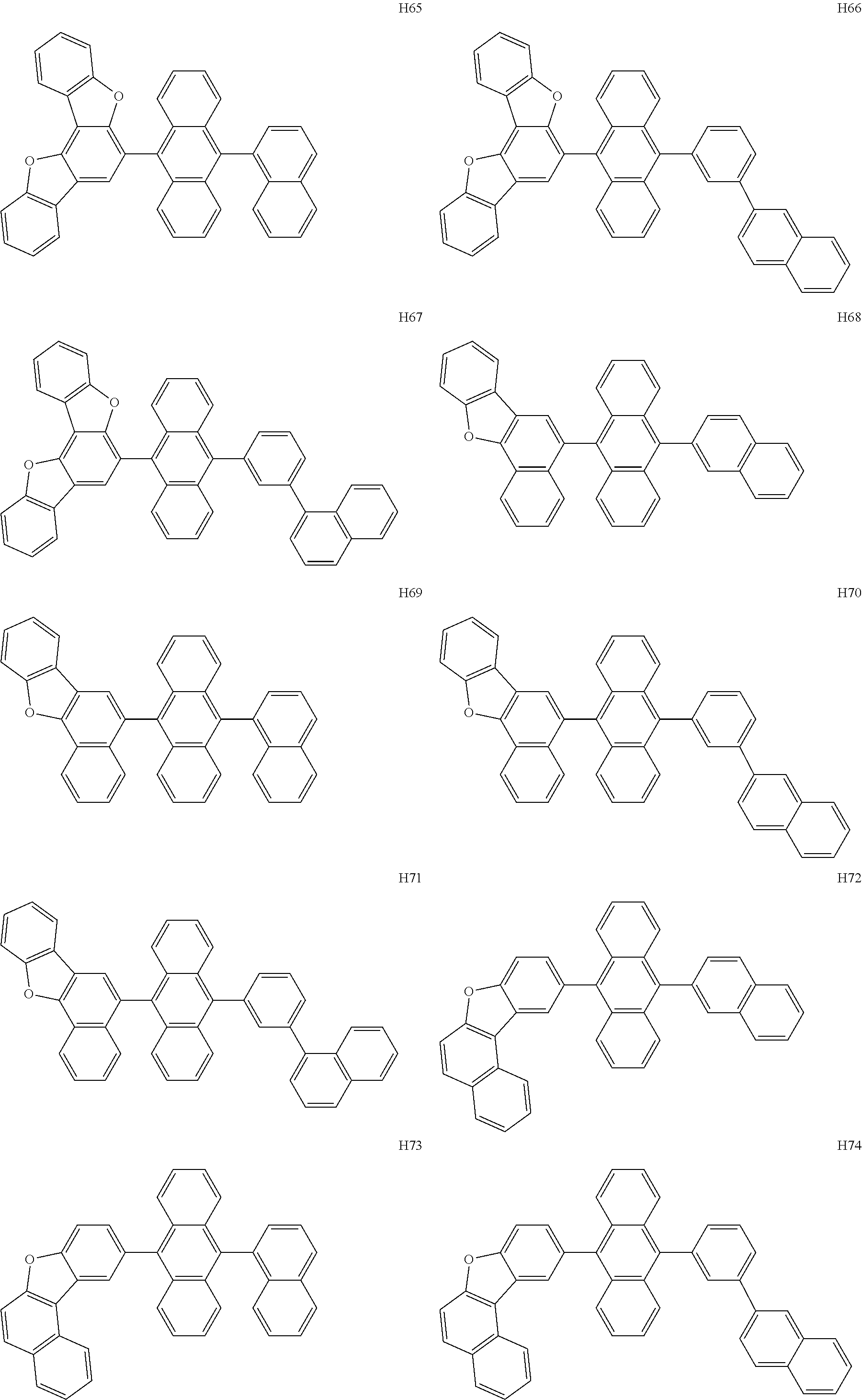

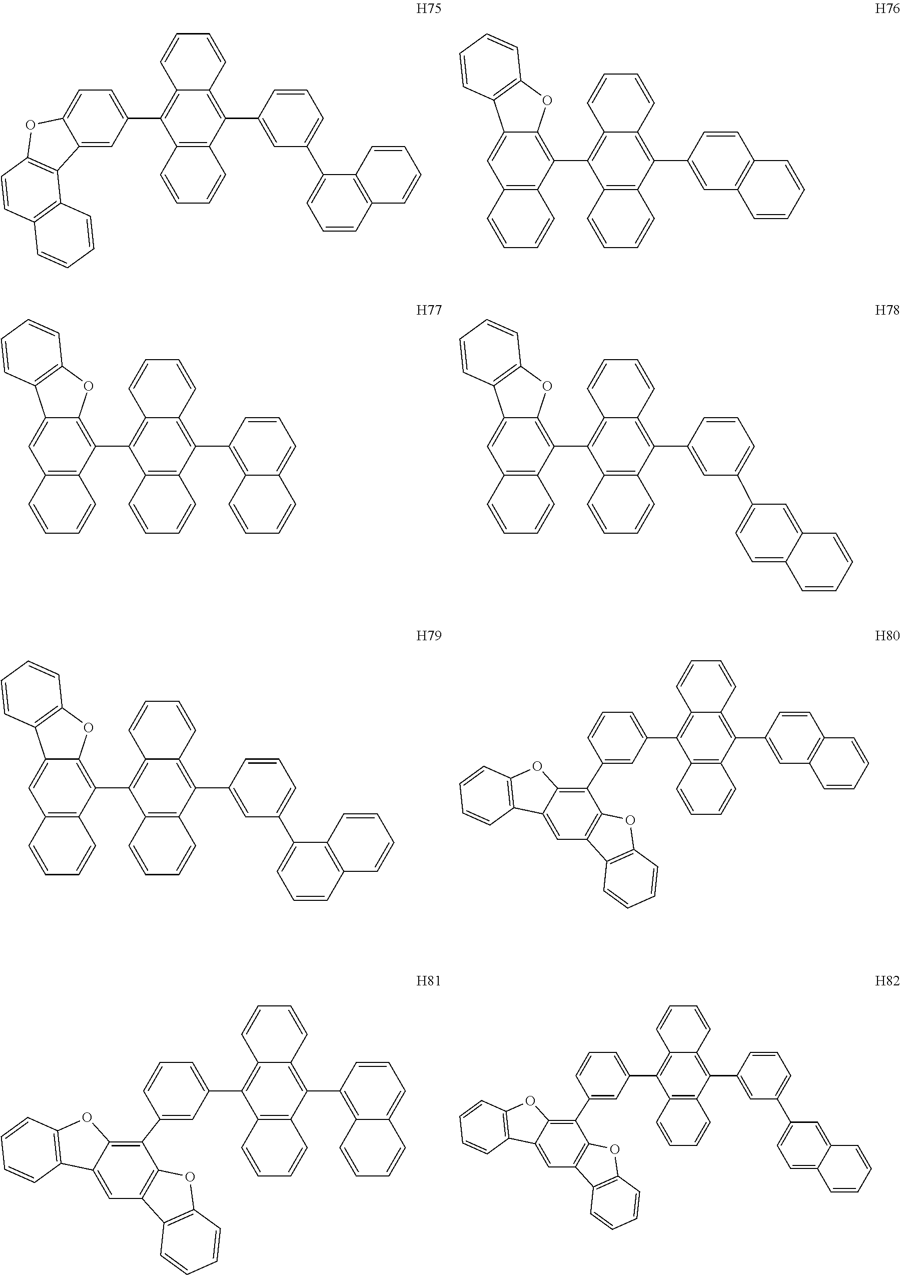

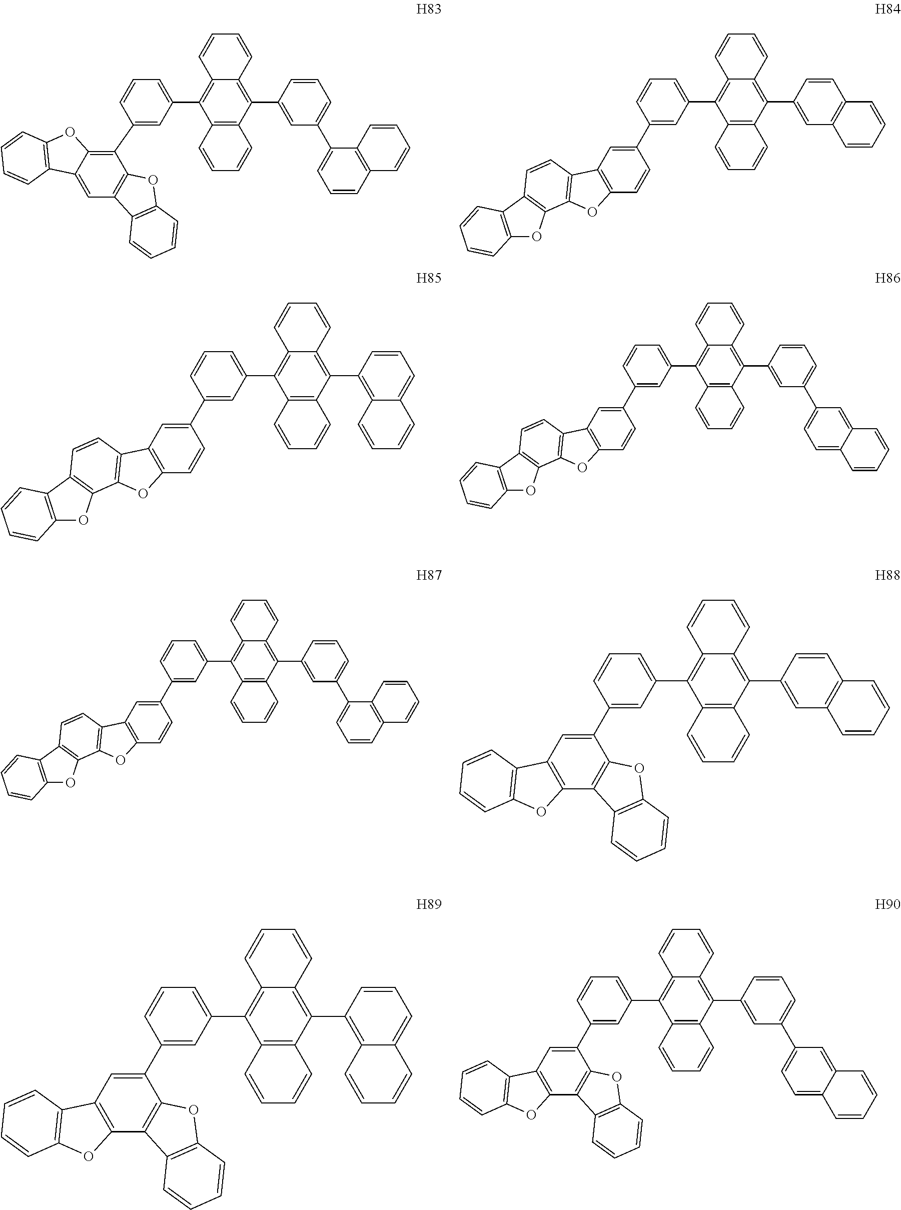

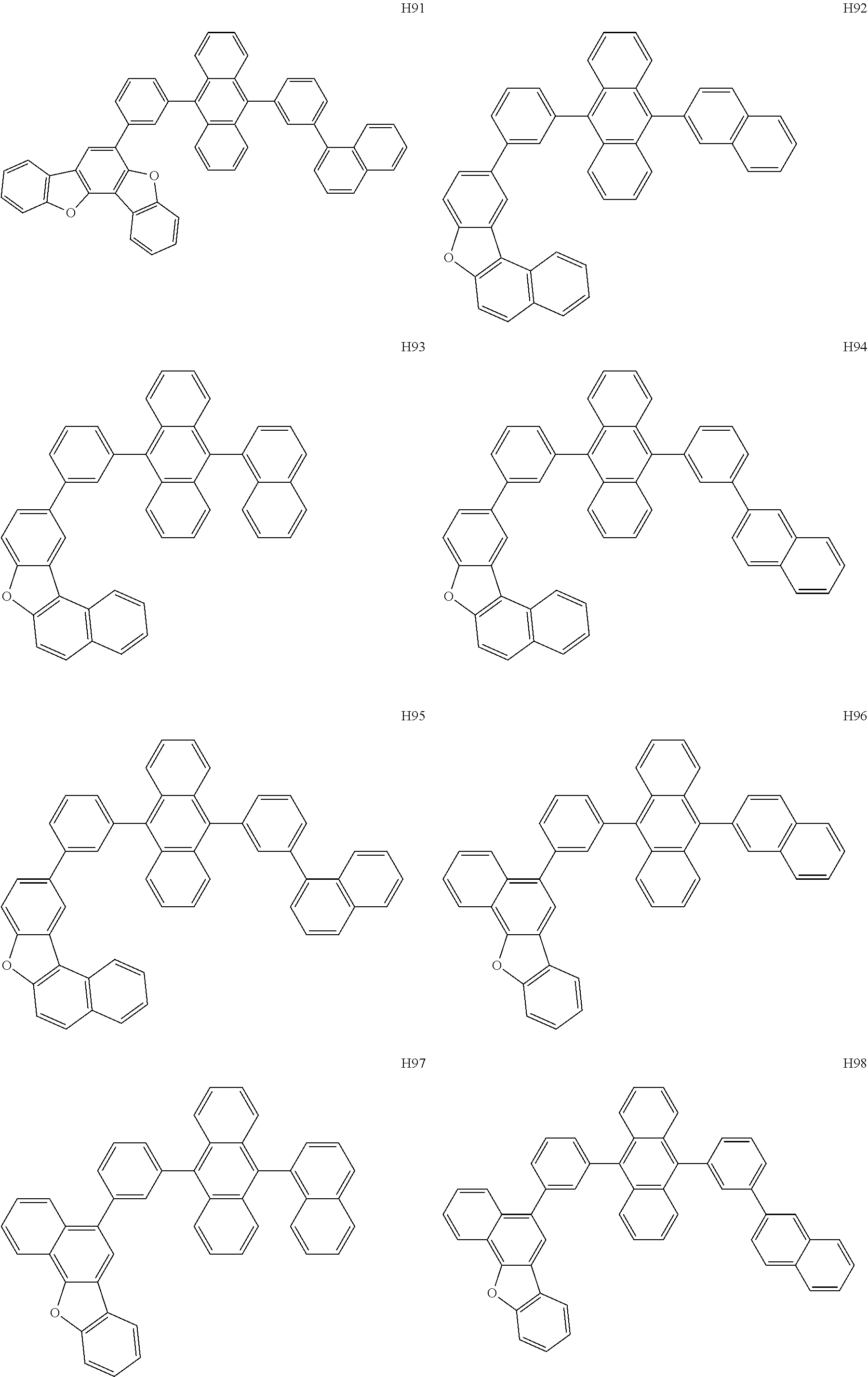

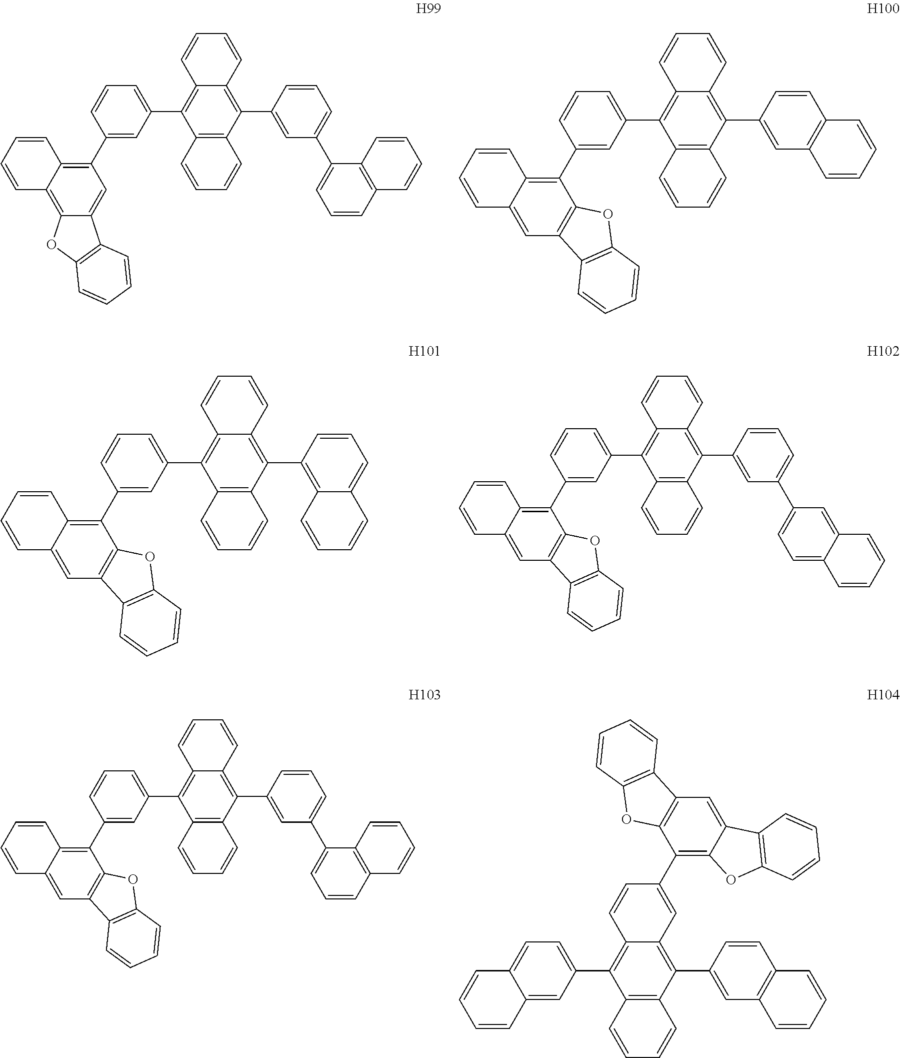

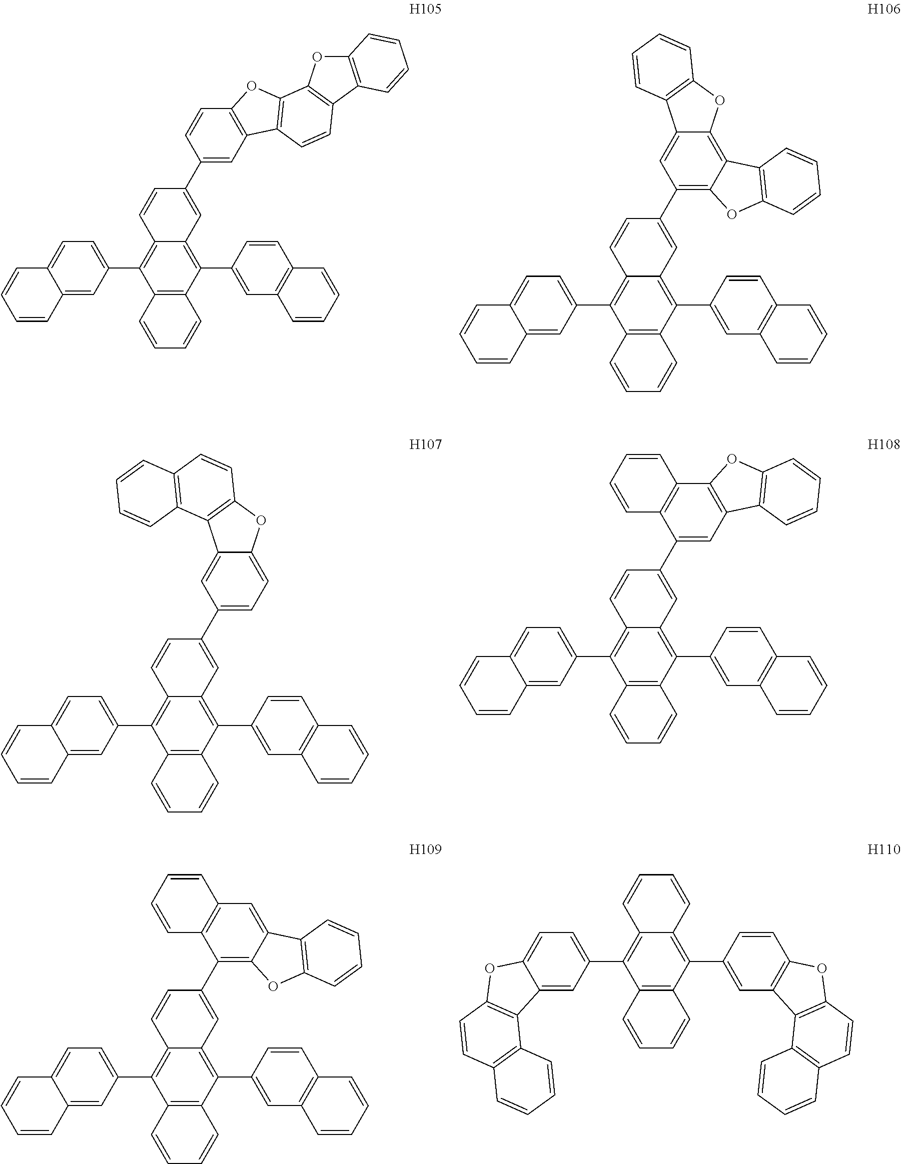

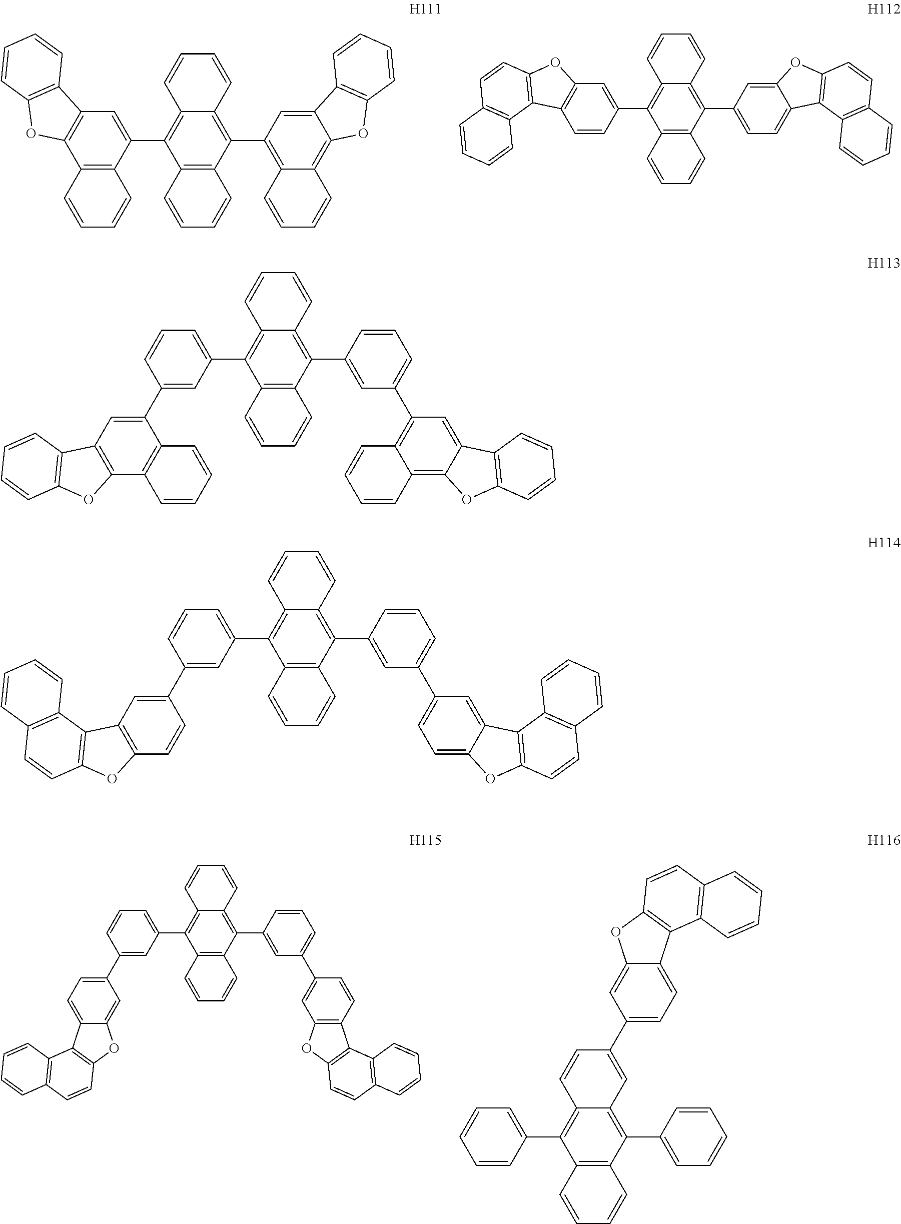

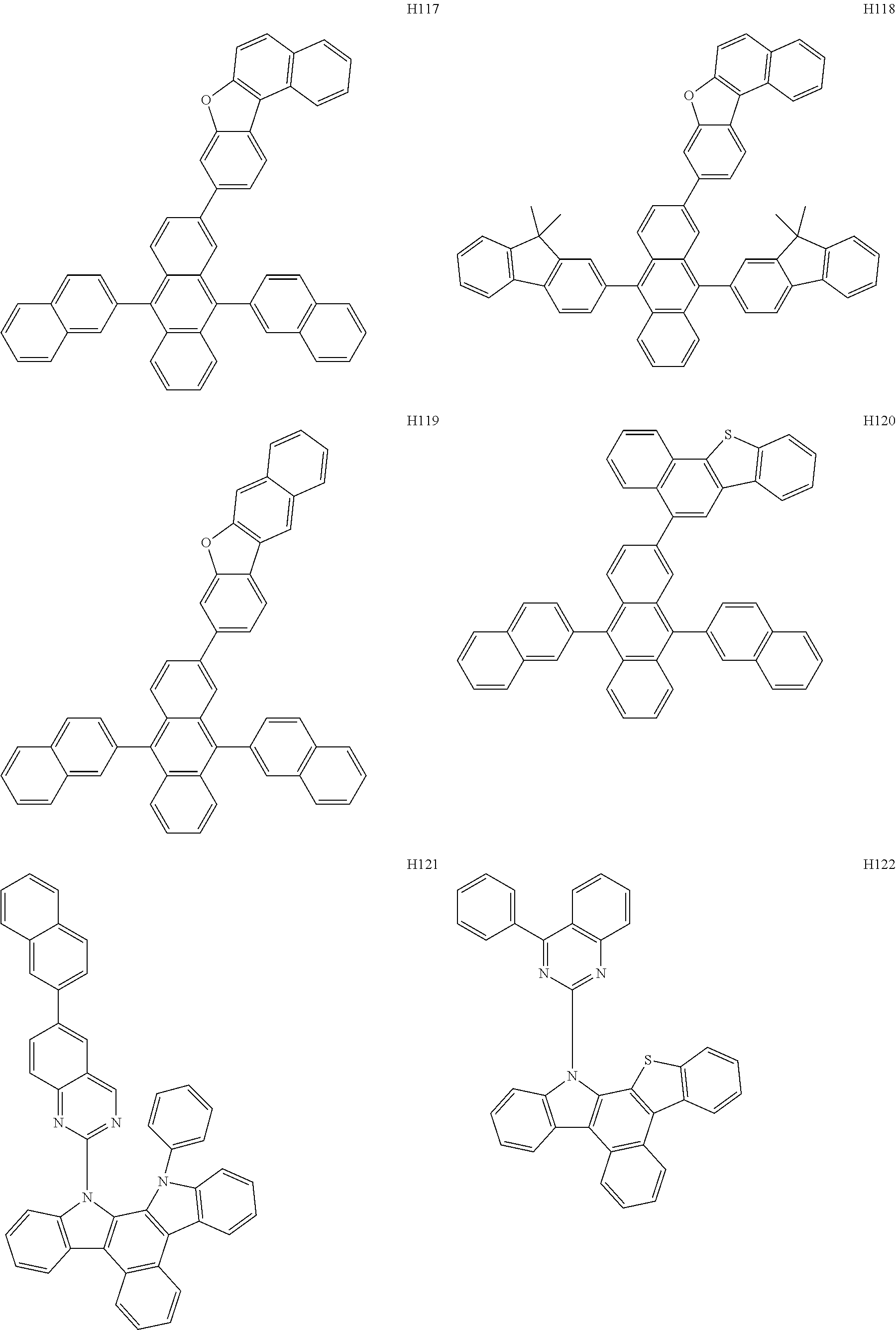

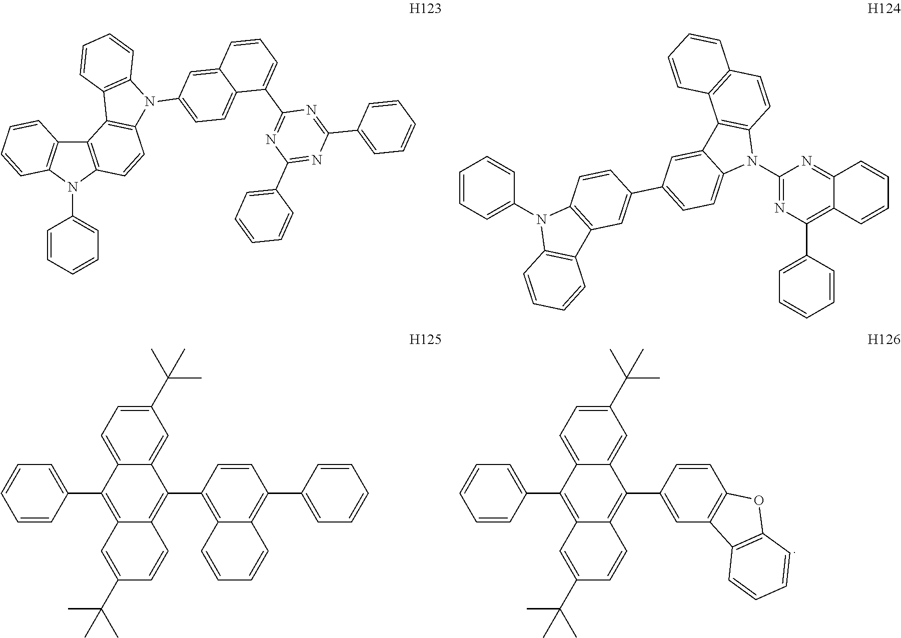

### Phosphorescent Dopant

In an embodiment, the phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In one or more embodiments, the phosphorescent dopant may include an organometallic compound represented by Formula 401:

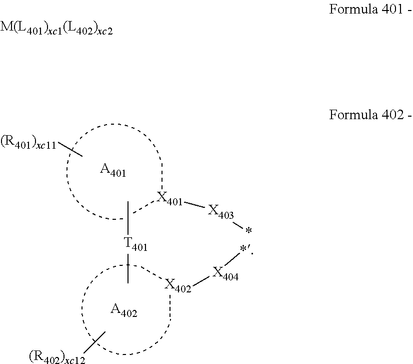

In Formulas 401 and 402,

M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein, when xc1 is 2 or more, two or more of L₄₀₁ may be identical to or different from each other,
L₄₀₂ may be an organic ligand, and xc2 may be 0, 1, 2, 3, or 4, wherein, when xc2 is 2 or more, two or more of L₄₀₂ may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)—*′, *—C(Q₄₁₁)(Q₄₁₂)—*′, *—C(Q₄₁₁)═C(Q₄₁₂)—*′, *—C(Q₄₁₁)═*′, or *═C═*′,

X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),

Q₄₁₁ to Q₄₁₄ may each be the same as described in connection with Q₁,
R₄₀₁ and R₄₀₂ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each be the same as described in connection with Q₁,
xc11 and xc12 may each independently be an integer from 0 to 10, and
* and *′ in Formula 402 each indicate a binding site to M in Formula 401.

For example, in Formula 402, i) X₄₀₁ may be nitrogen, and X₄₀₂ may be carbon, or ii) each of X₄₀₁ and X₄₀₂ may be nitrogen.

In an embodiment, when xc1 in Formula 401 is 2 or more, two ring A₄₀₁(s) among two or more of L₄₀₁ may optionally be bonded to each other via T₄₀₂, which is a linking group, and two ring A₄₀₂(s) among two or more of L₄₀₁ may optionally be bonded to each other via T₄₀₃, which is a linking group (see Compounds PD1 to PD4 and PD7). T₄₀₂ and T₄₀₃ may each be the same as described in connection with T₄₀₁.

In Formula 401, L₄₀₂ may be an organic ligand. For example, L₄₀₂ may include a halogen group, a diketone group (for example, an acetylacetonate group), a carboxylic acid group (for example, a picolinate group), —C(═O), an isonitrile group, a —CN group, a phosphorus group (for example, a phosphine group, a phosphite group, and the like), or any combination thereof.

The phosphorescent dopant may include, for example, one of Compounds PD1 to is PD39, or any combination thereof:

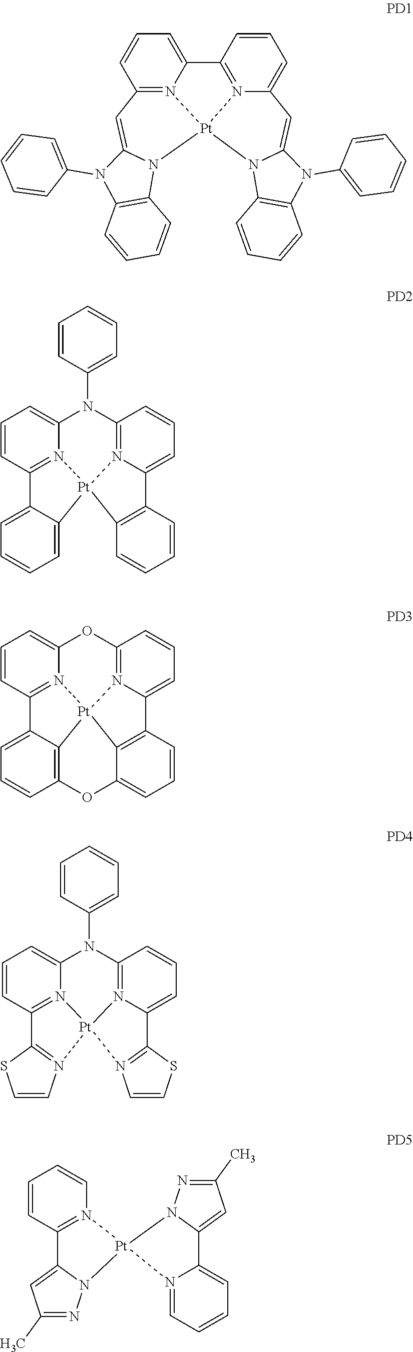

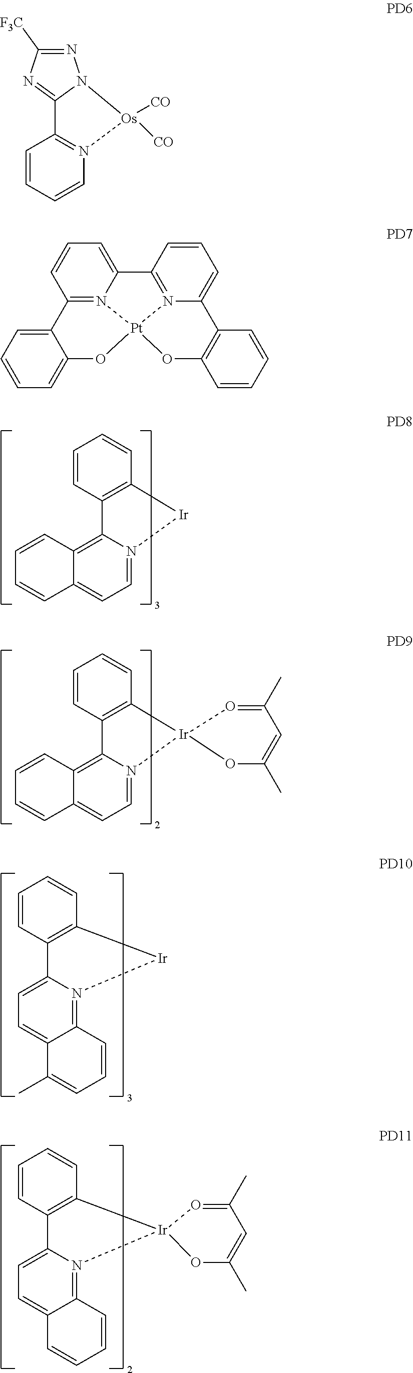

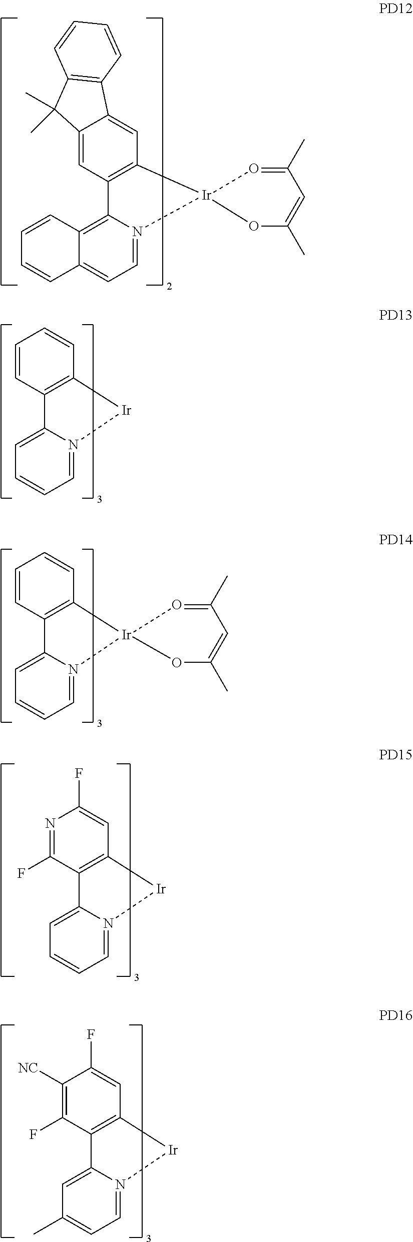

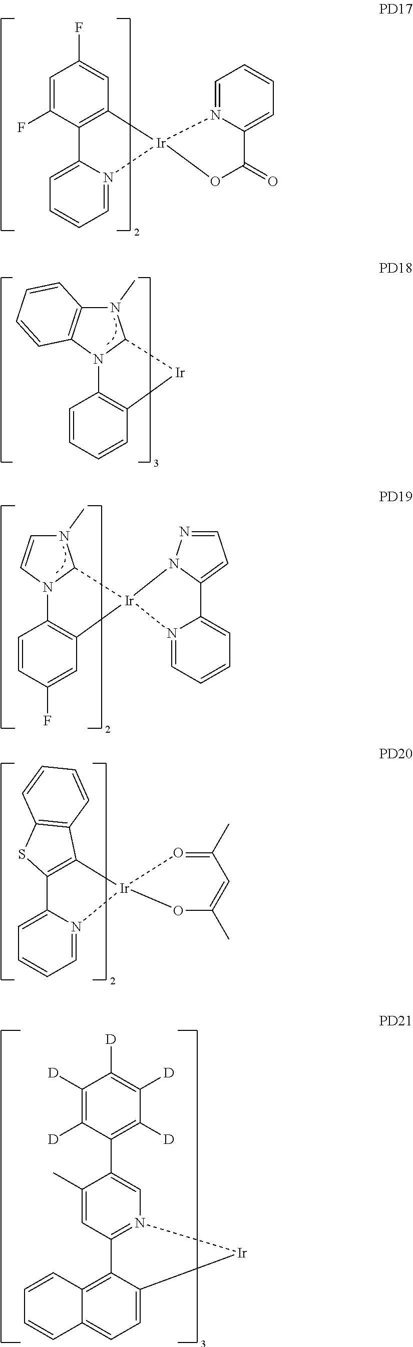

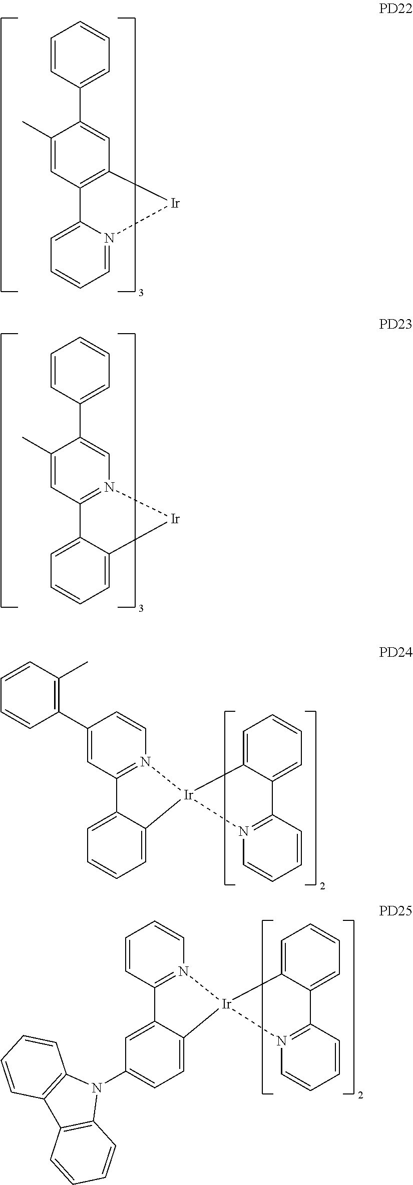

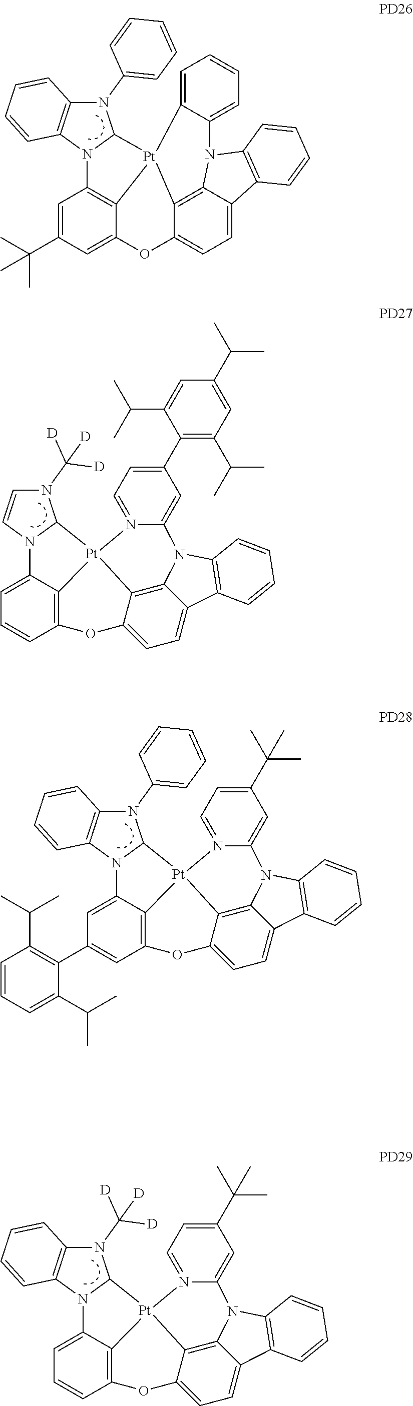

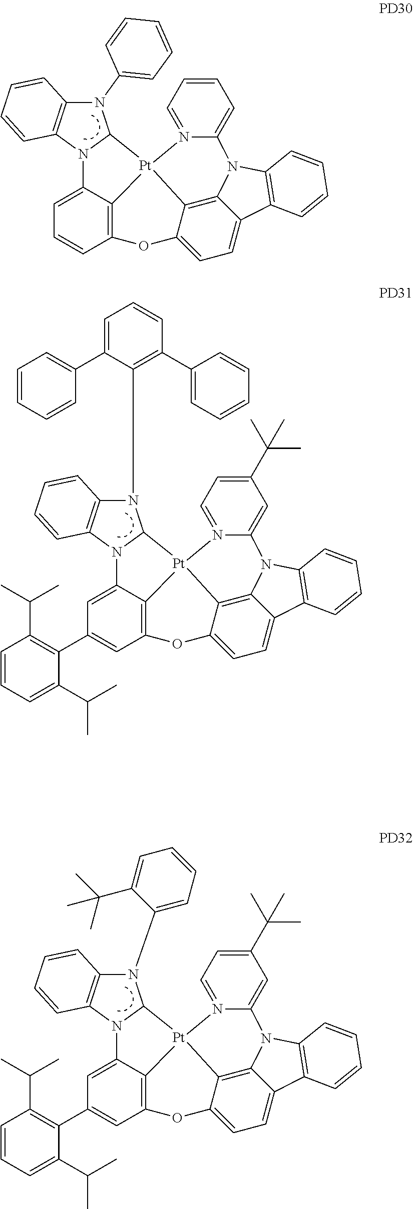

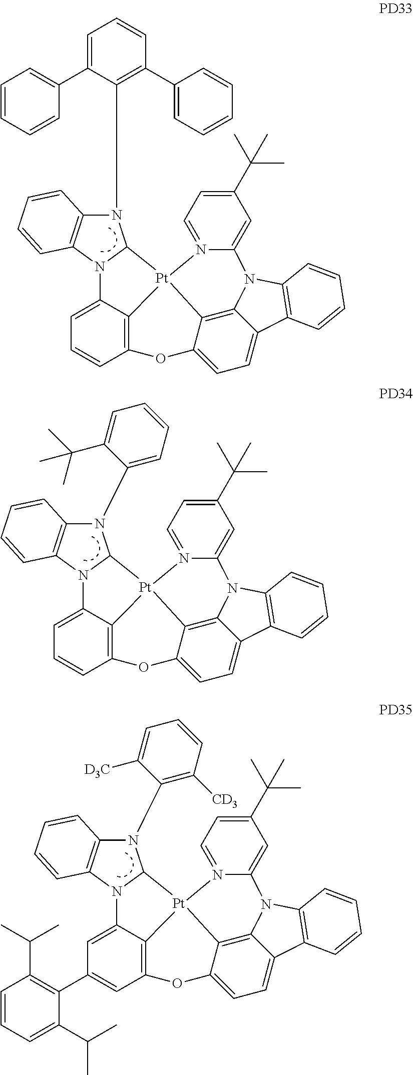

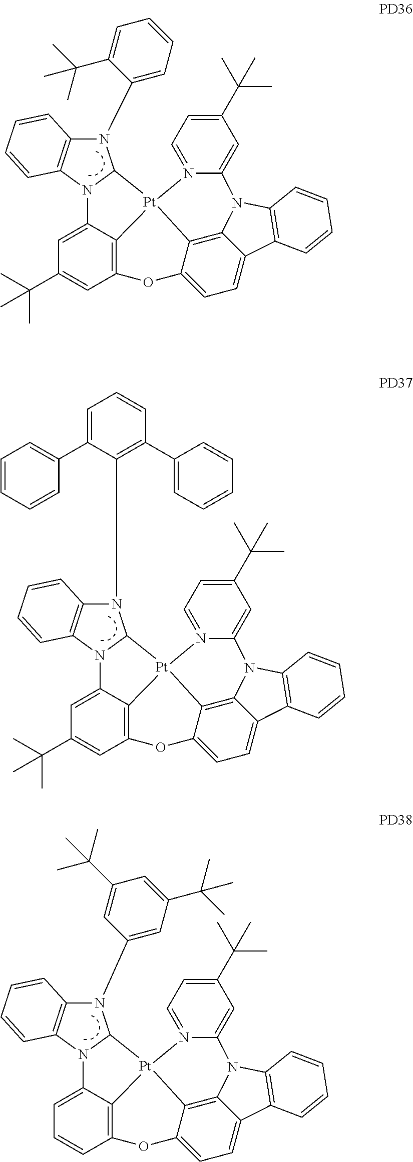

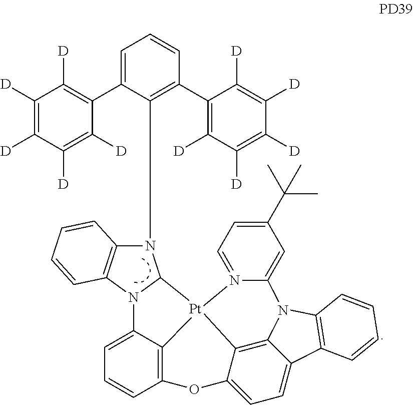

### Fluorescent Dopant

The fluorescent dopant may include an amine group-containing compound, a styryl group-containing compound, or any combination thereof.

For example, the fluorescent dopant may include a compound represented by Formula 501:

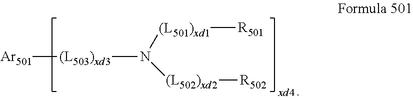

In Formula 501,

Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xd1 to xd3 may each independently be 0, 1, 2, or 3, and

xd4 may be 1, 2, 3, 4, 5, or 6.

For example, Ar₅₀₁ in Formula 501 may be a condensed cyclic group (for example, an anthracene group, a chrysene group, a pyrene group, and the like) in which three or more monocyclic groups are condensed together.

For example, xd4 in Formula 501 may be 2.

In one or more embodiments, the fluorescent dopant may include: one of Compounds FD1 to FD38; DPVBi; DPAVBi; or any combination thereof:

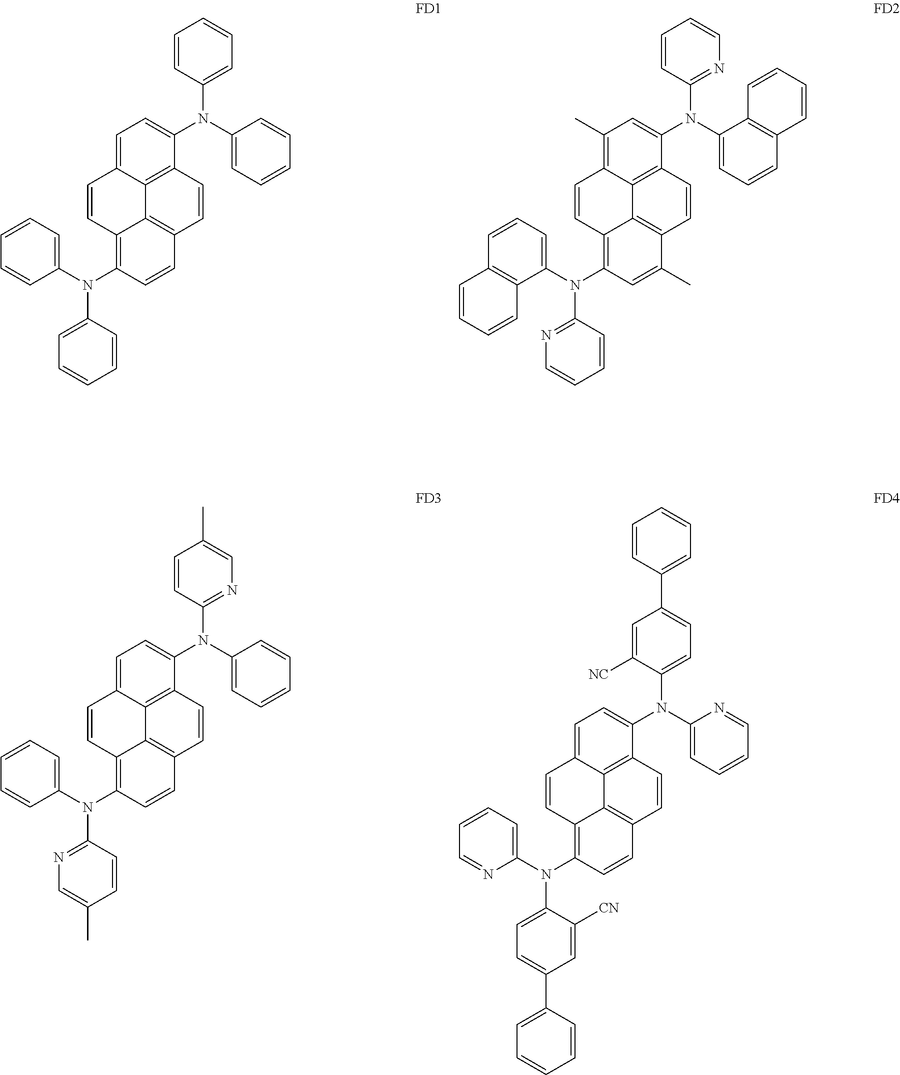 [SMILES: c1ccc(N(c2ccccc2)c2ccc3ccc4c(N(c5ccccc5)c5ccccc5)ccc5ccc2c3c54)cc1 ; Cc1cc(N(c2ccccn2)c2cccc3ccccc23)c2ccc3c(C)cc(N(c4ccccn4)c4cccc5ccccc45)c4ccc1c2c34 ; Cc1ccc(N(c2ccccc2)c2ccc3ccc4c(N(c5ccccc5)c5ccc(C)cn5)ccc5ccc2c3c54)nc1 ; N#Cc1cc(-c2ccccc2)ccc1N(c1ccccn1)c1ccc2ccc3c(N(c4ccccn4)c4ccc(-c5ccccc5)cc4C#N)ccc4ccc1c2c43]

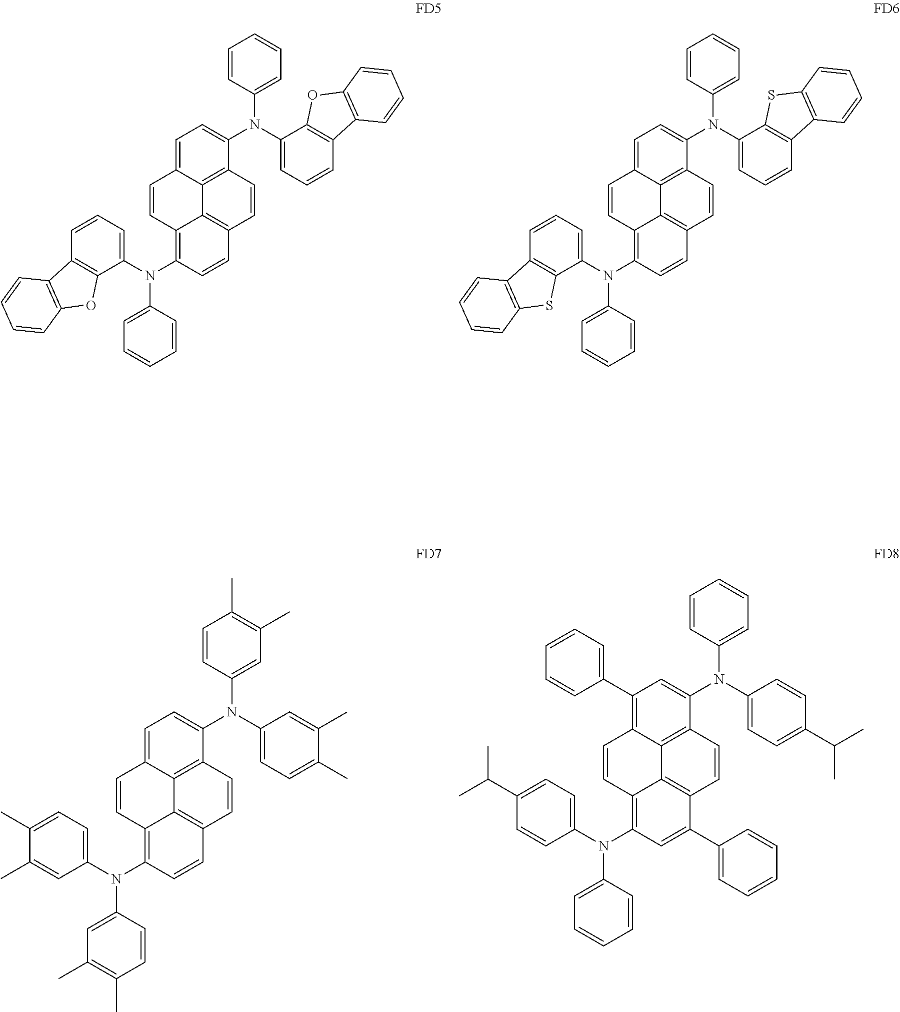

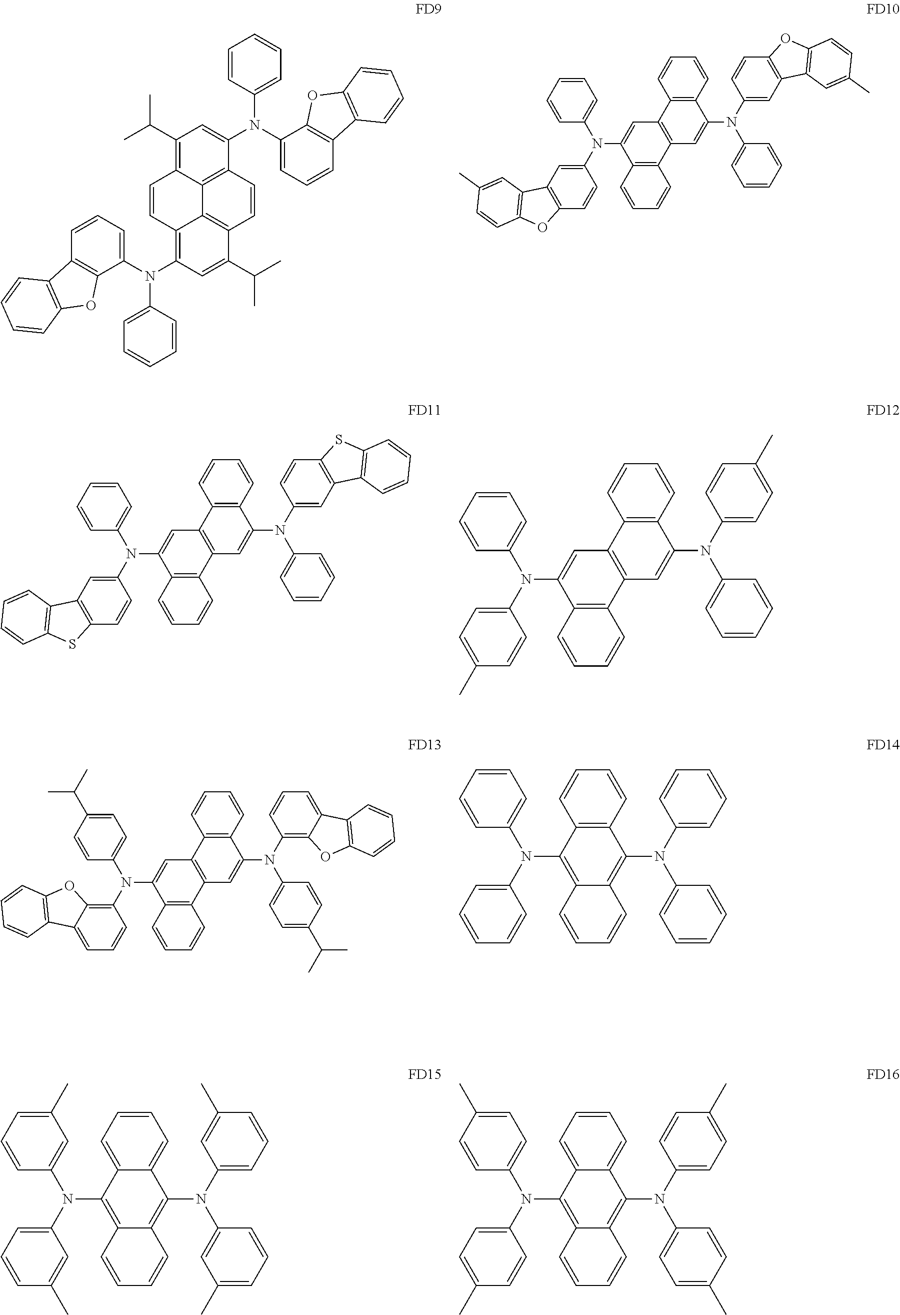

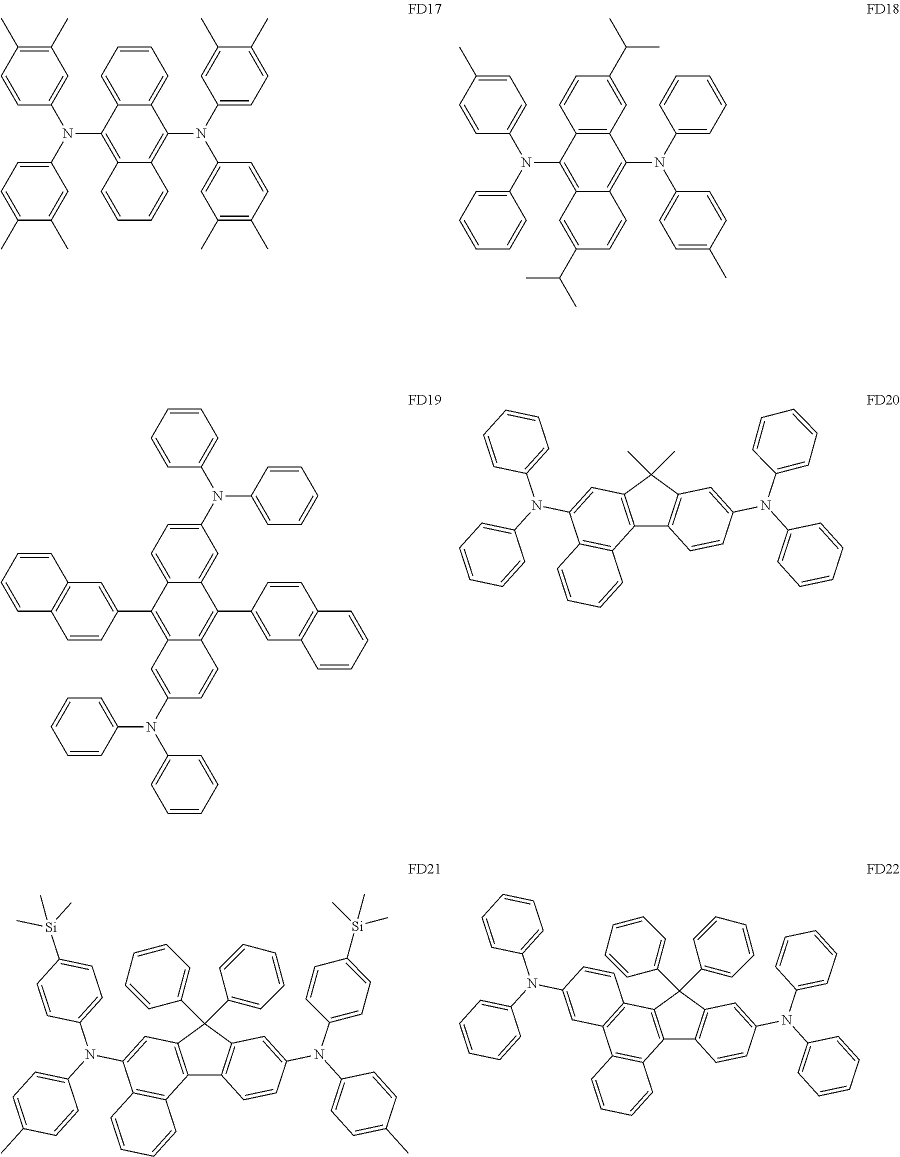

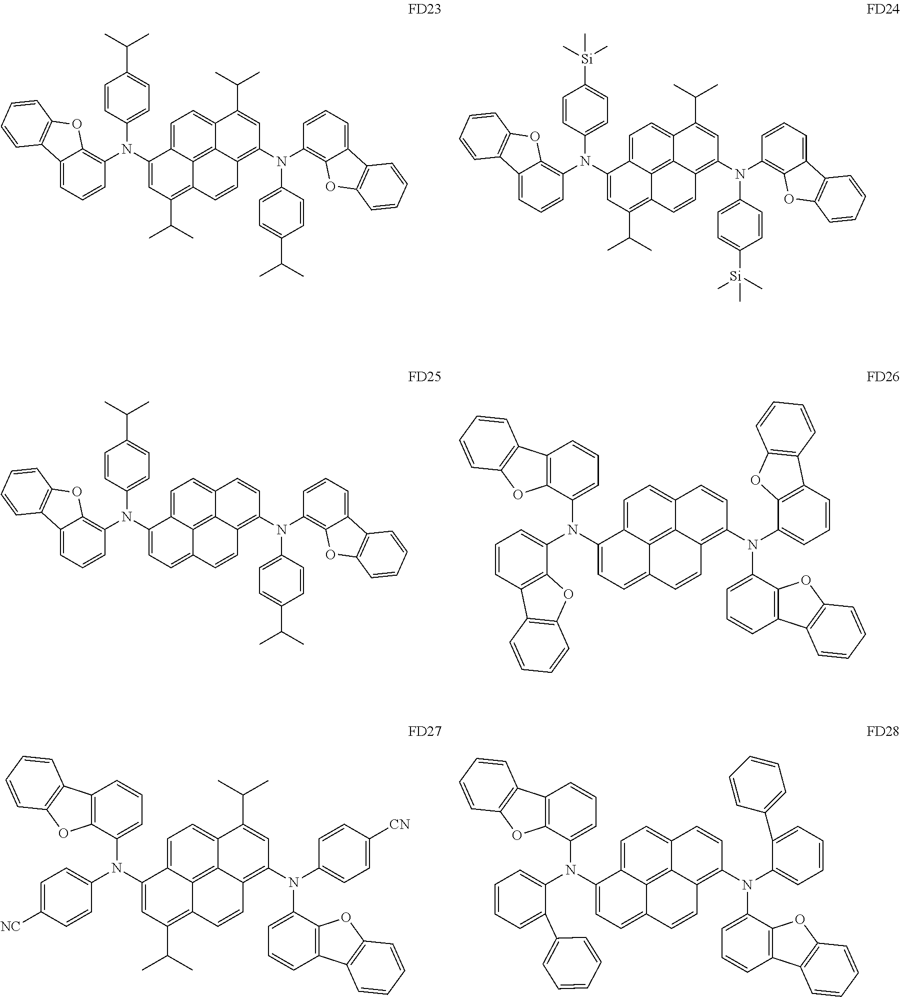

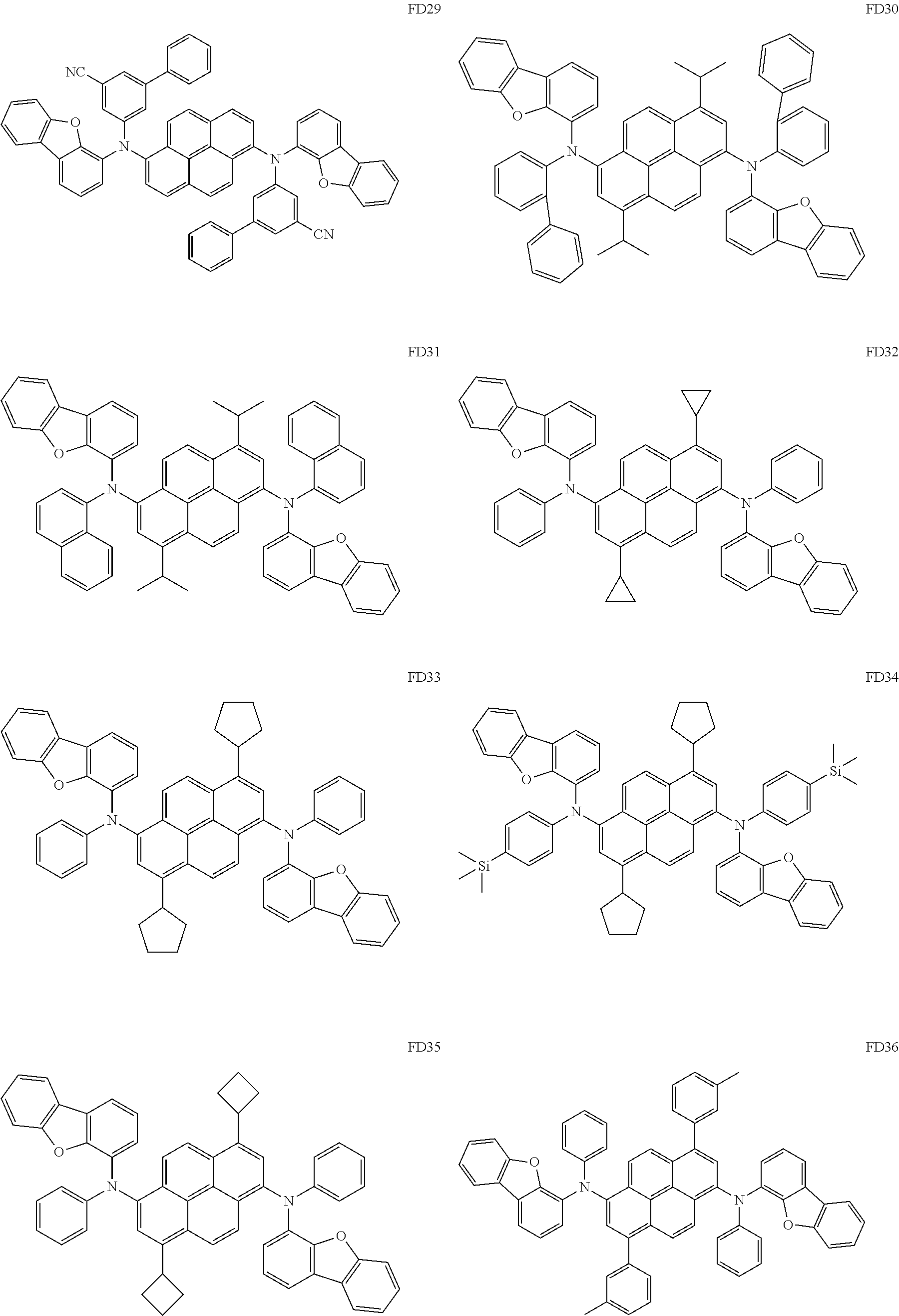

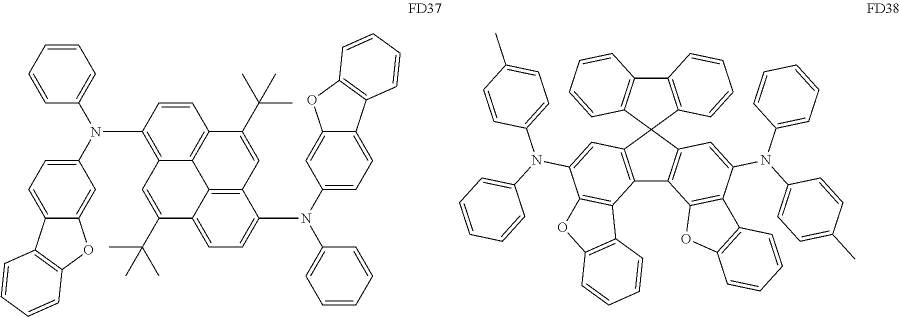 [SMILES: CC(C)(C)c1cc2c(N(c3ccccc3)c3ccc4c(c3)oc3ccccc34)ccc3c(C(C)(C)C)cc4c(N(c5ccccc5)c5ccc6c(c5)oc5ccccc56)ccc1c4c23 ; Cc1ccc(N(c2ccccc2)c2cc3c(c4c2oc2ccccc24)-c2c(cc(N(c4ccccc4)c4ccc(C)cc4)c4c2oc2ccccc24)C32c3ccccc3-c3ccccc32)cc1]

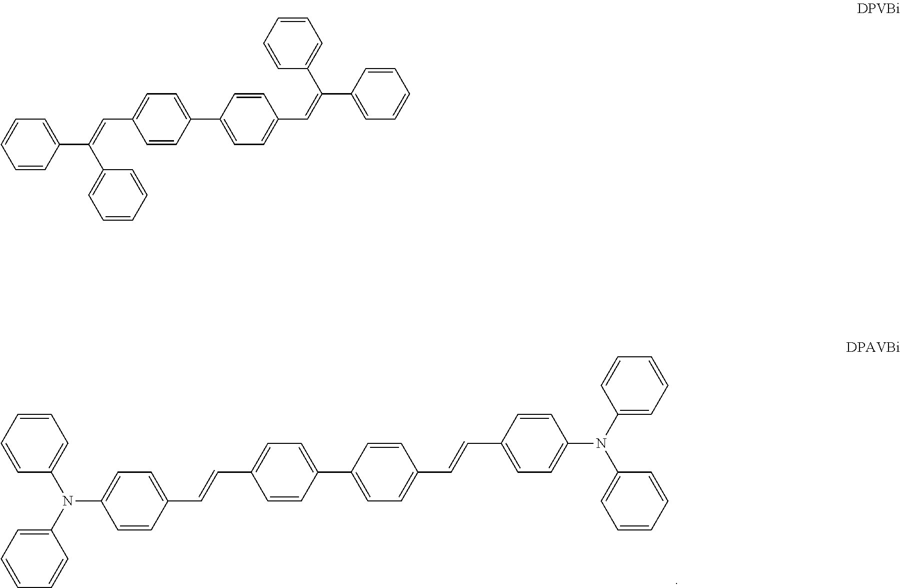

### Delayed Fluorescence Material

The emission layer 130 may include a delayed fluorescence material.

As described herein, the delayed fluorescence material may be selected from compounds capable of emitting delayed fluorescence by a delayed fluorescence emission mechanism.

The delayed fluorescence material included in the emission layer may act as a host or a dopant, depending on the type of other materials included in the emission layer.

In an embodiment, a difference between a triplet energy level (eV) of the delayed fluorescence material and a singlet energy level (eV) of the delayed fluorescence material may be about 0 eV or more and about 0.5 eV or less. When the difference between the triplet energy level (eV) of the delayed fluorescence material and the singlet energy level (eV) of the delayed fluorescence material is satisfied within the ranges above, up-conversion from the triplet state to the singlet state of the delayed fluorescence materials may effectively occur, thereby improving luminescence efficiency or the like of the light-emitting device 10.

For example, the delayed fluorescence material may include: i) a material including at least one electron donor (for example, a π electron-rich C₃-C₆₀ cyclic group and the is like, such as a carbazole group) and at least one electron acceptor (for example, a sulfoxide group, a cyano group, a π electron-deficient nitrogen-containing C₁-C₆₀ cyclic group, and the like); and ii) a material including a C₈-C₆₀ polycyclic group in which two or more cyclic groups are condensed while sharing boron (B).

Examples of the delayed fluorescence material are at least one of Compounds DF 1 to DF9:

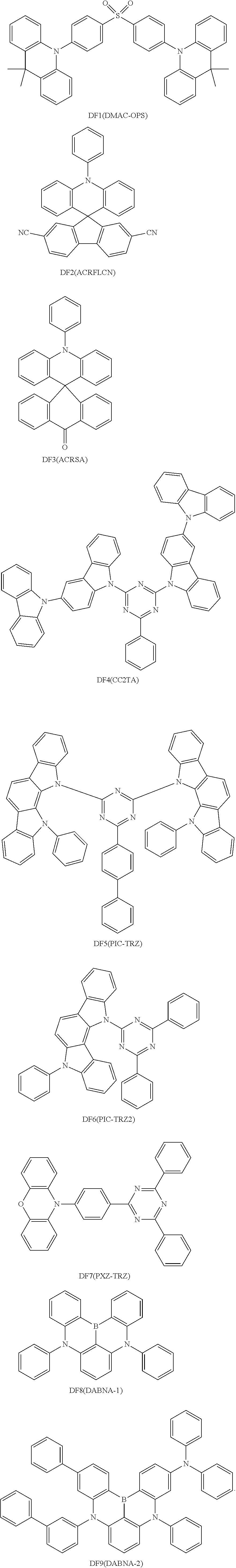

### Quantum Dot

The emission layer 130 may include a quantum dot.

The term “quantum dot” as used herein refers to a crystal of a semiconductor compound, and may include any material capable of emitting light of various emission wavelengths according to the size of the crystal.

A diameter of the quantum dot may be, for example, in a range of about 1 nm to about 10 nm.

The quantum dot may be synthesized by a wet chemical process, a metal organic chemical vapor deposition process, a molecular beam epitaxy process, or any process similar thereto.

The wet chemical process is a method including mixing a precursor material with an organic solvent and then growing a quantum dot particle crystal. When the crystal grows, the organic solvent naturally acts as a dispersant coordinated on the surface of the quantum dot crystal and controls the growth of the crystal so that the growth of quantum dot particles can be controlled through a process which costs lower, and is easier than vapor deposition methods, such as metal organic chemical vapor deposition (MOCVD) or molecular beam epitaxy (MBE),

The quantum dot may include: a Group II-VI semiconductor compound; a Group III-V semiconductor compound; a Group III-VI semiconductor compound; a Group semiconductor compound; a Group IV-VI semiconductor compound; a Group IV element or compound; or any combination thereof.

Examples of the Group II-VI semiconductor compound are: a binary compound, such as CdSe, CdTe, ZnS, ZnSe, ZnTe, ZnO, HgS, HgSe, HgTe, MgSe, MgS, and the like; a ternary compound, such as CdSeS, CdSeTe, CdSTe, ZnSeS, ZnSeTe, ZnSTe, HgSeS, HgSeTe, is HgSTe, CdZnS, CdZnSe, CdZnTe, CdHgS, CdHgSe, CdHgTe, HgZnS, HgZnSe, HgZnTe, MgZnSe, MgZnS, and the like; a quaternary compound, such as CdZnSeS, CdZnSeTe, CdZnSTe, CdHgSeS, CdHgSeTe, CdHgSTe, HgZnSeS, HgZnSeTe, HgZnSTe, and the like; or any combination thereof.

Examples of the Group III-V semiconductor compound are: a binary compound, such as GaN, GaP, GaAs, GaSb, AlN, AlP, AlAs, AlSb, InN, InP, InAs, InSb, and the like; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, and the like; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and the like; or any combination thereof. The Group III-V semiconductor compound may further include a Group II element. Examples of the Group III-V semiconductor compound further including a Group II element are InZnP, InGaZnP, InAlZnP, and the like.

Examples of the Group III-VI semiconductor compound are: a binary compound, such as GaS, GaSe, Ga₂Se₃, GaTe, InS, InSe, In₂S₃, In₂Se₃, InTe, and the like; a ternary compound, such as InGaS₃, InGaSe₃, and the like; or any combination thereof

Examples of the Group I-III-VI semiconductor compound are: a ternary compound, such as AgInS, AgInS₂, CuInS, CuInS₂, CuGaO₂, AgGaO₂, AgAlO₂, and the like; or any combination thereof.

Examples of the Group IV-VI semiconductor compound are: a binary compound, such as SnS, SnSe, SnTe, PbS, PbSe, PbTe, and the like; a ternary compound, such as SnSeS, SnSeTe, SnSTe, PbSeS, PbSeTe, PbSTe, SnPbS, SnPbSe, SnPbTe, and the like; a quaternary compound, such as SnPbSSe, SnPbSeTe, SnPbSTe, and the like; or any combination thereof

The Group IV element or compound may include: a single element compound, is such as Si, Ge, and the like; a binary compound, such as SiC, SiGe, and the like; or any combination thereof.

Each element included in a multi-element compound, such as the binary compound, the ternary compound, and the quaternary compound, may exist in a particle thereof at a uniform concentration or a non-uniform concentration.

The quantum dot may have a single structure or a dual core-shell structure. In the case of the quantum dot having a single structure, a concentration of each element included in the corresponding quantum dot may be uniform. For example, a material included in the core and a material included in the shell may be different from each other.

The shell of the quantum dot may act as a protective layer that prevents chemical degeneration of the core to maintain semiconductor characteristics, and/or as a charging layer that imparts electrophoretic characteristics to the quantum dot. The shell may be a single layer or a multi-layer. The interface between the core and the shell may have a concentration gradient in which the concentration of an element existing in the shell decreases s toward the center of the core.

Examples of the shell of the quantum dot are a metal oxide, a metalloid oxide, a non-metal oxide, a semiconductor compound, or any combination thereof. Examples of the oxide of metal, metalloid, or non-metal are: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and the like; a ternary compound, such as MgAl₂O₄, CoFe₂O₄, NiFe₂O₄, CoMn₂O₄, and the like; or any combination thereof. Examples of the semiconductor compound are: as described herein, a Group II-VI semiconductor compound; a Group III-V semiconductor compound; a Group III-VI semiconductor compound; a Group semiconductor compound; a Group IV-VI semiconductor compound; or any combination thereof. Examples of the semiconductor is compound are CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width of half maximum (FWHM) of an emission wavelength spectrum of the quantum dot may be about 45 nm or less, for example, about 40 nm or less, for example, about 30 nm or less, and within these ranges, color purity or color reproducibility may be increased. In addition, since the light emitted through the quantum dot is emitted in all directions, the wide viewing angle may be improved.

In addition, the quantum dot may be specifically, spherical, pyramidal, multi-arm, or cubic nanoparticles, nanotubes, nanowires, nanofibers, or nanoplate particles.

Since the energy band gap may be adjusted by controlling the size of the quantum dot, light having various wavelength bands may be obtained from the emission layer including the quantum dot. Accordingly, by using quantum dot of different sizes, a light-emitting device that emits light of various wavelengths may be implemented. In detail, the size of the quantum dot may be selected in consideration of emitting red light, green light, and/or blue light. In addition, the size of the quantum dot may be configured to emit white light by combination of light of various colors.

### Hole Transport Region 140

The hole transport region 140 may have: i) a single-layered structure consisting of a single layer consisting of a single material; ii) a single-layered structure consisting of a single layer consisting of a plurality of different materials; or iii) a multi-layered structure including a plurality of layers including different materials.

The hole transport region 140 may include a hole injection layer, a hole transport layer, an emission auxiliary layer, an electron blocking layer, or any combination thereof

For example, the hole transport region 140 may include a multi-layered structure including a hole transport layer/hole injection layer structure, an emission auxiliary layer/hole transport layer/hole injection layer structure, an emission auxiliary layer/hole injection layer structure, an emission auxiliary layer/hole transport layer structure, or an electron blocking layer/hole transport layer/hole injection layer structure, wherein constituent layers of each structure are stacked sequentially from the emission layer 130.

The hole transport region 140 may include a first compound including a first repeating unit represented by Formula 1, a second compound represented by Formula 2, a fifth compound represented by Formula 5, or any combination thereof:

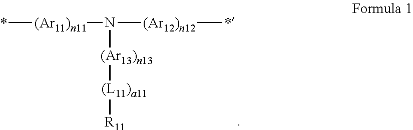

In Formula 1, Ar₁₁ to Ar₁₁ may each independently be a single bond, a C₁-C₆₀ alkylene group unsubstituted or substituted with at least one R₁₀ₐ, a C₂-C₆₀ alkenylene group unsubstituted or substituted with at least one R₁₀ₐ, a C₂-C₆₀ alkynylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ.

In an embodiment,

Ar₁₁ to Ar₁₃ may each independently be a single bond, a C₃-C₁₀ cycloalkylene group unsubstituted or substituted with at least one R₁₀ₐ, a C₁-C₁₀ heterocycloalkylene group unsubstituted or substituted with at least one R₁₀ₐ, a C₃-C₁₀ cycloalkenylene group unsubstituted or substituted with at least one R₁₀ₐ, a C₁-C₁₀ heterocycloalkenylene group unsubstituted or substituted with at least one R₁₀ₐ, a C₆-C₆₀ arylene group unsubstituted or substituted with at least one R₁₀ₐ, a C₁-C₆₀ heteroarylene group unsubstituted or substituted with at least one R₁₀ₐ, a divalent non-aromatic condensed polycyclic group unsubstituted or substituted with at least one is R₁₀ₐ, or a divalent non-aromatic condensed heteropolycyclic group unsubstituted or substituted with at least one R₁₀ₐ, wherein R₁₀ₐ may be the same as described herein.

In one or more embodiments, Ar₁₁ to Ar₁₃ may each independently be:
a single bond; or
a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, an azadibenzothiophene 5,5-dioxide group, is a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group, each unsubstituted or substituted with at least one R₁₀ₐ, and
R₁₀ₐ may be the same as described herein.

In one or more embodiments, Ar₁₁ to Ar₁₃ may each independently be:

a single bond, phenylene, naphthalene, or fluorene; or
phenylene, naphthalene, or fluorene, each substituted with deuterium, a C₁-C₁₀ alkyl group, a phenyl group, or any combination thereof.

In one or more embodiments, Ar₁₁ to Ar₁₃ may each independently be a single bond or one of groups represented by Formulas 1A-1 to 1A-13 and 1B-1 to 1B-10:

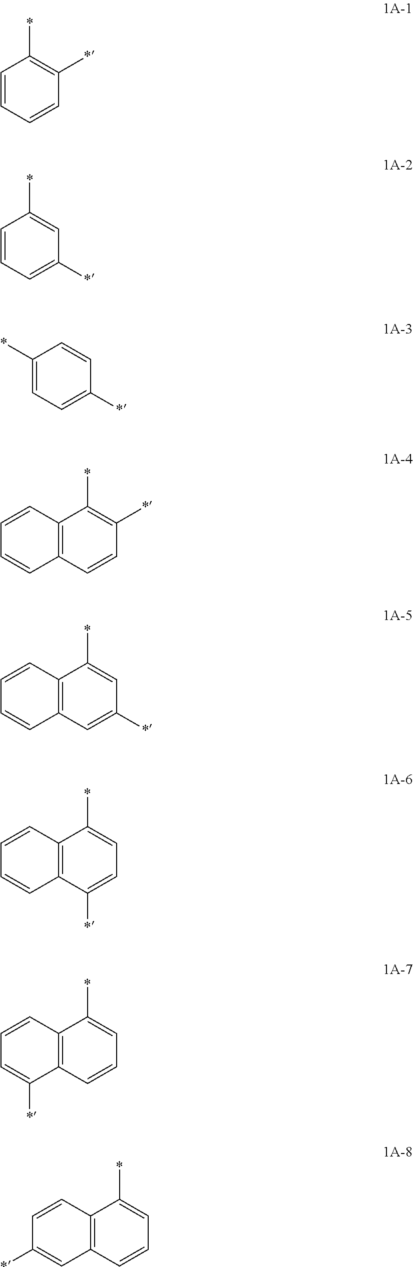

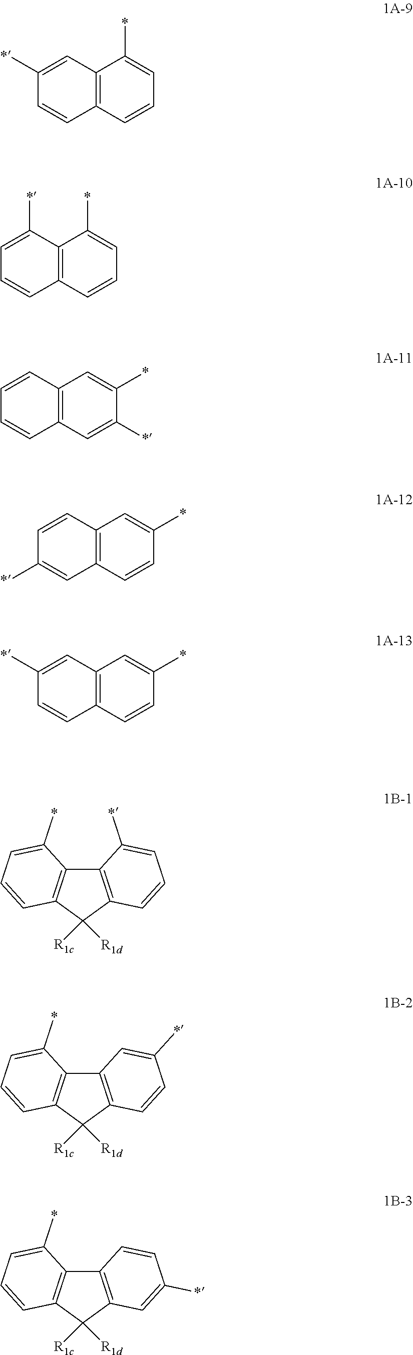

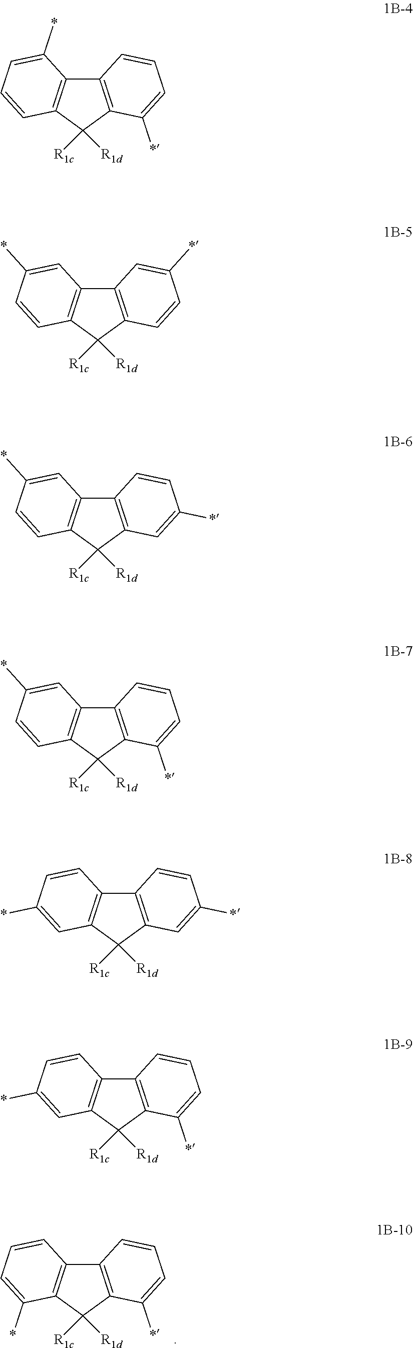

In Formulas 1A-1 to 1A-13 and 1B-1 to 1B-10,

R_{1c}and R_{1d}may each independently be hydrogen, deuterium, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₁-C₆₀ carbocyclic group unsubstituted or substituted with at least one R₁₀ₐ, or a C₁-C₆₀ heterocyclic group unsubstituted or substituted with at least one R₁₀ₐ,
* and *′ each indicate a binding site to a neighboring atom, and
R₁₀ₐ may be the same as described herein.

For example, in Formulas 1B-1 to 1B-10, R_{1c} and R_{1d} may each independently be hydrogen, deuterium, a C₁-C₂₀ alkyl group, a C₁-C₂₀ alkenyl group, a C₁-C₂₀ alkynyl group, a phenyl group, or a naphthyl group.

In Formula 1, n11 to n13 may each independently be an integer from 1 to 10. In an embodiment, Ar₁₁ (s) in the number of n11 may be identical to or different from each other, Ar₁₁ (s) in the number of n12 may be identical to or different from each other, Ar₁₃ (s) in the number of n13 may be identical to or different from each other.

In an embodiment, n11 to n13 may each independently be an integer from 1 to 3.

In Formula 1, L₁₁ may be a single bond, *—C(R₁ₐ)(R_{1b})—*′, *—C(R₁ₐ)═*′, *═C(R₁ₐ)—*′, *—C(R₁ₐ)═C(R_{1b})—*′, *—C(═O)—*′, *—C(═S)—*′, *—C≡C—*′, *—B(R₁ₐ)—*′, *—N(R₁ₐ)—*′, *—O—*′, *—Si(R₁ₐ)(R_{1b})—*′, *—P(═O)(R₁ₐ)—*′, *—S—*′, *—S(═O)—*′, *—S(═O)₂—*′, or *—Ge(R₁ₐ)(R_{1b})—*′, and *′ each indicate a binding site to a neighboring atom, and R₁ₐand R_{1b}may each be the same as described herein.

In an embodiment, L₁₁ may be *—C(R₁ₐ)(R_{1b})—*′, or *—O—*′.

In an embodiment, a moiety represented by (L₁₁)ₐ₁₁ may be a group represented is by Formula 1L:

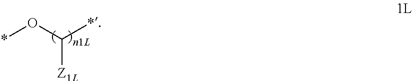

In Formula 1L,

n1L may be an integer from 0 to 10,
Z_{1L} may be hydrogen, deuterium, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, or a C₁-C₆₀ arylthio group unsubstituted or substituted with at least one R₁₀ₐ,
* and *′ each indicate a binding site to a neighboring atom, and
R₁₀ₐ may be the same as described herein.

In an embodiment, n1L may be an integer from 2 to 5.

In an embodiment, Z_{1L} may be hydrogen, deuterium, a C₁-C₁₀ alkyl group, or a phenyl group.

In an embodiment, * indicates a binding site to a moiety represented by (Ar₁₃)ₙ₁₃ in Formula 1 or N in Formula 1, and *′ indicates a binding site to R₁₁ in Formula 1. That is, a bond shown in Formula 1-1L may be formed:

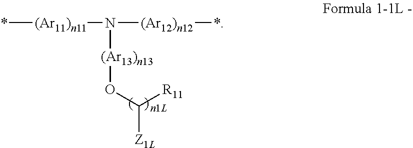

In an embodiment, a11 in Formula 1 may be an integer from 1 to 20.

In one or more embodiments, a11 in Formula 1 may be an integer from 3 to 10.

In an embodiment, R₁₁ in Formula 1 may be a group represented by Formula 1-1, a C₃-C₆₀ carbocyclic group unsubstituted or substituted with at least one R₁₀ₐ, or a C₁-C₆₀ heterocyclic group unsubstituted or substituted with at least one R₁₀ₐ.

In an embodiment, R₁₁ in Formula 1 may be:
a group represented by Formula 1-1; or
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a terphenyl group, a C₁-C₂₀ alkyl phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indenyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzofluorenyl group, a benzocarbazolyl group, a naphthobenzofuranyl group, a naphthobenzothiophenyl group, a naphthobenzosilolyl group, a dibenzofluorenyl group, a dibenzocarbazolyl group, a dinaphthofuranyl group, a dinaphthothiophenyl group, a dinaphthosilolyl group, an indenocarbazolyl group, an indolocarbazolyl group, a benzofuranocarbazolyl group, a benzothienocarbazolyl group, a benzosilolocarbazolyl group, an imidazopyridinyl group, an imidazopyrimidinyl group, an azafluorenyl group, an azacarbazolyl group, an azadibenzofuranyl group, an azadibenzothiophenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a terphenyl group, a C₁-C₂₀ alkyl phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indenyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a is carbazolyl group, a phenanthrolinyl group, a benzimidazolyl group, a benzofuranyl group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzofluorenyl group, a benzocarbazolyl group, a naphthobenzofuranyl group, a naphthobenzothiophenyl group, a naphthobenzosilolyl group, a dibenzofluorenyl group, a dibenzocarbazolyl group, a dinaphthofuranyl group, a dinaphthothiophenyl group, a dinaphthosilolyl group, an indenocarbazolyl group, an indolocarbazolyl group, a benzofuranocarbazolyl group, a benzothienocarbazolyl group, a benzosilolocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof, and
Q₃₁ to Q₃₃ may respectively be the same as described herein.

In an embodiment, R₁₁ in Formula 1 may be a group represented by Formula 1-1:

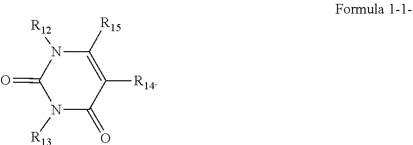

In Formula 1-1, i) R₁₂ may be a binding site to a neighboring atom in Formula 1, and R₁₃ may be hydrogen, or ii) R₁₂ may be hydrogen, and R₁₃ may be a binding site to a neighboring atom in Formula 1.

In an embodiment, in Formula 1-1, R₁₄ and R₁₅ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and

R₁₀ₐ and Q₁ to Q₃ may respectively be the same as described herein.

In one or more embodiments, R₁₄ and R₁₅ may each independently be:

hydrogen, deuterium, —F, —Cl, —Br, —I, a hydroxyl group, a cyano group, a nitro group, a C₁-C₂₀ alkyl group, or a C₁-C₂₀ alkoxy group;

a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a terphenyl group, a naphthyl group, a pyridinyl group, a pyrimidinyl group, or any combination thereof;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a terphenyl group, a C₁-C₂₀ alkyl phenyl group, a naphthyl group, a fluorenyl group, a phenanthrenyl group, an is anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indenyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzofluorenyl group, a benzocarbazolyl group, a naphthobenzofuranyl group, a naphthobenzothiophenyl group, a naphthobenzosilolyl group, a dibenzofluorenyl group, a dibenzocarbazolyl group, a dinaphthofuranyl group, a dinaphthothiophenyl group, a dinaphthosilolyl group, an indenocarbazolyl group, an indolocarbazolyl group, a benzofuranocarbazolyl group, a benzothienocarbazolyl group, a benzosilolocarbazolyl group, an imidazopyridinyl group, an imidazopyrimidinyl group, an azafluorenyl group, an azacarbazolyl group, an azadibenzofuranyl group, an azadibenzothiophenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a terphenyl group, a C₁-C₂₀ alkyl phenyl group, a naphthyl group, a fluorenyl group, a phenanthrenyl group, an anthracenyl group, a fluoranthenyl group, a triphenylenyl group, a pyrenyl group, a chrysenyl is group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indenyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzofluorenyl group, a benzocarbazolyl group, a naphthobenzofuranyl group, a naphthobenzothiophenyl group, a naphthobenzosilolyl group, a dibenzofluorenyl group, a dibenzocarbazolyl group, a dinaphthofuranyl group, a dinaphthothiophenyl group, a dinaphthosilolyl group, an indenocarbazolyl group, an indolocarbazolyl group, a benzofuranocarbazolyl group, a benzothienocarbazolyl group, a benzosilolocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof; or
—Si(Q₁)(Q₂)(Q₃), —N[(L₁₁)_{b11}-Q₁][(L₁₂)_{b12}-Q₂], —B[(L₁₁)_{b11}-Q₁][(L₁₂)_{b12}-Q₂],—(═O)(Q₁), —S(═O)₂(Q₁), or —P(═O)(Q₁)(Q₂), and
Q₁ to Q₃ and Q₃₁ to Q₃₃ may each independently be:
—CH₃, —CD₃, —CD₂H, —CDH₂,—CH₂CH₃, —CD₂CH₃,—CH₂CD₂H, —CH₂CDH₂,—CHDCH₃, —CHDCD₂H, —CHDCDH₂, —CHDCD₃, —CD₂CD₃, —CD₂CD₂H, or —CD₂CDH₂; or
an n-propyl group, an iso-propyl group, an n-butyl group, an isobutyl group, a sec-butyl group, a tert-butyl group, an n-pentyl group, an isopentyl group, a sec-pentyl group, a tert-pentyl is group, a phenyl group, a naphthyl group, a pyridinyl group, a pyrimidinyl group, a pyridazinyl group, a pyrazinyl group, or a triazinyl group, each unsubstituted or substituted with deuterium, a C₁-C₂₀ alkyl group, a phenyl group, a biphenyl group, a pyridinyl group, a pyrimidinyl group, a pyridazinyl group, a pyrazinyl group, a triazinyl group, or any combination thereof

In one or more embodiments, R₁₄ and R₁₅ may each independent.ly be:

hydrogen, deuterium, —F, —Cl, —Br, —I, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a C₁-C₂₀ alkyl group, or any combination thereof;
a phenyl group or a naphthyl group, each unsubstituted or substituted with deuterium, —F, —Cl, —Br, —I, —CD₃, —CD₂H, —CDH₂, —CF₃, —CFH₂, a C₁-C₂₀ alkyl group, a C₁-C₂₀ alkoxy group, or any combination thereof.

In Formula 1, * and *′ each indicate a binding site to a neighboring atom.

In an embodiment, the first compound may be one of Compounds 1-1 to 1-6:

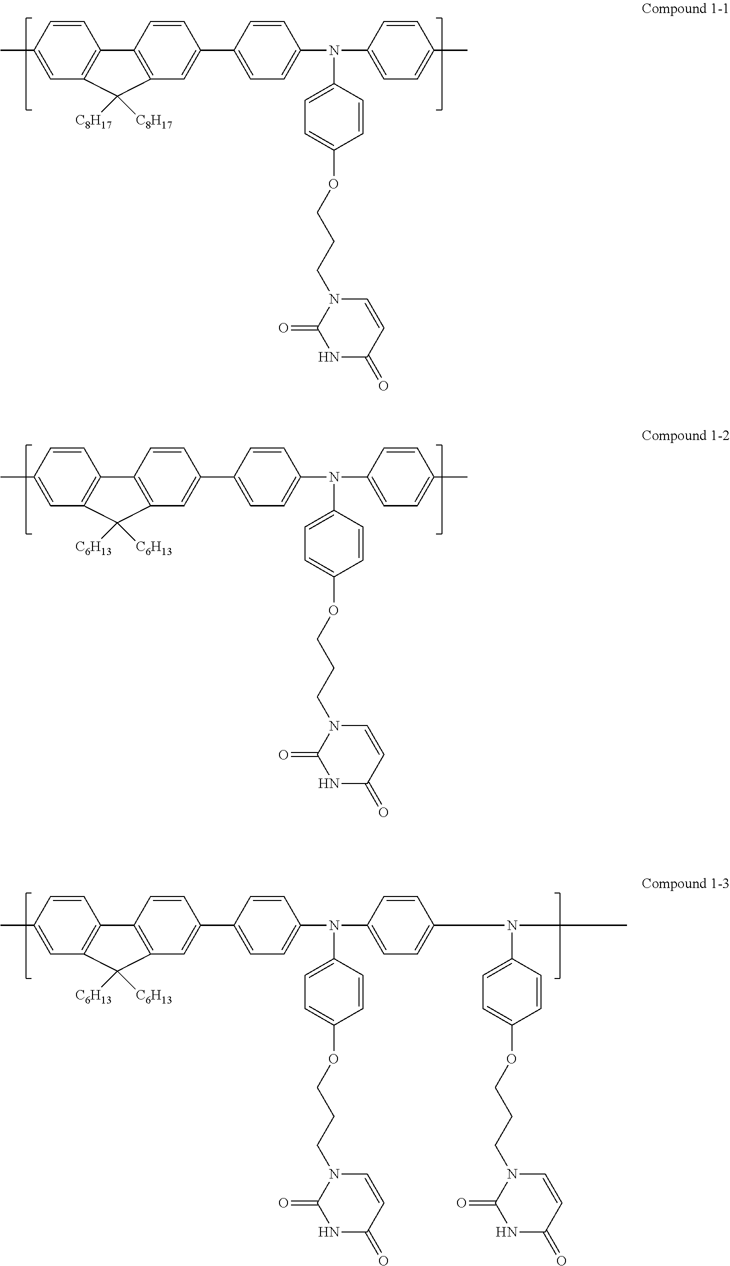

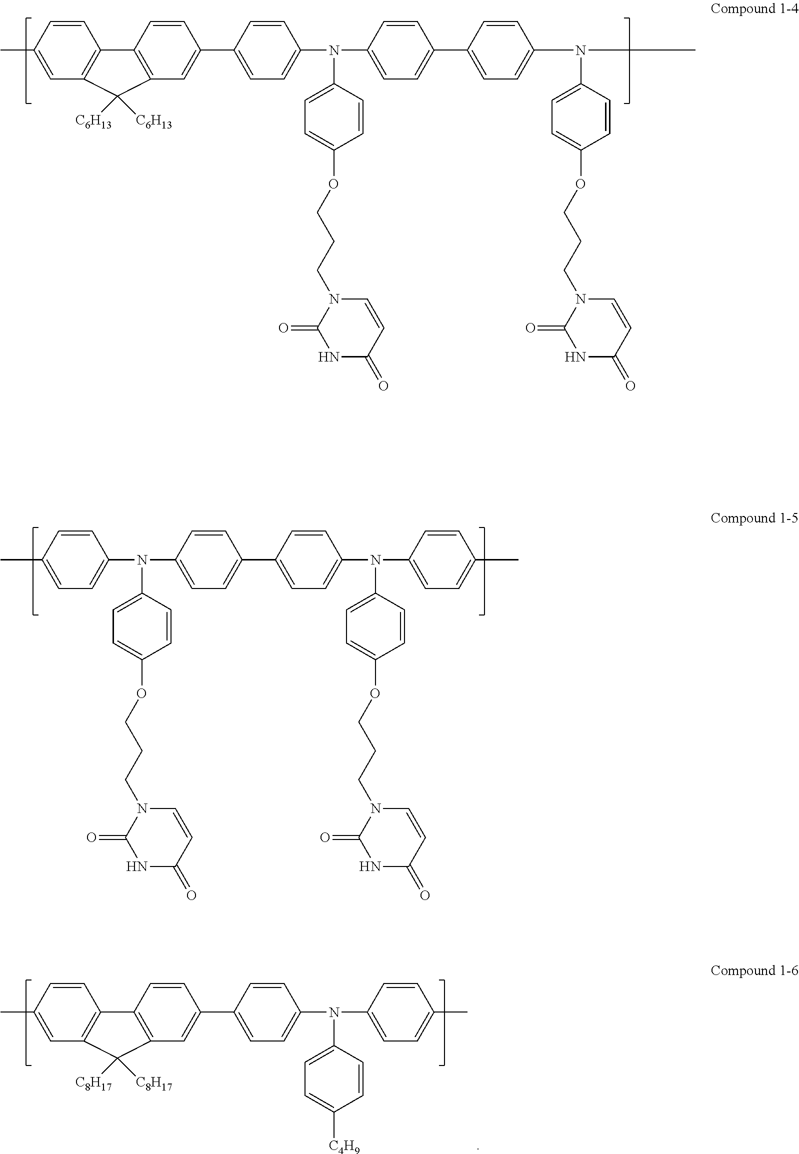

In one or more embodiments, the first compound may not include azaid (—N₃).

In an embodiment, a molecular weight of the first compound may be in a range s of about 400 to about 20,000.

N₃—(Ar₂₁)ₙ₂₁-(L₂₁)ₐ₂₁-(Ar₂₂)ₙ₂₂N₃ Formula 2-

In an embodiment, in Formula 2, Ar₂₁ and Ar₂₂ may each independently be a single bond, a C₁-C₆₀ alkylene group unsubstituted or substituted with at least one R₁₀ₐ, a C₂-C₆₀ alkenylene group unsubstituted or substituted with at least one R₁₀ₐ, a C₂-C₆₀ alkynylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ.

In one or more embodiments, in Formula 2, Ar₂₁ and Ar₂₂ may each is independently be a single bond, a C₃-C₁₀ cycloalkylene group unsubstituted or substituted with at least one R₁₀ₐ, a C₁-C₁₀ heterocycloalkylene group unsubstituted or substituted with at least one R₁₀ₐ, a C₃-C₁₀ cycloalkenylene group unsubstituted or substituted with at least one R₁₀ₐ, a C₁-C₁₀ heterocycloalkenylene group unsubstituted or substituted with at least one R₁₀ₐ, C₆-C₆₀ arylene group unsubstituted or substituted with at least one R₁₀ₐ, a C₁-C₆₀ heteroarylene group unsubstituted or substituted with at least one R₁₀ₐ, a divalent non-aromatic condensed polycyclic group unsubstituted or substituted with at least one R₁₀ₐ, or a divalent non-aromatic condensed heteropolycyclic group unsubstituted or substituted with at least one R₁₀ₐ, and

R₁₀ₐ may be the same as described herein.

In one or more embodiments, in Formula 2, Ar₂₁ and Ar₂₂ may each independently be:
a single bond; or
a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-a fluorene-9-one group, a dibenzothiophene 5,5-dioxide group, an azaindole group, is an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group, each unsubstituted or substituted with at least one R₁₀ₐ, and
R₁₀ₐ may be the same as described herein.

In one or more embodiments, in Formula 2, Ar₂₁ and Ar₂₂ may each independently be:

phenylene or naphthalene; or
phenylene or naphthalene, each substituted with deuterium, —F, or a C₁-C₁₀ alkyl group.

In one or more embodiments, in Formula 2, Ar₂₁ and Ar₂₂ may each independently be one of groups of Formulas 2A-1 to 2A-13:

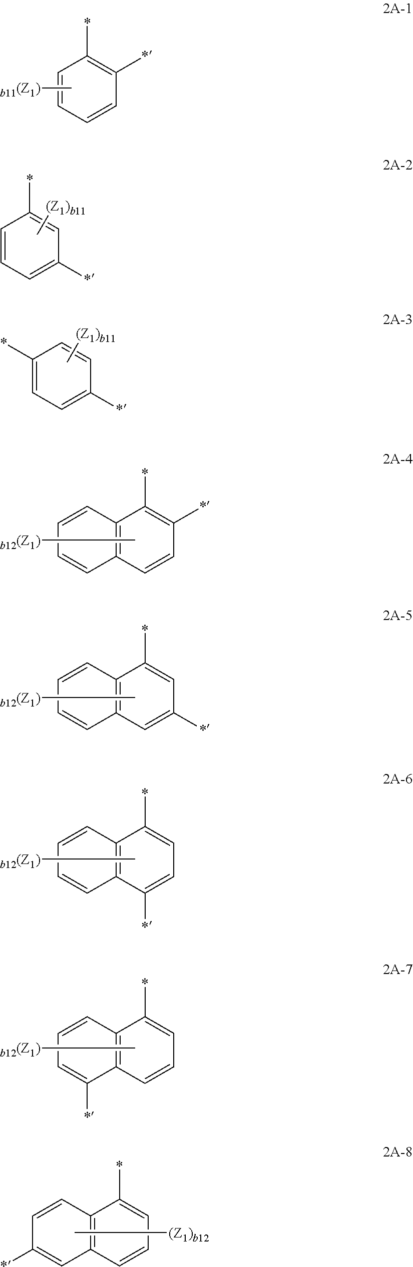

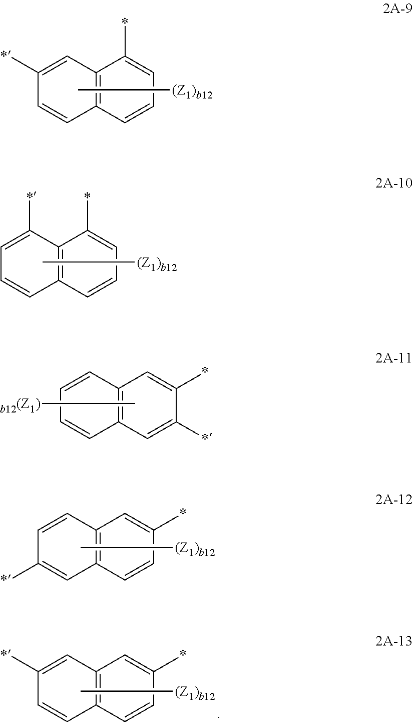

In Formulas 2A-1 to 2A-13,
Z₁ may be hydrogen, deuterium, —F, —Cl, —Br, —I, a hydroxyl group, a cyano group, or a nitro group,
b11 may be an integer from 1 to 4,
b12 may be an integer from 1 to 6, and
* and *′ each indicate a binding site to a neighboring atom.

In an embodiment, in Formula 2, n21 and n22 may each independently be an integer from 1 to 10.

In one or more embodiments, in Formula 2, n21 and n22 may each independently be an integer from 1 to 3.

In an embodiment, L₁₁ in Formula 1 may be a single bond, *—C(R₁ₐ)(R_{1b})—*′, *═C(R₁ₐ)—*′, *′C(R₁ₐ)—*′, *—C(R₁ₐ)═C(R_{1b})—*′, *—C(═O)—*′, *—C(═S)—*′, —C≡C—*′, *B(R₁ₐ)—*′, *—N(R₁ₐ)—*′, *—O—*′, *—P(═O)(R₁ₐ)—*′, *—S—*′, *—S(═O)—*′, *—S(═O)₂—*′, or *—Ge(R₁ₐ)(R_{1b})—*′, wherein * and *′ each indicate a binding site to a neighboring atom, and R₁ₐ and R_{1b} may respectively be the same as described herein.

In one or more embodiments, L₂₁ in Formula 2 may be a single bond, *—C(R₁ₐ)(R_{1b})—*′, *—C(R₁ₐ)═*′, *′═C(R₁ₐ)—*′, *—C(R₁ₐ)═C(R_{1b})—*′, *—C(═O)—*′, or *—O—*′.

In Formula 2, a21 may be an integer from 1 to 20.

In one or more embodiments, L₂₁ in Formula 2 may be a single bond, *—C(R₁ₐ)(R_{1b})—*′, *—C(═O)—*′, or *—O—*′, and a21 in Formula 2 may be an integer from 1 to 10.

In an embodiment, R₁ₐ and R_{1b} may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and

R₁₀ₐ and Q₁ to Q₃ may respectively be the same as described herein.

In one or more embodiments, R₁ₐ and R_{1b} may each independently be:
hydrogen, deuterium, —F, —Cl, —Br, —I, a hydroxyl group, a cyano group, a nitro group, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a terphenyl group, a naphthyl group, a pyridinyl group, a pyrimidinyl group, or any combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a terphenyl group, a C₁-C₂₀ alkyl phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indenyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl is group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzofluorenyl group, a benzocarbazolyl group, a naphthobenzofuranyl group, a naphthobenzothiophenyl group, a naphthobenzosilolyl group, a dibenzofluorenyl group, a dibenzocarbazolyl group, a dinaphthofuranyl group, a dinaphthothiophenyl group, a dinaphthosilolyl group, an indenocarbazolyl group, an indolocarbazolyl group, a benzofuranocarbazolyl group, a benzothienocarbazolyl group, a benzosilolocarbazolyl group, an imidazopyridinyl group, an imidazopyrimidinyl group, an azafluorenyl group, an azacarbazolyl group, an azadibenzofuranyl group, an azadibenzothiophenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a terphenyl group, a C₁-C₂₀ alkyl phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indenyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a is carbazolyl group, a phenanthrolinyl group, a benzimidazolyl group, a benzofuranyl group, a benzothiophenyl group, a benzosilolyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a dibenzosilolyl group, a benzofluorenyl group, a benzocarbazolyl group, a naphthobenzofuranyl group, a naphthobenzothiophenyl group, a naphthobenzosilolyl group, a dibenzofluorenyl group, a dibenzocarbazolyl group, a dinaphthofuranyl group, a dinaphthothiophenyl group, a dinaphthosilolyl group, an indenocarbazolyl group, an indolocarbazolyl group, a benzofuranocarbazolyl group, a benzothienocarbazolyl group, a benzosilolocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof; or
—Si(Q₁)(Q₂)(Q₃), —N[(L₁₁)_{b11}-Q₁][(L₁₂)_{b12}-Q₂], —B[(L₁₁)_{b11}-Q₁][(L₁₂)_{b12}-Q₂], —C(═O)(Q₁), —S(═O)₂(Q₁), or —P(═O)(Q₁)(Q₂), and
Q₁ to Q₃ and Q₃₁ to Q₃₃ may each independently be:
—CH₃, —CD₃, —CD₂H, —CDH₂,—CH₂CH₃, —CD₂CH₃,—CH₂CD₂H, —CH₂CDH₂, —CHDCH₃,—CHDCD₂H,—CHDCDH₂, —CHDCD₃, —CD₂CD₃, —CD₂CD₂H, or —CD₂CDH₂; or
an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with deuterium, a C₁-C₆₀ alkyl group, a phenyl group, a biphenyl group, a pyridinyl group, a pyrimidinyl group, a pyridazinyl group, a pyrazinyl group, a triazinyl group, or any combination thereof.

In one or more embodiments, R₁ₐ and R_{1b} may each independently be: hydrogen, deuterium, —F, —Cl, —Br, —I, a C₁-C₂₀ alkyl group, or a C₁-C₂₀ alkoxy group; a C₁-C₂₀ alkyl group or a C₁-C₂₀ alkoxy group, each substituted with deuterium, —F, —Cl, —Br, —I, —CD₃, —CD₂H, —CDH₂,—CF₃, —CFH₂, a C₁-C₂₀ alkyl group, or any combination thereof; or a phenyl group or a naphthyl group, each unsubstituted or substituted with deuterium, —F, —Cl, —Br, —I, —CD₃, —CD₂H, —CDH₂,—CF₃, —CFH₂, a C₁-C₂₀ alkyl group, a C₁-C₂₀ alkoxy group, or any combination thereof.

In an embodiment, the second compound may be one of Compounds 2-1 to 2-3:

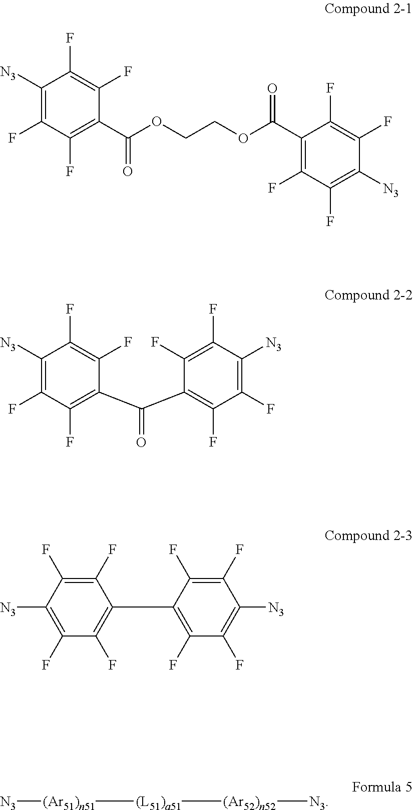

In an embodiment, in Formula 5, Ar₅₁ and Ar₅₂ may each independently be a single bond, a C₁-C₆₀ alkylene group unsubstituted or substituted with at least one R₁₀ₐ, a C₂-C₆₀ alkenylene group unsubstituted or substituted with at least one R₁₀ₐ, a C₂-C₆₀ alkynylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ, and R₁₀ₐ may be the same as described herein.

In one or more embodiments, Ar₅₁ and Ar₅₂ may each independently be a single bond or a C₁-C₆₀ alkylene group unsubstituted or substituted with at least one R₁₀ₐ, and R₁₀ₐ may be the same as described herein.

In an embodiment, in Formula 5, n51 and n52 may each independently be an integer from 1 to 10.

In Formula 5, L₅₁ may be the first repeating unit represented by Formula 1:

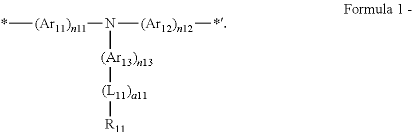

In Formula 1, Ar₁₁ to Ar₁₃n11 to n13, L₁₁, a11, and R₁₁ may respectively be the same as described herein.

In an embodiment, a51 in Formula 5 may be an integer from 1 to 20.

In one or more embodiments, a51 in Formula 5 may be an integer from 1 to 3.

In an embodiment, the fifth compound may be represented by Formula 5-1:

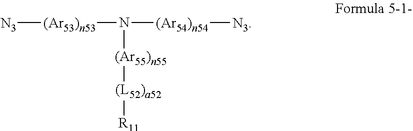

In Formula 5-1, Ar₅₃ to Ar₅₅ may each independently be a single bond, a C₁-C₆₀ alkylene group unsubstituted or substituted with at least one R₁₀ₐ, a C₂-C₆₀ alkenylene group unsubstituted or substituted with at least one R₁₀ₐ, a C₂-C₆₀ alkynylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ, and R₁₀ₐ may be the same as described herein.

In an embodiment, Ar₅₃ to Ar₅₅ may each independently be:

a single bond, phenylene, naphthalene, or fluorene; or
phenylene, naphthalene, or fluorene, each substituted with deuterium, —F, a C₁-C₁₀ alkyl group, a phenyl group, or any combination thereof.

In one or more embodiments, Ar₅₃ to Ar₅₅ may each independently be a single bond or one of groups represented by Formulas 5A-1 to 5A-13 and 5B-1 to 5B-10:

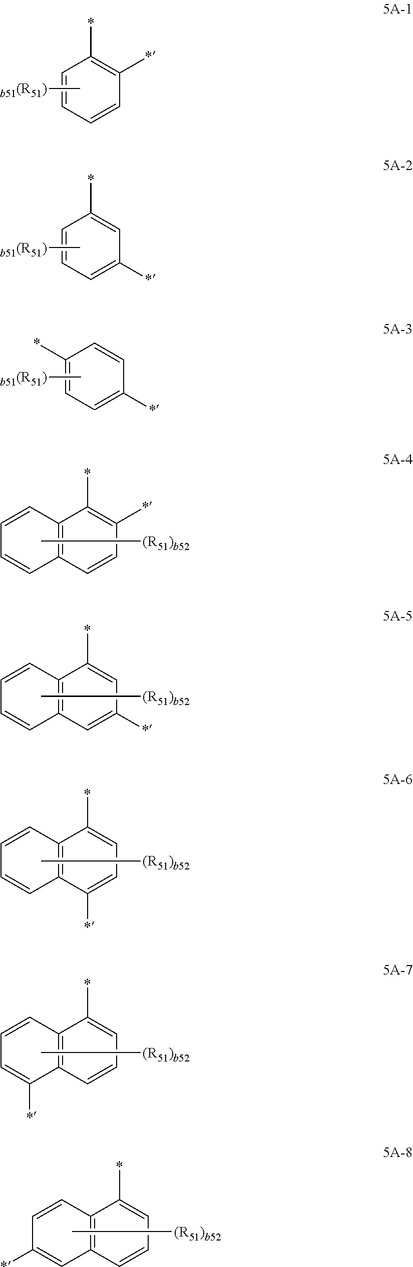

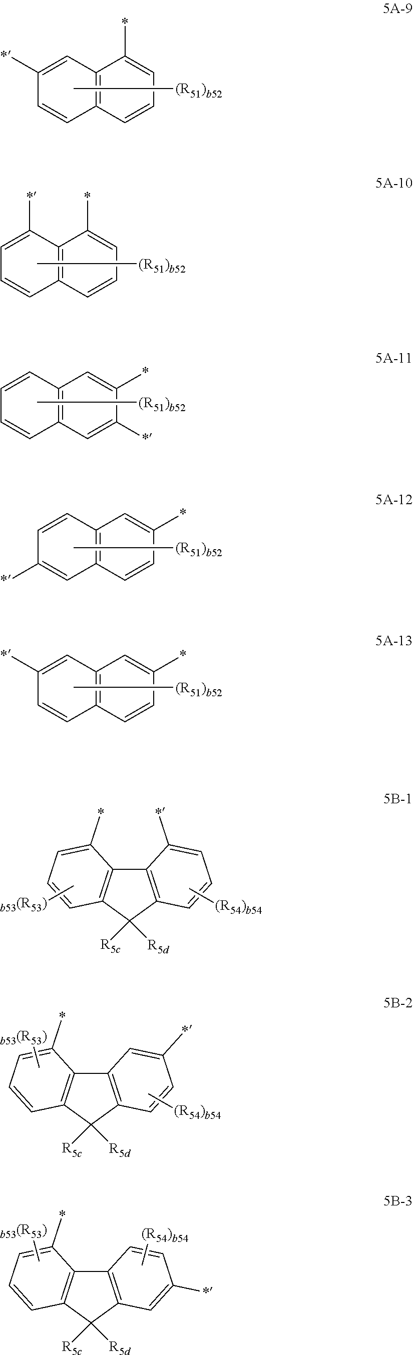

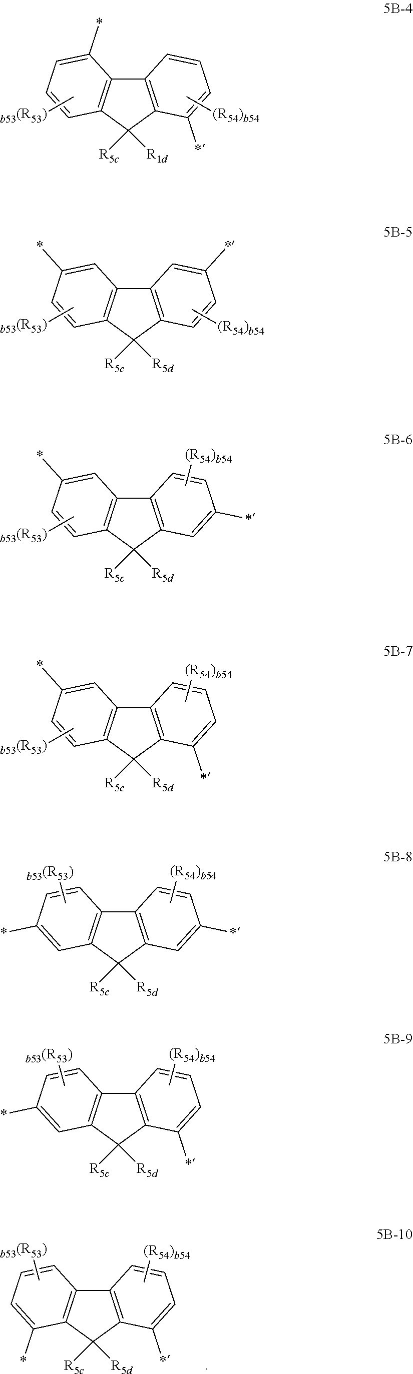

In Formulas 5A-1 to 5A-13 and 5B-1 to 5B-10,

R_{5c} and R_{5d} may each independently be hydrogen, deuterium, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,

R₅₁, R₅₃, and R₅₄ may each independently be deuterium, —F, —Cl, —Br, —I, or a C₁-C₁₀ alkyl group,
b51 may be an integer from 0 to 4,
b52 may be an integer from 0 to 6,
b53 and b54 may each independently an integer from 0 to 3,
* and *′ each indicate a binding site to a neighboring atom, and
R₁₀ₐ may be the same as described herein.

For example, in Formulas 5B-1 to 5B-10, R₅ and R_{5d} may each independently be hydrogen, deuterium, a C₁-C₂₀ alkyl group, a C₂-C₂₀ alkenyl group, a C₂-C₂₀ alkynyl group, a phenyl group, or a naphthyl group.

In Formula 5-1, n53 to n55 may each independently be an integer from 1 to 10. In an embodiment, Ars3(s) in the number of n53 may be identical to or different from each other, Ar₅₄(s) in the number of n54 may be identical to or different from each other, Ar₅₅(s) in the number of n55 may be identical to or different from each other.

In Formula 5-1, L₅₂ may be a single bond, *—C(R₁ₐ)(R_{1b})—*′, *—C(R₁ₐ)═*′, *═C(R₁ₐ)—*′, *—CR₁ₐ)═CR_{1b})—*′, *—C(═O)—*′, *—C(═S)—*′, *—C≡C—*′, *—B(R₁ₐ)—*′, *—N(R₁ₐ)—*′, —O—*′, *—P(R₁ₐ)—*′, *—Si(R₁ₐ)(R_{1b})—*′, *—P(═O)(R₁ₐ)—*′, *—S—*′, *—S(═O)—*′, *—S(═O)₂-*′, or *—Ge(R₁ₐ)(R_{1b})—*′, * and *′ each indicate a binding site to a neighboring atom, and R₁ₐ and R_{1b} may each be the same as described herein.

In an embodiment, L₅₂ may be *—C(R₁ₐ)(R_{1b})—*′ or *—O—*′.

In an embodiment, a moiety represented by (L₅₂)ₐ₅₂ may be a group represented is by Formula 1L:

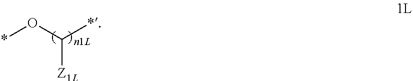

In Formula 1L, n1L and Z_{1L} may respectively be the same as described herein.

In Formula 5-1, R₁₁ may be a group represented by Formula 1-1, a C₃-C₆₀ carbocyclic group unsubstituted or substituted with at least one R₁₀ₐ, or a C₁-C₆₀ heterocyclic group unsubstituted or substituted with at least one R₁₀ₐ.

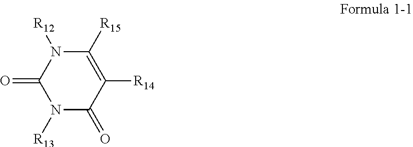

In Formula 1-1, i) R₁₂ may be a binding site to a neighboring atom in Formula 1, and R₁₃ may be hydrogen, or ii) R₁₂ may be hydrogen, and R₁₃ may be a binding site to a neighboring atom in Formula 1.

In an embodiment, in Formula 1-1, R₁₄ and R₁₅ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and

R₁₀ₐ and Q₁ to Q₃ may respectively be the same as described herein.

In an embodiment, R₁₁ in Formula 5-1 may be a group represented by Formula

In an embodiment, the fifth compound may be Compound 5-1:

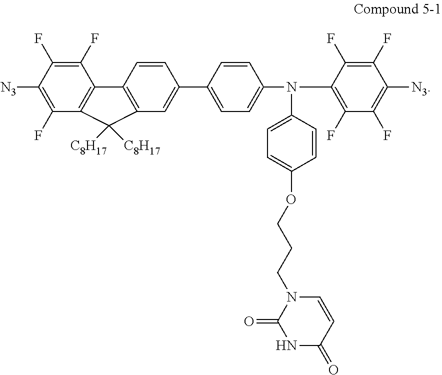

The light-emitting device according to an embodiment of the present disclosure has an inverted structure in which an organic layer consists of a substrate, a cathode, an electron transport region, an emission layer, a hole transport region, and an anode that are sequentially formed, wherein the hole transport region includes a first compound including a first repeating unit represented by Formula 1, a compound represented by Formula 2, a first compound represented by Formula 5, or any combination thereof.

When the hole transport region includes the first compound, the second compound, the fifth compound, or any combination thereof, low-temperature thermal curing or low-temperature photocuring may occur, thereby minimizing thermal decomposition of the emission layer that may occur during high-temperature thermal curing.

In addition, the light-emitting device having such an inverted structure may include an electron transport region including a third compound that is a metal oxide, and the hole transport region including the first compound, the second compound, the fifth compound, or is any combination thereof, thereby exhibiting excellent efficiency characteristics and long lifespan characteristics.

The hole transport region may include a compound represented by Formula 201, a compound represented by Formula 202, or any combination thereof:

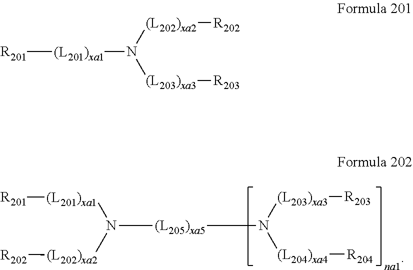

In Formulas 201 and 202,

L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)—*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be bonded to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (for example, a carbazole group or the like) unsubstituted or substituted with at least one R₁₀ₐ (for example, Compound HT16),
R₂₀₃ and R₂₀₄ may optionally be bonded to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

For example, each of Formulas 201 and 202 may include at least one of groups represented by Formulas CY201 to CY217:

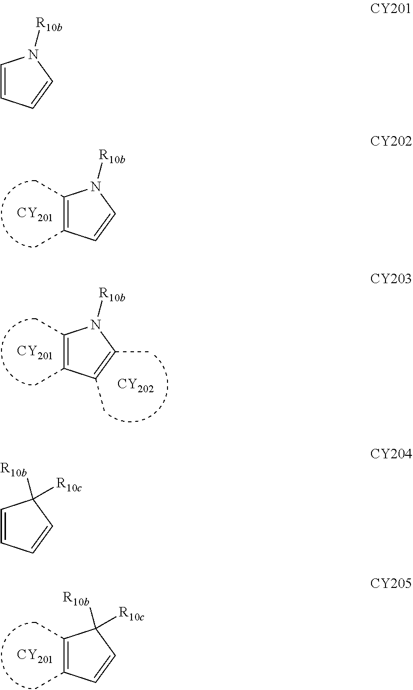

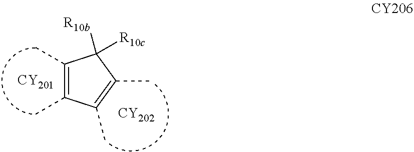

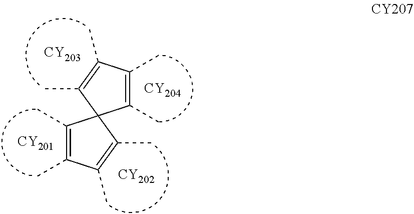

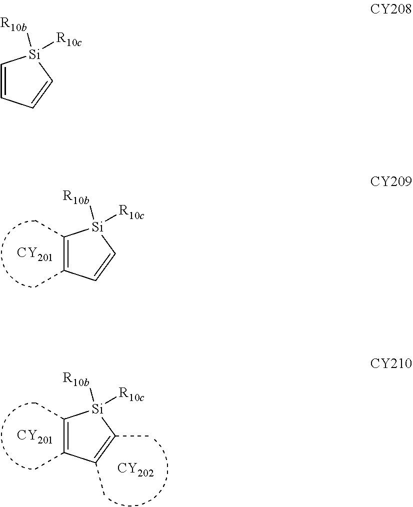

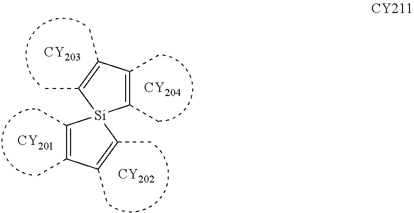

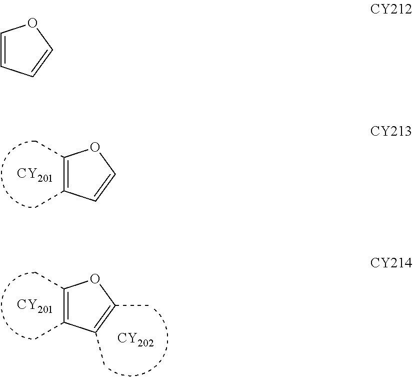

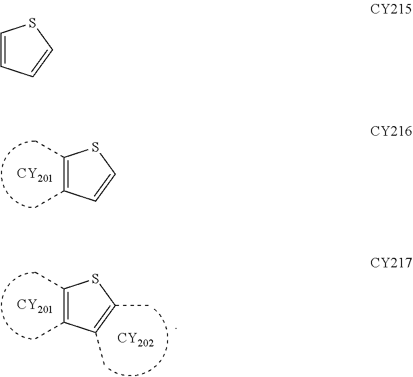

In Formulas CY201 to CY217, R_{10b} and R_{10c} may each be the same as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described above.

In an embodiment, ring CY₂₀₁ to ring CY₂₀₄ in Formulas CY201 to CY217 may each independently be a benzene group, a naphthalene group, a phenanthrene group, or an anthracene group.

In one or more embodiments, each of Formulas 201 and 202 may include at least one of groups represented by Formulas CY201 to CY203.

In one or more embodiments, Formula 201 may include at least one of groups represented by Formulas CY201 to CY203 and at least one of groups represented by Formulas CY204 to CY217.

In one or more embodiments, in Formula 201, xa1 may be 1, R₂₀₁ may be a group represented by one of Formulas CY201 to CY203, xa2 may be 0, and R₂₀₂ may be a group represented by one of Formulas CY204 to CY207.

In one or more embodiments, each of Formulas 201 and 202 may not include groups represented by Formulas CY201 to CY203.

In one or more embodiments, each of Formulas 201 and 202 may not include groups represented by Formulas CY201 to CY203, and may include at least one of groups represented by Formulas CY204 to CY217.

In one or more embodiments, each of Formulas 201 and 202 may not include groups represented by Formulas CY201 to CY217.

For example, the hole transport region may include one of Compounds HT1 to HT46, m-MTDATA, TDATA, 2-TNATA, NPB(NPD), TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/C SA), polyaniline/poly(4-styrenesulfonate) (PANT/PS S), or any combination thereof:

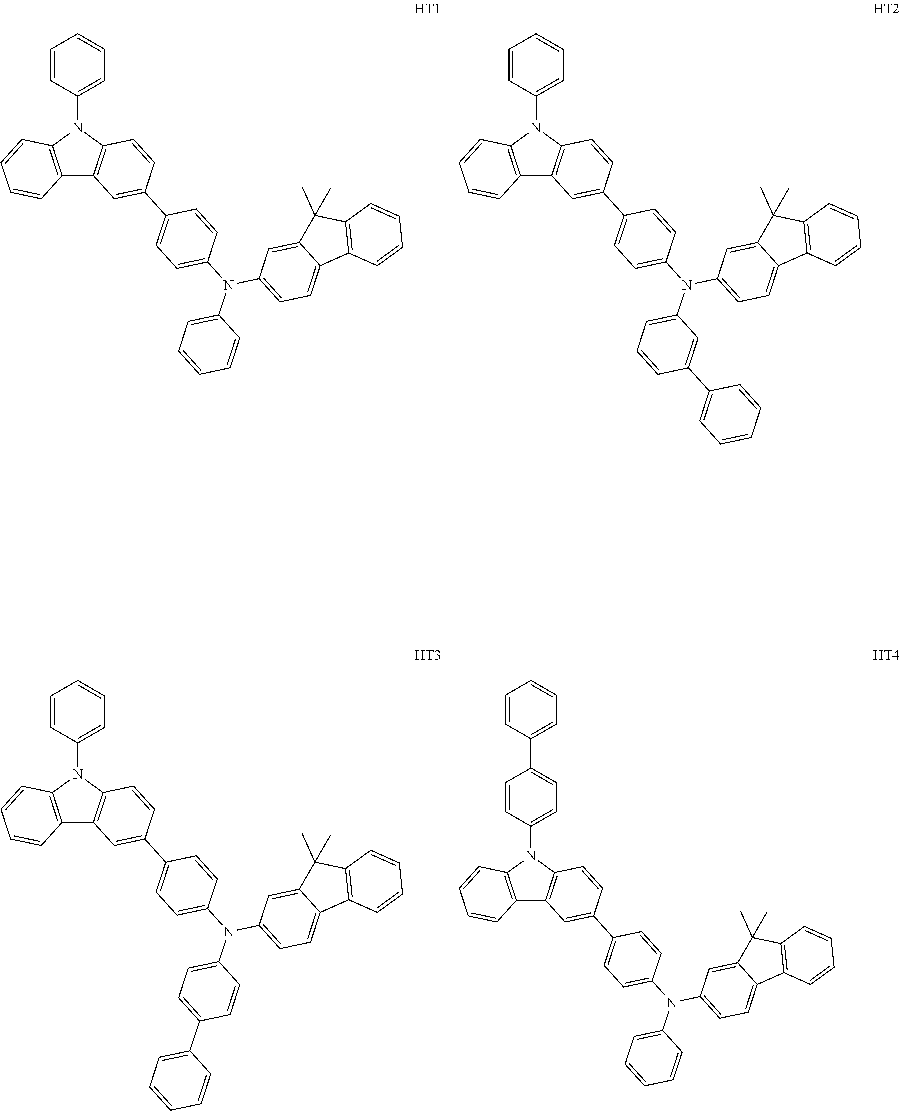 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

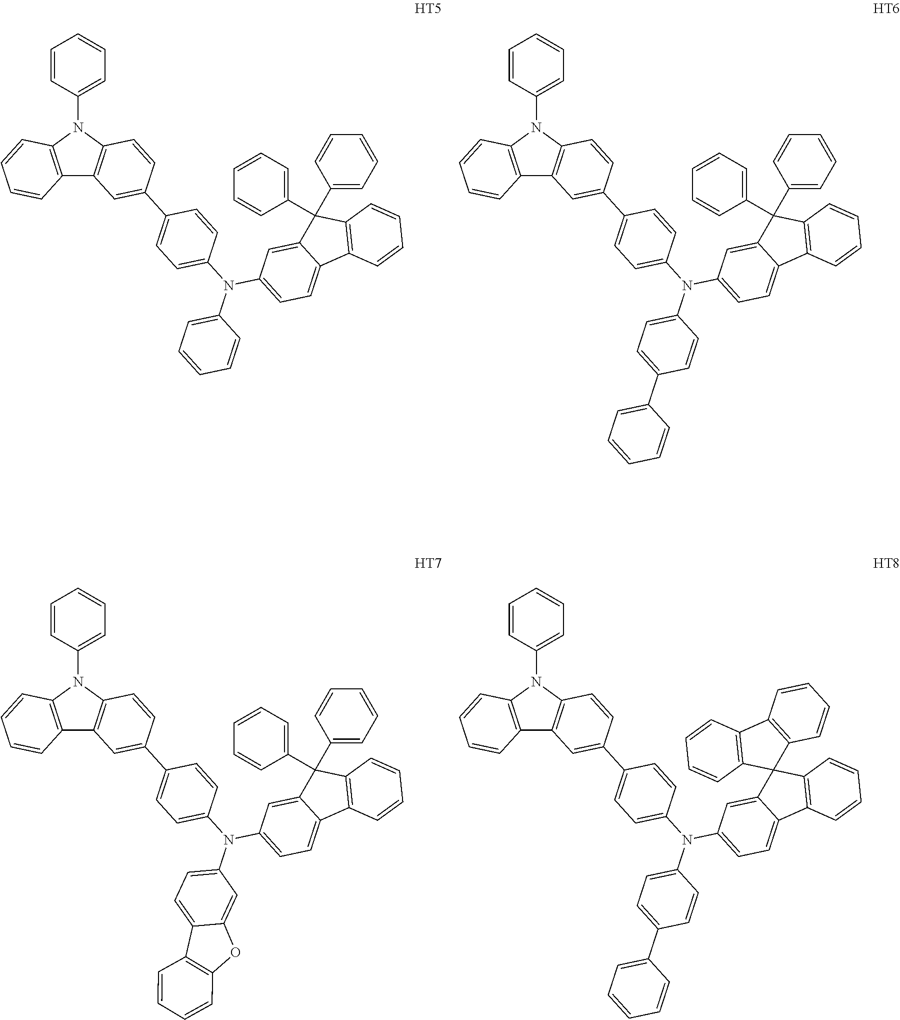 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

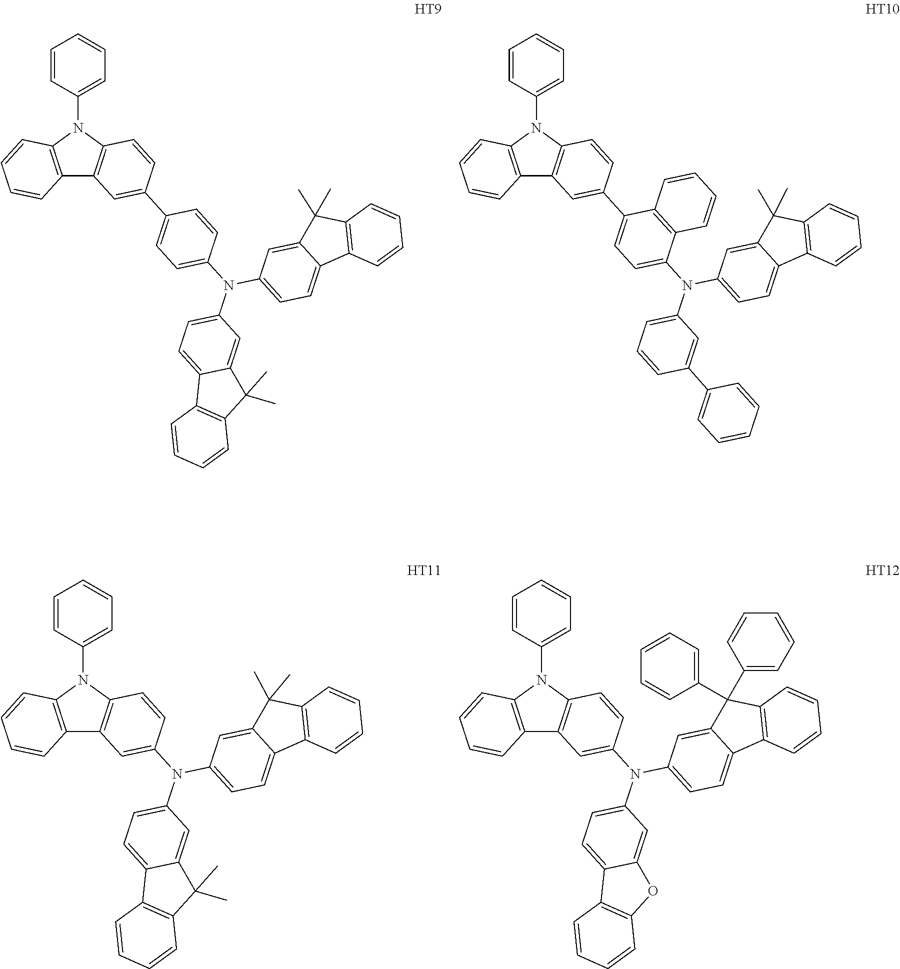 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

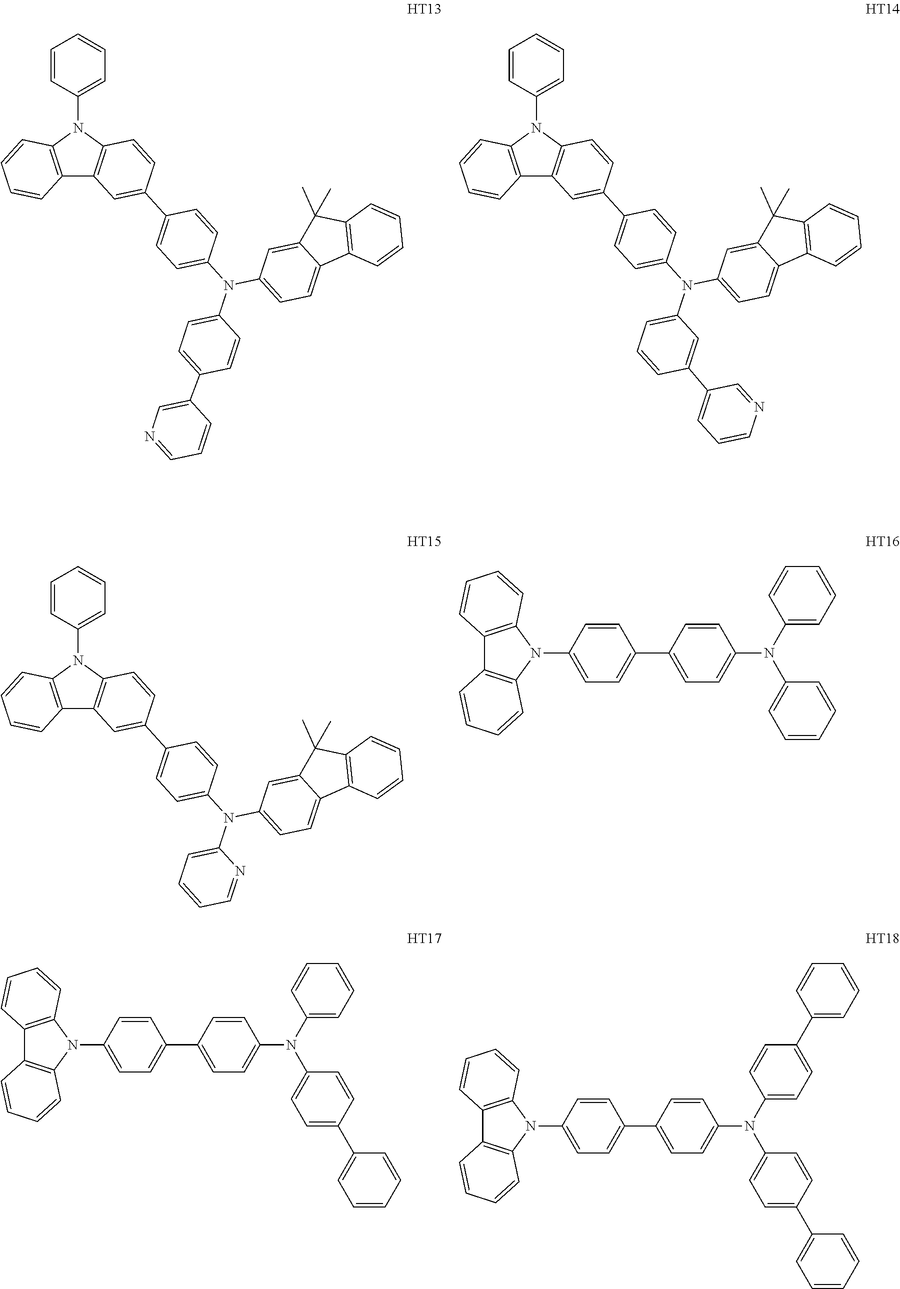 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

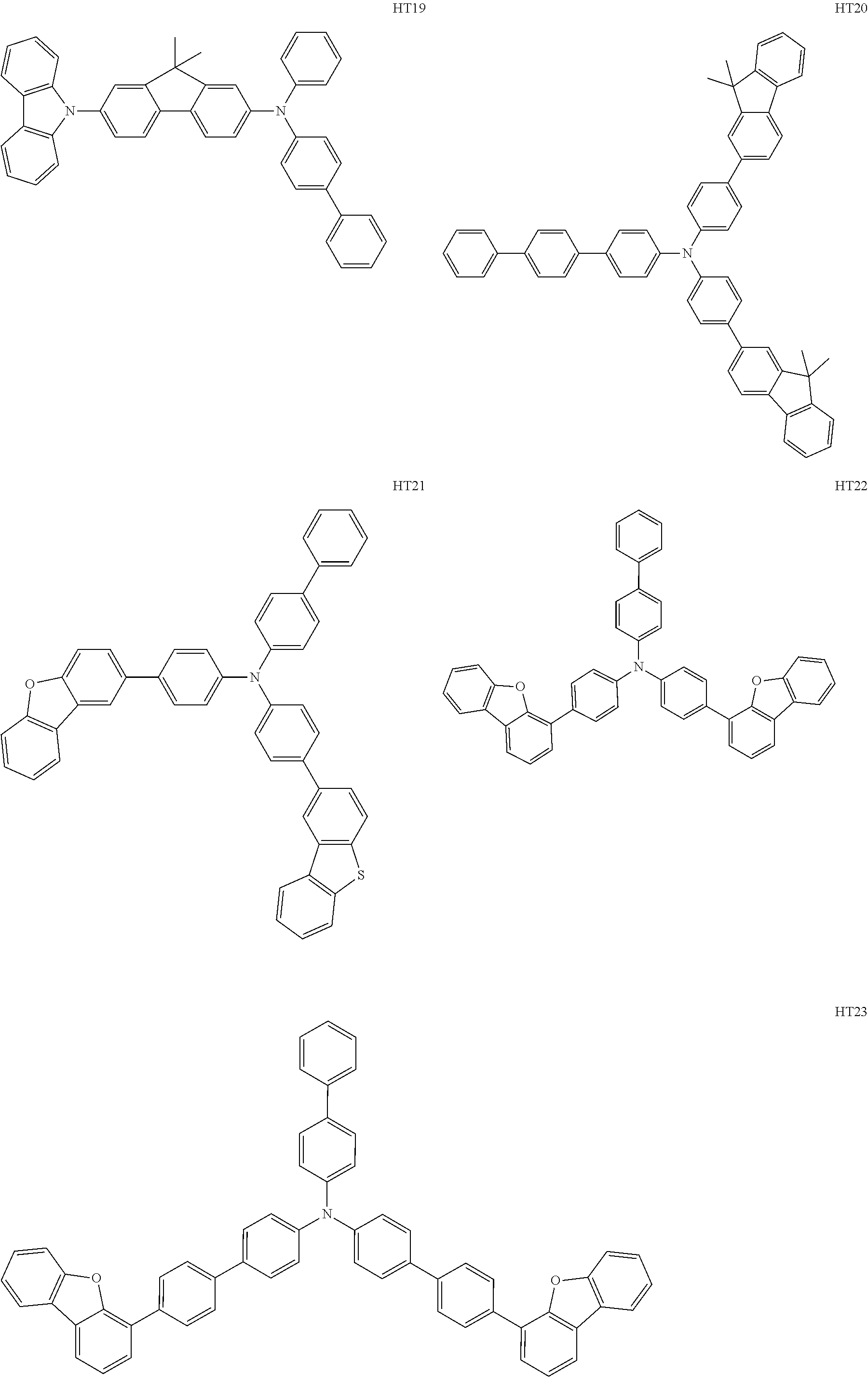 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

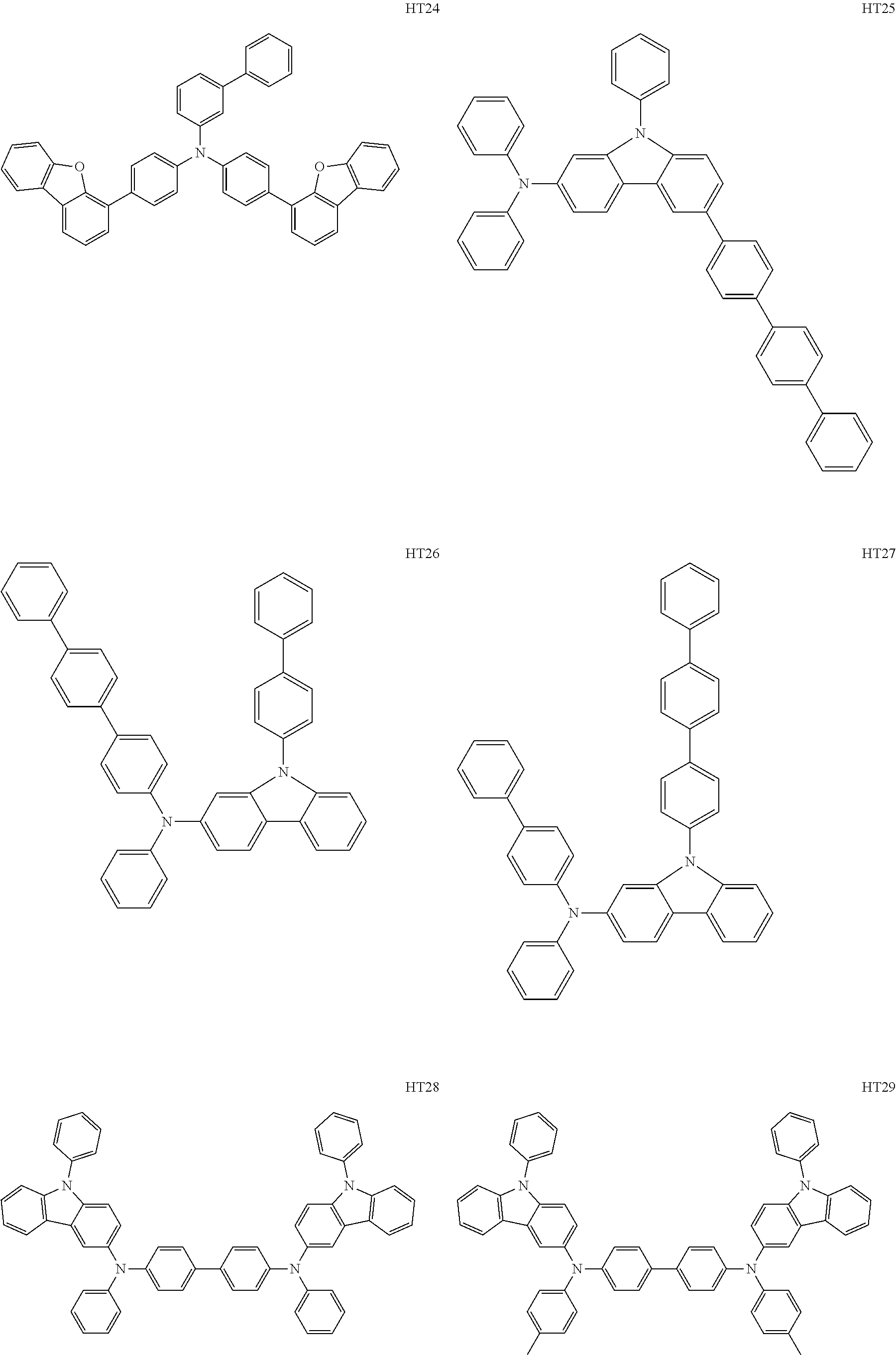

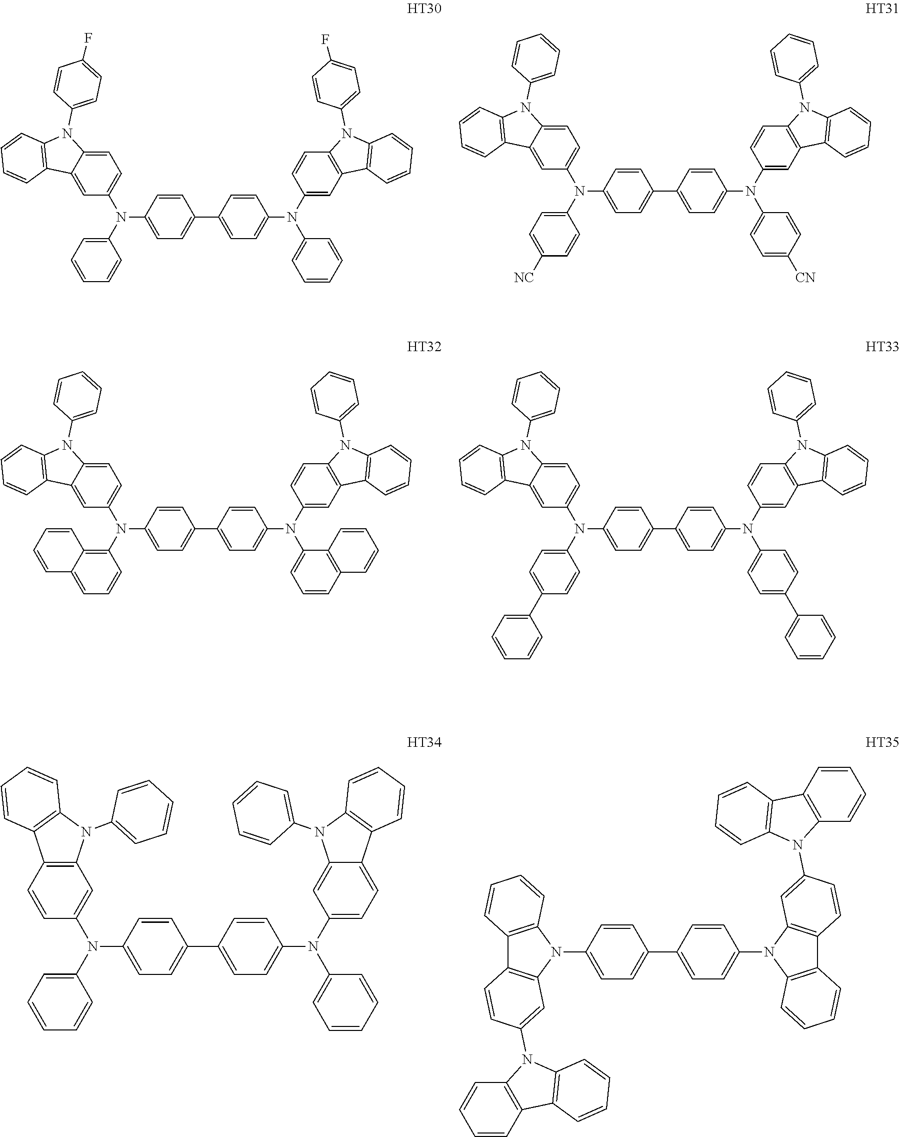

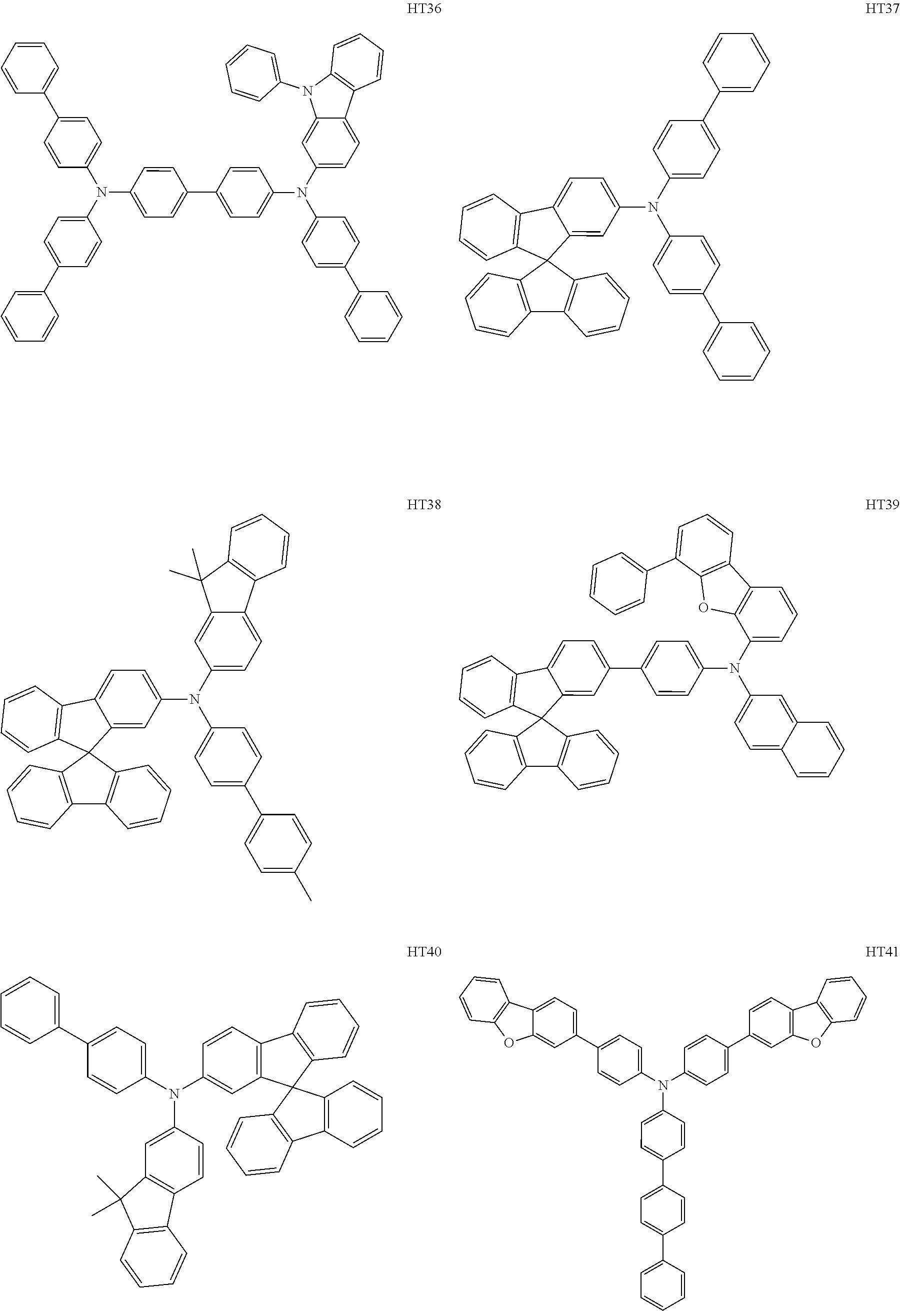

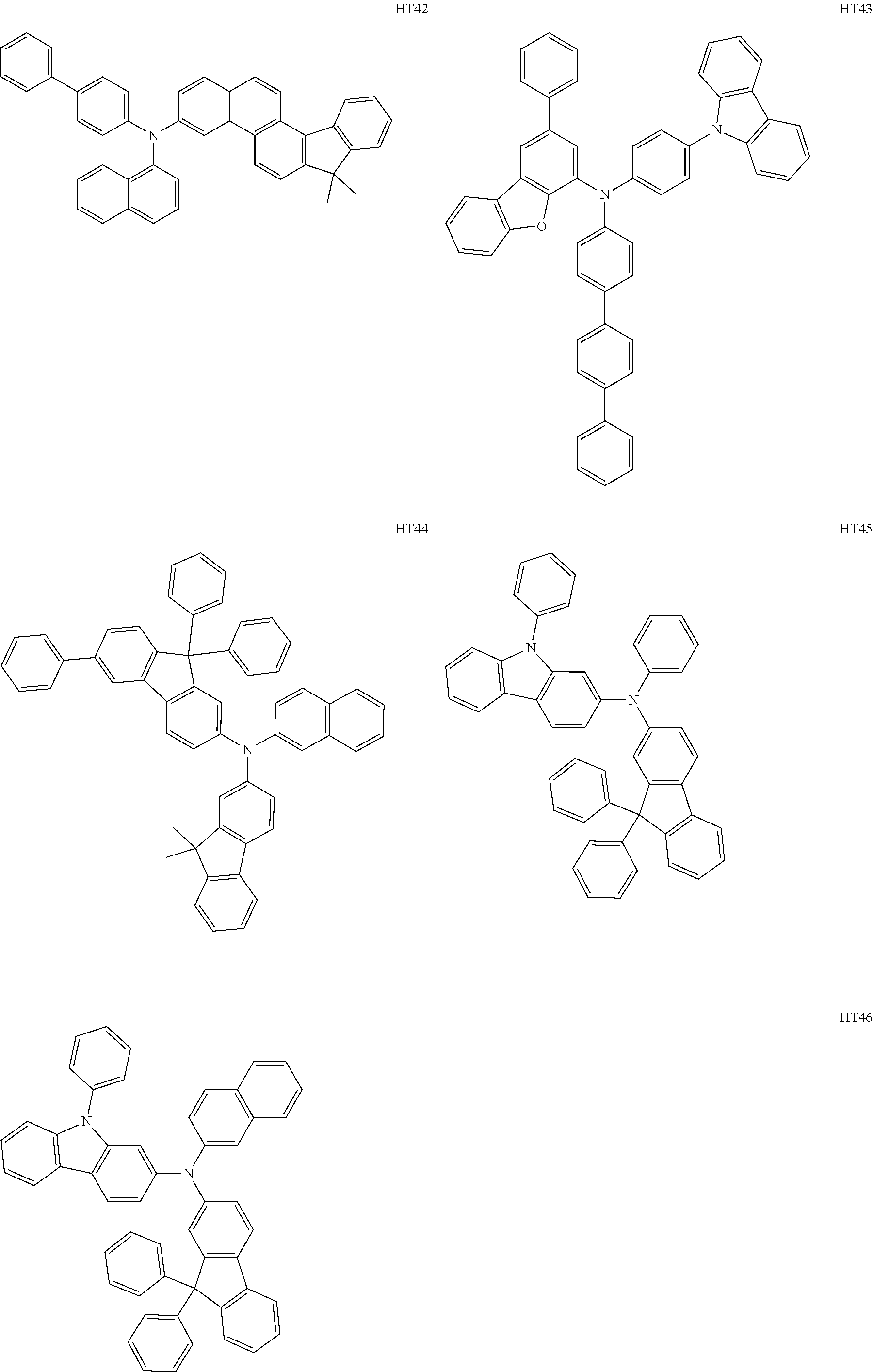 [SMILES: CC1(C)c2ccccc2-c2c1ccc1c2ccc2ccc(N(c3ccc(-c4ccccc4)cc3)c3cccc4ccccc34)cc21 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; CC1(C)c2ccccc2-c2ccc(N(c3ccc4c(c3)C(c3ccccc3)(c3ccccc3)c3ccc(-c5ccccc5)cc3-4)c3ccc4ccccc4c3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; c1ccc(-n2c3ccccc3c3ccc(N(c4ccc5c(c4)C(c4ccccc4)(c4ccccc4)c4ccccc4-5)c4ccc5ccccc5c4)cc32)cc1]

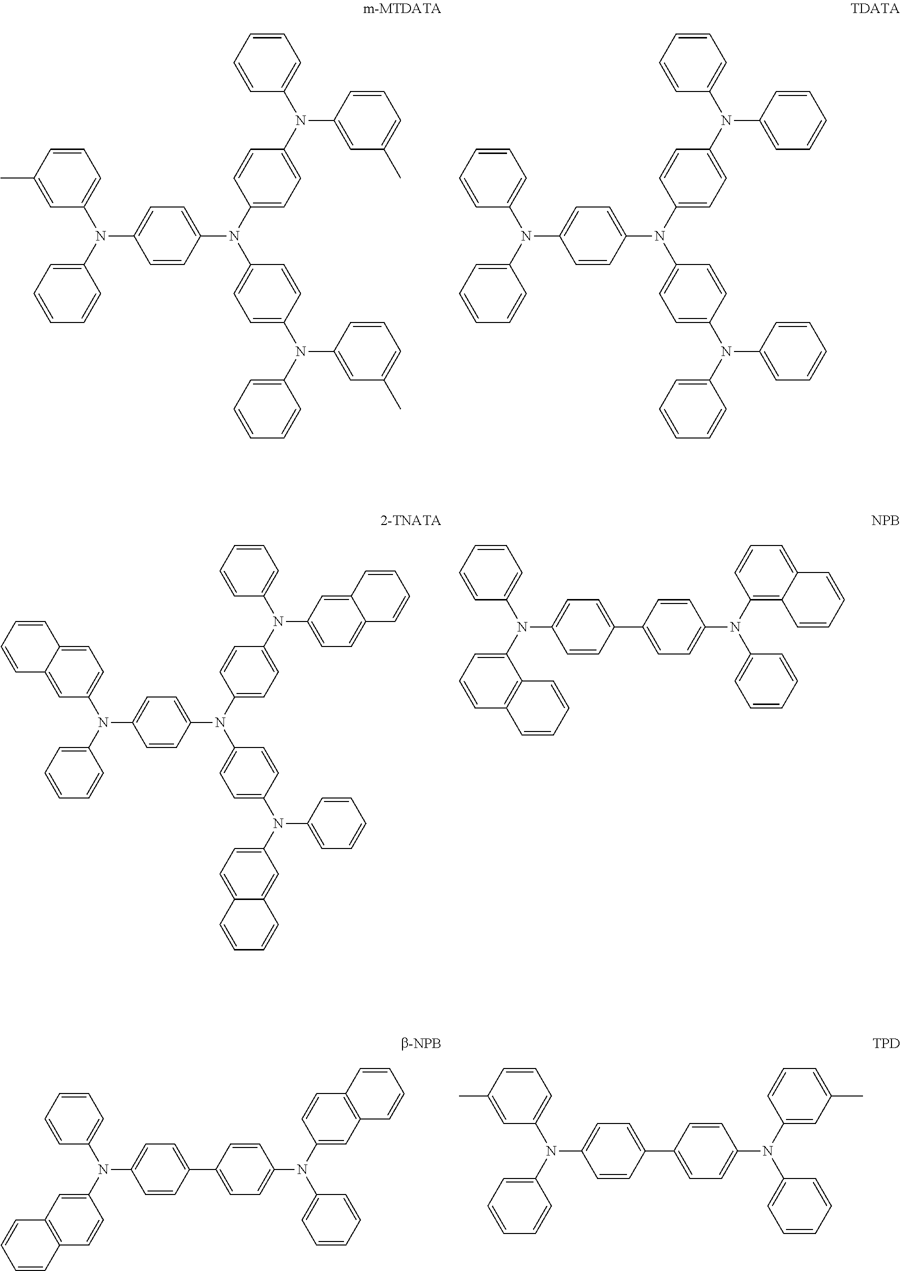

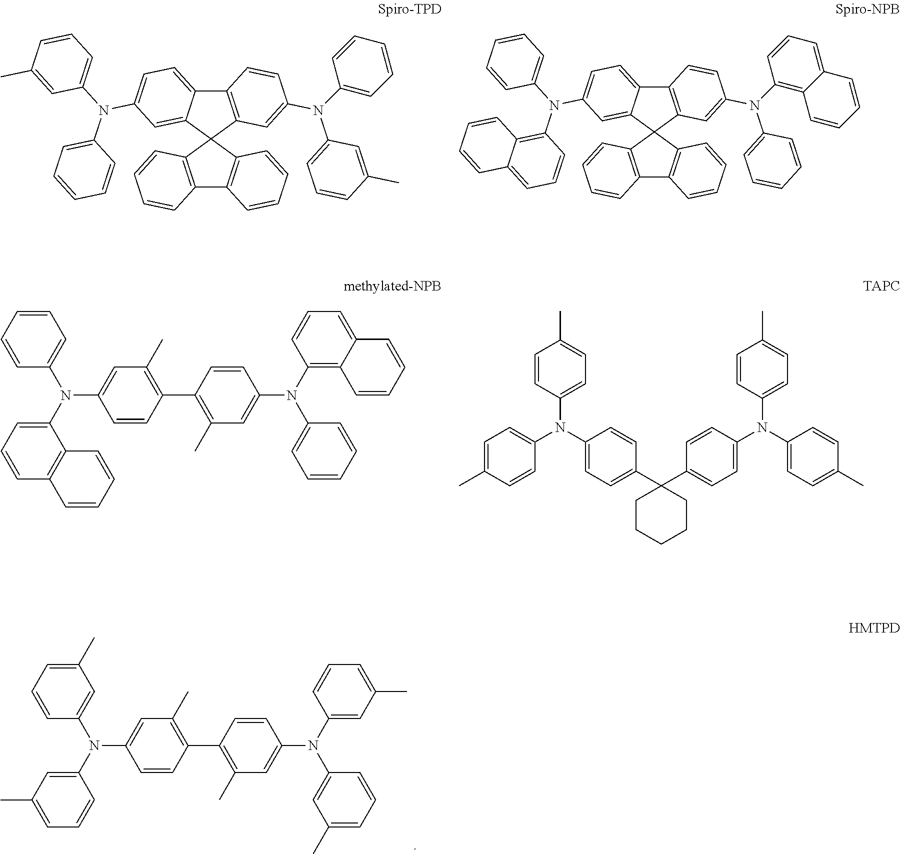

A thickness of the hole transport region may be in a range of about 50 Å to about 10,000 Å, for example, about 100 Å to about 4,000 Å. When the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within these ranges, satisfactory hole transporting characteristics may be obtained without a substantial increase in driving voltage.

The emission auxiliary layer may increase light-emission efficiency by compensating for an optical resonance distance according to the wavelength of light emitted by the emission layer, and the electron blocking layer may block the leakage of electrons from the emission layer to the hole transport region. Materials that may be included in the hole transport region may be included in the emission auxiliary layer and the electron blocking layer.

### p-Dopant

The hole transport region may further include, in addition to these materials, a charge-generation material for the improvement of conductive properties. The charge-generation material may be uniformly or non-uniformly dispersed in the hole transport region (for example, in the form of a single layer consisting of a charge-generation material).

The charge-generation material may be, for example, a p-dopant.

For example, a lowest unoccupied molecular orbital (LUMO) energy level of the p-dopant may be about −3.5 eV or less.

In an embodiment, the p-dopant may include a quinone derivative, a cyano group-containing compound, a compound including element EL1 and element EL2, or any combination thereof.

Examples of the quinone derivative are TCNQ, F4-TCNQ, and the like.

Examples of the cyano group-containing compound are HAT-CN, a compound represented by Formula 221, and the like:

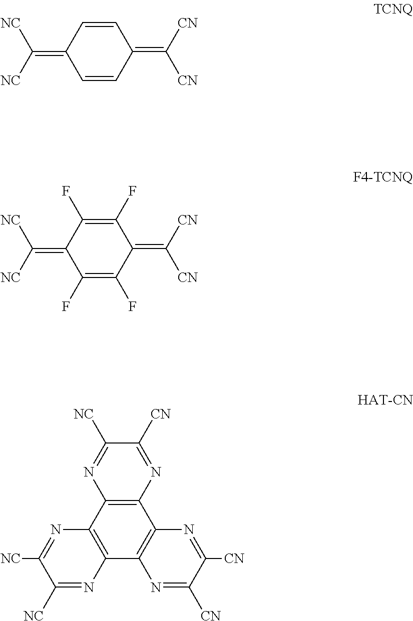

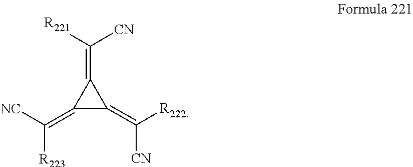

In Formula 221,

R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be metal, metalloid, or any combination thereof, and element EL2 may be non-metal, metalloid, or any combination thereof.

Examples of the metal are an alkali metal (for example, lithium (Li), sodium (Na), potassium (K), rubidium (Rb), cesium (Cs), and the like); alkaline earth metal (for example, beryllium (Be), magnesium (Mg), calcium (Ca), strontium (Sr), barium (Ba), and the like); transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and the like); post-transition metal (for example, zinc (Zn), indium (In), tin (Sn), and the like); lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and the like); and the like.

Examples of the metalloid are silicon (Si), antimony (Sb), tellurium (Te), and the like.

Examples of the non-metal are oxygen (O), halogen (for example, F, Cl , Br, I, and the like), and the like.

Examples of the compound including element EL1 and element EL2 are metal oxide, metal halide (for example, metal fluoride, metal chloride, metal bromide, metal iodide, and the like), metalloid halide (for example, metalloid fluoride, metalloid chloride, metalloid bromide, metalloid iodide, and the like), metal telluride, or any combination thereof.

Examples of the metal oxide are tungsten oxide (for example, WO, W₂O₃, WO₂, WO₃, W₂O₅, and the like), vanadium oxide (for example, VO, V₂O₃, VO₂, V₂O₅, and the like), molybdenum oxide (MoO, Mo₂O₃, MoO₂, MoO₃, Mo₂O₅, and the like), rhenium oxide (for example, ReO₃ and the like), and the like.

Examples of the metal halide are alkali metal halide, alkaline earth metal halide, transition metal halide, post-transition metal halide, lanthanide metal halide, and the like.

Examples of the alkali metal halide are LiF, NaF, KF, RbF, CsF, LiCl, NaCl, KCl, RbCl, CsCl, LiBr, NaBr, KBr, RbBr, CsBr, LiI, NaI, KI, RbI, CsI, and the like.

Examples of the alkaline earth metal halide are BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, SrI₂, BaI₂, and the like.

Examples of the transition metal halide are titanium halide (for example, TiF₄, TiCl₄, TiBr₄, TiI₄, and the like), zirconium halide (for example, ZrF₄, ZrCl₄, ZrBr₄, ZrI₄, and the like), hafnium halide (for example, HfF₄, HfCl₄, HfBr₄, HfI₄, and the like), vanadium halide (for example, VF₃, VCl₃, VBr₃, VI₃, and the like), niobium halide (for example, NbF₃, NbCl₃, NbBr₃, NbI₃, and the like), tantalum halide (for example, TaF₃, TaCl₃, TaBr₃, TaI₃, and the like), chromium halide (for example, CrF₃, CrCl₃, CrBr₃, CrI₃, and the like), molybdenum halide (for example, MoF₃, MoCl₃, MoBr₃, MoI₃, and the like), tungsten halide (for example, WF₃, WCl₃, WBr₃, WI₃, and the like), manganese halide (for example, MnF₂, MnCl₂,MnBr₂, MnI₂, and the like), technetium halide (for example, TcF₂, TcCl₂, TcBr₂, TcI₂, and the like), rhenium halide (for example, ReF₂, ReCl₂, ReBr₂, ReI₂, and the like), iron halide (for example, FeF₂, FeCl₂, FeBr₂, FeI₂, and the like), ruthenium halide (for example, RuF₂, RuCl₂, RuBr₂, RuI₂, and the like), osmium halide (for example, OsF₂, OsCl₂, OsBr₂, OsI₂, and the like), cobalt halide (for example, CoF₂, CoCl₂,CoBr₂, CoI₂, and the like), rhodium halide (for example, RhF₂, RhCl₂, RhBr₂, RhI₂, and the like), iridium halide (for example, IrF₂, IrCl₂,IrBr₂, IrI₂, and the like), nickel halide (for example, NiF₂, NiCl₂, NiBr₂, NiI₂, and the like), palladium halide (for example, PdF₂, PdCl₂, PdBr₂, PdI₂, and the like), platinum halide (for example, PtF₂, PtCl₂, PtBr₂, PtI₂, and the like), copper halide (for example, CuF, CuCl, CuBr, CuI, and the like), silver halide (for example, AgF, AgCl, AgBr, AgI, and the like), gold halide (for example, AuF, AuCl, AuBr, AuI, and the like), and the like.

Examples of the post-transition metal halide are zinc halide (for example, ZnF₂, ZnCl₂, ZnBr₂, ZnI₂, and the like), indium halide (for example, InI₃ and the like), tin halide (for example, SnI₂ and the like), and the like.

Examples of the lanthanide metal halide are YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, and the like.

Examples of the metalloid halide are antimony halide (for example, SbCl₅ and the like) and the like.

Examples of the metal telluride are alkali metal telluride (for example, Li₂Te, a na₂Te, K₂Te, Rb₂Te, Cs₂Te, and the like), alkaline earth metal telluride (for example, BeTe, MgTe, CaTe, SrTe, BaTe, and the like), transition metal telluride (for example, TiTe₂, ZrTe₂, HfTe₂, V₂Te₃, Nb₂Te₃, Ta₂Te₃, CR₂Te₃, Mo₂Te₃, W₂Te₃, MnTe, TcTe, ReTe, FeTe, RuTe, OsTe, CoTe, RhTe, IrTe, NiTe, PdTe, PtTe, Cu2Te, CuTe, Ag₂Te, AgTe, AuzTe, and the like), post-transition metal telluride (for example, ZnTe, and the like), lanthanide metal telluride (for example, LaTe, CeTe, PrTe, NdTe, PmTe, EuTe, GdTe, TbTe, DyTe, HoTe, ErTe, TmTe, YbTe, LuTe, and the like), and the like.

### Anode 150

The anode 150 is arranged on the hole transport region 140.

The anode 150 may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or any combination thereof. The anode 150 may be a transmissive electrode, a semi-transmissive electrode, or a reflective electrode.

The anode 150 may have a single-layered structure or a multi-layered structure including a plurality of layers.

### Capping Layer

A first capping layer may be arranged outside the cathode 110, and/or a second capping layer may be arranged outside the anode 150. In detail, the light-emitting device 10 may have a structure in which the first capping layer, the cathode 110, the emission layer 130, and the anode 150 are sequentially stacked in the stated order, a structure in which the cathode 110, the emission layer 130, the anode 150, and the second capping layer are sequentially stacked in the stated order, or a structure in which the first capping layer, the cathode 110, the emission layer 130, the anode 150, and the second capping layer are sequentially stacked in the stated order.

In an embodiment, light generated in the emission layer 130 of the organic layer 160 of the light-emitting device 10 may be extracted toward the outside through the cathode 110, which is a semi-transmissive electrode or a transmissive electrode, and the first capping layer. In one or more embodiments, light generated in the emission layer 130 of the organic layer 160 of the light-emitting device 10 may be extracted toward the outside through the anode 150, which is a semi-transmissive electrode or a transmissive electrode, and the second capping layer.

The first capping layer and the second capping layer may increase external emission efficiency according to the principle of constructive interference. Accordingly, the light extraction efficiency of the light-emitting device 10 may be increased, so that the luminescence efficiency of the light-emitting device 10 may be also improved.

Each of the first capping layer and the second capping layer may include a material having a refractive index of 1.6 or more (at 589 nm).

The first capping layer and the second capping layer may each independently be an organic capping layer including an organic material, an inorganic capping layer including an inorganic material, or an organic-inorganic composite capping layer including an organic material and an inorganic material.

In an embodiment, at least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may each optionally be substituted with a substituent including O, N, S, Se, Si, F, Cl, Br, I, or any combination thereof In one or more embodiments, at least one of the first capping layer and the second capping layer may each independently include an amine group-containing compound.

In one or more embodiments, at least one of the first capping layer and the second capping layer may each independently include a compound represented by Formula 201, a compound represented by Formula 202, or any combination thereof.

In one or more embodiments, at least one of the first capping layer and the second capping layer may each independently include one of Compounds HT28 to HT33, one of Compounds CP1 to CP6, β-NPB, or any combination thereof:

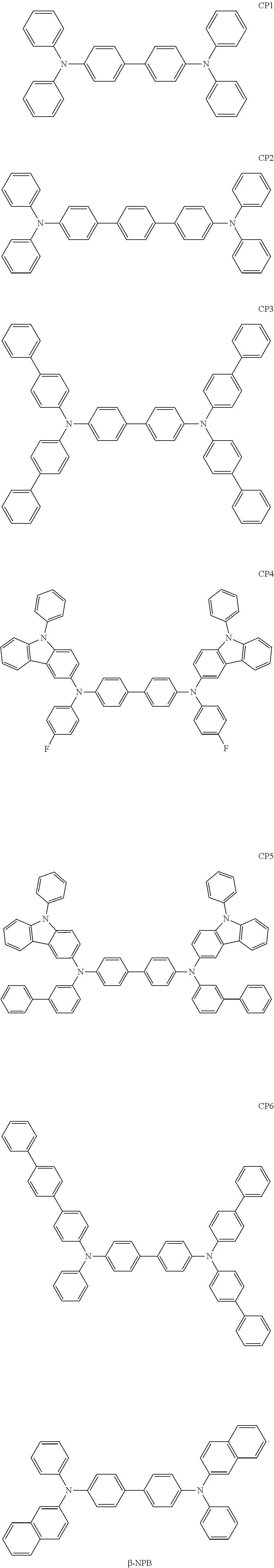

### Electronic Apparatus

The light-emitting device may be included in various electronic apparatuses. For example, an electronic apparatus including the light-emitting device may be a light-emitting apparatus, an authentication apparatus, or the like.

The electronic apparatus (for example, a light-emitting apparatus) may further include, in addition to the light-emitting device, i) a color filter, ii) a color conversion layer, or iii) both a color filter and a color conversion layer. The color filter and/or the color conversion layer may be arranged in at least one traveling direction of light emitted from the light-emitting device. For example, light emitted from the light-emitting device may be blue light or white light. Details for the light-emitting device may be the same as described herein. In an embodiment, the color conversion layer may include a quantum dot. The quantum dots may be, for example, the same as described herein.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be arranged among the subpixel areas to define each of the subpixel areas.

The color filter may further include a plurality of color filter areas and light-shielding patterns arranged among the color filter areas, and the color conversion layer may further include a plurality of color conversion areas and light-shielding patterns arranged among the color conversion areas.

The plurality of color filter areas (or the plurality of color conversion areas) may include a first area emitting first-color light, a second area emitting second-color light, and/or a third area emitting third-color light, wherein the first-color light, the second-color light, and/or the third-color light may have different maximum emission wavelengths from one another. For example, the first-color light may be red light, the second-color light may be green light, and the third-color light may be blue light. For example, the plurality of color filter areas (or the plurality of color conversion areas) may include quantum dots. In particular, the first region may include red quantum dots, the second region may include green quantum dots, and the third region may not include quantum dots. Details for the quantum dots may be the same as described herein. The first region, the second region, and/or the third region may each further include a scatter.

For example, the light-emitting device may emit first light, the first region may absorb the first light and emit first-first-color light, the second region may absorb the first light and emit second-first-color light, and the third region may absorb the first light and emit third-first-color light. Here, the first-first-color light, the second-first-color light, and the third-first-color light may have different maximum emission wavelengths from each other. In detail, the first light may be blue light, the first-first-color light may be red light, the second-first-color light may be green light, and the third-first-color light may be blue light.

The electronic apparatus may further include a thin-film transistor in addition to the above-described light-emitting device. The thin-film transistor may include a source electrode, a drain electrode, and an activation layer, wherein any one of the source electrode and the drain electrode may be electrically connected to any one of the first electrode and the second electrode of the light-emitting device.

The thin-film transistor may further include a gate electrode, a gate insulating film, or the like.

The activation layer may include crystalline silicon, amorphous silicon, an organic semiconductor, an oxide semiconductor, or the like.

The electronic apparatus may further include a sealing portion for sealing the light-emitting device. The sealing portion may be arranged between the color conversion layer and/or color filter and the light-emitting device. The sealing portion allows light from the light-emitting device to be extracted to the outside, and simultaneously prevents ambient air and moisture from penetrating into the light-emitting device. The sealing portion may be a sealing substrate including a transparent glass substrate or a plastic substrate. The sealing portion may be a thin-film encapsulation layer including at least one of an organic layer and/or an inorganic layer. When the sealing portion is a thin-film encapsulation layer, the electronic apparatus may be flexible.

Various functional layers may be additionally arranged on the sealing portion, in addition to the color filter and/or the color conversion layer, according to the use of the electronic apparatus. The functional layers may include a touch screen layer, a polarizing layer, and the like. The touch screen layer may be a pressure-sensitive touch screen layer, a capacitive touch screen layer, or an infrared touch screen layer.

The authentication apparatus may further include, in addition to the light-emitting emitting device as described above, a biometric information collector. The authentication apparatus may be, for example, a biometric authentication apparatus that authenticates an individual by using biometric information of a living body (for example, fingertips, pupils, and the like).

The electronic apparatus may be applied to various displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, and the like.

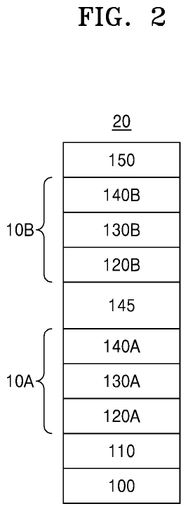

### Description of FIG. 2

Another aspect of the present disclosure provides a light-emitting device including:

a substrate;
a cathode disposed on the substrate;
an anode facing the cathode;
x emitting units between the cathode and the anode; and
x−1 charge generation layers, each arranged between two neighboring emitting units among the x emitting units and including an n-type charge generation layer and a p-type charge generation layer,
wherein x may be an integer of 2 or more,
each of the x emitting units may include an electron transport region, an emission layer, and a hole transport region that are sequentially arranged from the cathode, and
the hole transport region may include a first compound including a first repeating unit represented by Formula 1, a second compound represented by Formula 2, a fifth compound represented by Formula 5, or any combination thereof.

The first compound, the second compound, and the fifth compound may be the same as described herein.

FIG. 2 is a schematic cross-sectional view of a light-emitting device 20 according to another embodiment. As shown in FIG. 2, the light-emitting device 20 includes a substrate 100, a cathode 110 on the substrate 100, an anode 150 facing the cathode 100, 2 emitting units 10A and 10B stacked between the cathode 100 and the anode 150, and 1 charge generation layers 145, each arranged between two neighboring emitting units among the 2 emitting units and including an n-type charge generation layer and a p-type charge generation layer.

The emitting units 10A and 10B may include electron transport regions 120A and 120B, emission layers 130A and 130B, and hole transport regions 140A and 140B, respectively, that are sequentially stated in the stated order from the cathode 100.

The “light-emitting device” may include x emitting units, wherein x may be an integer of 2 or more. A number, x, of the emitting units, may vary according to the purpose, and the upper limit of the number is not particularly limited. For example, the light-emitting device may include 2, 3, 4, 5, or 6 emitting units.

The light-emitting device may include a charge generation layer between two neighboring emitting units of the x emitting units. Herein, the term “neighboring” refers to the arrangement relationship of layers or units that are closest to each other, from among layers or units referred to as being neighbored. For example, the term “two neighboring emitting units” refers to the arrangement relationship of two emitting units arranged closest to each other among a plurality of emitting units. The term “neighboring” may refer to a case where two layers or units are physically in contact with each other, and a case where another layer or unit, not mentioned, may be arranged between the two layers or units. For example, an emitting unit neighboring to an anode refers to an emitting unit arranged closest to the anode, among a plurality of emitting units. Also, the anode and the neighboring emitting unit thereto may be in physical contact with each other. In an embodiment, however, other layers or units other than the emitting unit may be arranged between the anode and the neighboring emitting unit thereto. In an embodiment, an electron transport layer may be arranged between the anode and the neighboring emitting unit thereto. However, the charge generation layer may be arranged between two neighboring emitting units.

The “charge generation layer” may generate electrons with respect to one emitting unit of two neighboring emitting units and thus acts as a cathode, and may generate holes with respect to the other emitting unit and thus acts as an anode. The charge generation layer is not directly connected to an electrode, and may separate neighboring emitting units. That is, a light-emitting device including x emitting units may include x−1 charge generation layers.

In an embodiment, the charge generation layer 145 may include a hole-transporting material.

In one or more embodiments, the charge generation layer 145 may include PEDOT:PSS, Nafion, sulfonic acid, and the like.

In one or more embodiments, the charge generation layer 145 may include a fourth compound represented by Formula 4:

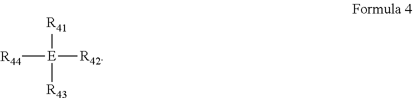

In Formula 4,

### E may be B, Al, Ga, In, or Tl,

R₄₁ to R₄₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
R₁₀ₐ may be the same as described herein.

In an embodiment, E in Formula 4 may be B.

In an embodiment, R₄₁ to R₄₄ may each independently be a C₁-C₁₀ heterocycloalkenylene group unsubstituted or substituted with at least one R₁₀ₐ, a C₆-C₆₀ arylene group unsubstituted or substituted with at least one R₁₀ₐ, a C₁-C₆₀ heteroarylene group unsubstituted or substituted with at least one R₁₀ₐ, a monovalent non-aromatic condensed polycyclic group unsubstituted or substituted with at least one R₁₀ₐ, or a monovalent non-aromatic condensed heteropolycyclic group unsubstituted or substituted with at least one R₁₀ₐ.

In one or more embodiments, R₄₁ to R₄₄ may each independently a phenyl group substituted with at least one —F, a C₂-C₁₀ alkenyl group, a C₆-C₆₀ arylene group, or a monovalent non-aromatic condensed polycyclic group.

In an embodiment, the fourth compound may be one of Compounds 4-1 to 4-6:

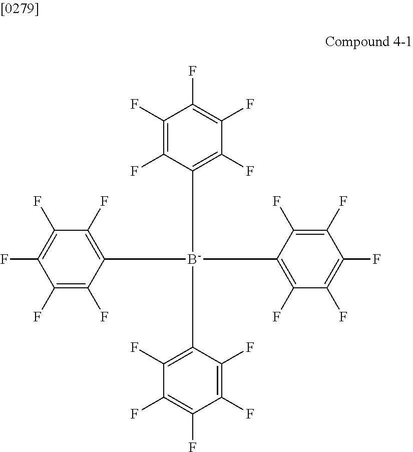 [SMILES: Fc1c(F)c(F)c([B-](c2c(F)c(F)c(F)c(F)c2F)(c2c(F)c(F)c(F)c(F)c2F)c2c(F)c(F)c(F)c(F)c2F)c(F)c1F]

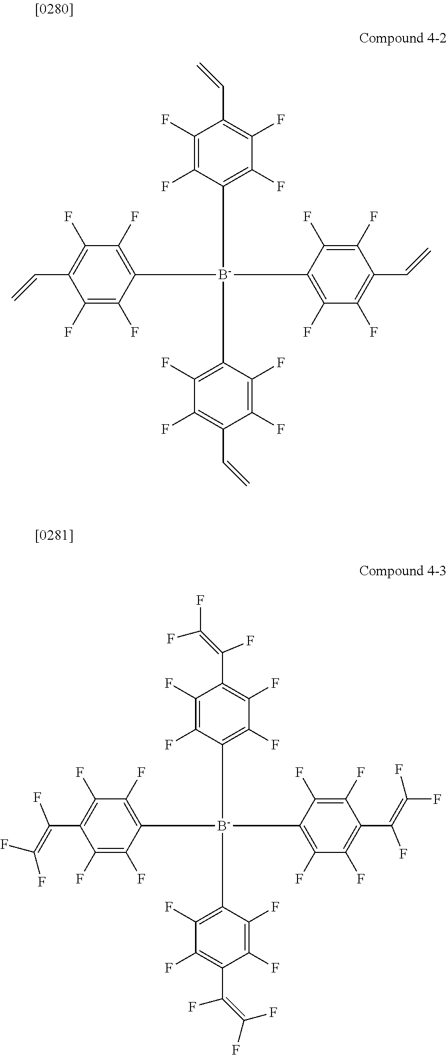 [SMILES: C=Cc1c(F)c(F)c([B-](c2c(F)c(F)c(C=C)c(F)c2F)(c2c(F)c(F)c(C=C)c(F)c2F)c2c(F)c(F)c(C=C)c(F)c2F)c(F)c1F ; FC(F)=C(F)c1c(F)c(F)c([B-](c2c(F)c(F)c(C(F)=C(F)F)c(F)c2F)(c2c(F)c(F)c(C(F)=C(F)F)c(F)c2F)c2c(F)c(F)c(C(F)=C(F)F)c(F)c2F)c(F)c1F]

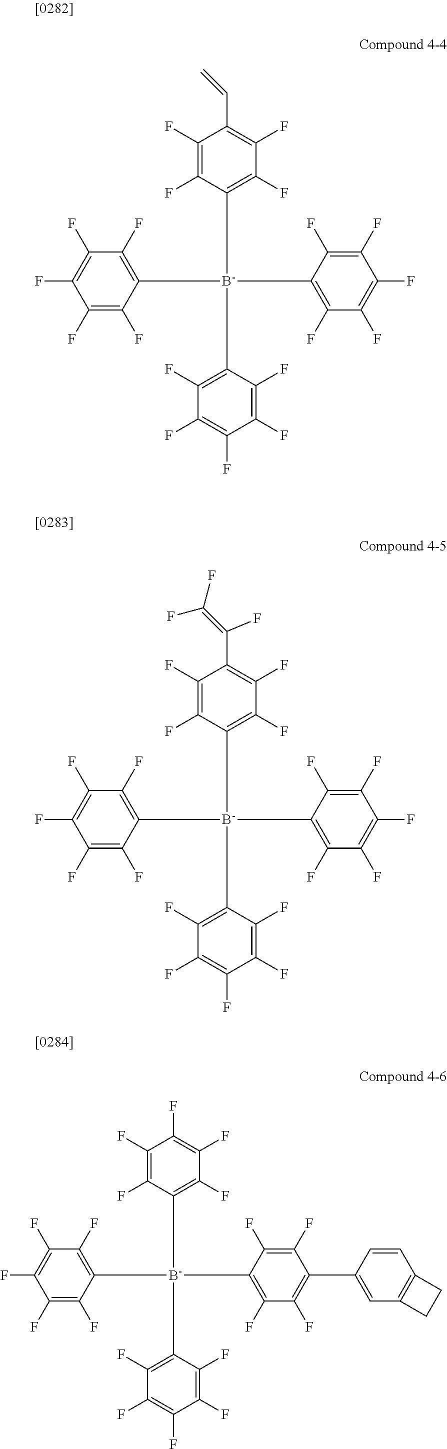 [SMILES: C=Cc1c(F)c(F)c([B-](c2c(F)c(F)c(F)c(F)c2F)(c2c(F)c(F)c(F)c(F)c2F)c2c(F)c(F)c(F)c(F)c2F)c(F)c1F ; FC(F)=C(F)c1c(F)c(F)c([B-](c2c(F)c(F)c(F)c(F)c2F)(c2c(F)c(F)c(F)c(F)c2F)c2c(F)c(F)c(F)c(F)c2F)c(F)c1F ; Fc1c(F)c(F)c([B-](c2c(F)c(F)c(F)c(F)c2F)(c2c(F)c(F)c(F)c(F)c2F)c2c(F)c(F)c(-c3ccc4c(c3)CC4)c(F)c2F)c(F)c1F]

In the light-emitting device including the x emitting units according to an embodiment of the present disclosure, each of the x emitting units includes the electron transport region, which includes the third compound that is a metal oxide, and the hole transport region, which includes the first compound or the second compound, so as to exhibit excellent efficiency characteristics and long lifespan characteristics.

Each of the x−1 charge generation layers may include an n-type charge generation layer and a p-type charge generation layer. Here, the n-type charge generation layer and the p-type charge generation layer may be in direct contact with each other to form an NP junction. By the NP junction, electrons and holes may be simultaneously generated between the n-type charge generation layer and the p-type charge generation layer. The generated electrons may be transferred to one of the two neighboring emitting units through the n-type charge generation layer. The generated holes may move to the other one of the two neighboring emitting units through the p-type charge generation layer. In addition, in the presence of a plurality of charge generation layers, each of the plurality of charge generation layers includes one n-type charge generation layer and one p-type charge generation layer. That is, a light-emitting device including x−1 charge generation layers may include x−1 n-type charge generation layers and x−1 p-type charge generation layers.

The n-type refers to n-type semiconductor characteristics, that is, the characteristics of injecting or transporting electrons. The p-type refers to p-type semiconductor characteristics, that is, the characteristics of injecting or transporting holes.

The x emitting units may include the electron transport regions, the emission layers, and the hole transport regions, respectively, that are sequentially arranged in this stated order from the cathode 110. Here, each of the x electron transport regions included in the x emitting units may include the third compound represented by Formula 3, and each of the x hole transport regions included in the x emitting units may include the first compound including the first repeating unit represented by Formula 1 and the second compound represented by Formula 2.

Each of the plurality of hole transport regions may include a hole injection layer, a hole transport layer, an electron blocking layer, or any combination thereof, and each of the plurality of electron transport regions may include a hole blocking layer, an electron transport layer, an electron injection layer, or any combination thereof

In an embodiment, a maximum emission wavelength of light emitted from the x emitting units may all be the same.

In one or more embodiments, the x emitting units may emit blue light having a maximum emission wavelength of about 420 nm or more and about 490 nm or less.

In one or more embodiments, the x emitting units may emit red light having a maximum emission wavelength of about 620 nm or more and about 750 nm or less.

In one or more embodiments, the x emitting units may emit green light having a maximum emission wavelength of about 495 nm or more and about 580 nm or less.

In one or more embodiments, the maximum emission wavelength of light emitted from at least one of the x emitting units may be different from the maximum emission wavelength of light emitted from at least one emitting unit among the remaining emitting units. For example, in the case of a light-emitting device in which a first emitting unit and a second emitting unit are stacked, a maximum emission wavelength of light emitted from the first emitting unit may be different from a maximum emission wavelength of light emitted from the second emitting unit. In this case, an emission layer of the first emitting unit and an emission layer of the second emitting unit may each independently have i) a single-layered structure consisting of a single layer consisting of a single material, ii) a single-layer structure consisting of a single layer consisting of a plurality of different materials, or iii) a multi-layered structure having a plurality of layers consisting of a plurality of different materials. Accordingly, light emitted from the first emitting unit or light emitted from the second emitting unit may be single-color light or mixed-color light. For example, in the case of a light-emitting device in which a first emitting unit, a second emitting unit, and a third emitting unit are stacked, a maximum emission wavelength of light emitted from the first emitting unit may be the same as a maximum emission wavelength of light emitted from the second emitting unit, but may be different from a maximum emission wavelength of light emitted from the third emitting unit. Alternatively, the maximum emission wavelength of light emitted from the first emitting unit, the maximum emission wavelength of light emitted from the second emitting unit, and the maximum emission wavelength of light emitted from the third emitting unit may be different from one another.

### Manufacturing Method

The emission layer and the constituent layers of the electron transport region and the hole transport region may be formed using a solution process.

Another aspect of the present disclosure provides a method of manufacturing a light-emitting device, the method including:

forming a first organic layer between the cathode and an anode;
forming a second organic layer between the anode and the first organic layer; and
forming a third organic layer between the second organic layer and the anode.

In an embodiment, the first organic layer may be a hole transport region, the second organic layer may be an emission layer, and the third organic layer may be an electron transport region.

In one or more embodiments, a separate organic layer may be formed between the first organic layer and the second organic layer, and a separate organic layer may be formed between the second organic layer and the third organic layer.

In an embodiment, the forming of the first organic layer may be performed by a solution process using a composition including a third compound represented by Formula 3.

The third compound may be the same as described herein.

An amount of the third compound included in the composition may be, based on total 100 wt % of the composition, about 1 wt % or more and about 5 wt % or less or about 2 wt % or more and about 4 wt % or less.

In an embodiment, the forming of the second organic layer may be performed by a solution process using a composition including a host compound, a dopant compound, a delayed fluorescence material, a quantum dot, or any combination thereof

The host compound, the dopant compound, the delayed fluorescence material, and the quantum dot may respectively be the same as described herein.

When the composition includes the host compound only, an amount of the host compound included in the composition may be, based on total 100 wt % of the composition, about 1 wt % or more and about 5 wt % or less or about 2 wt % or more and about 4 wt % or less.

When the composition includes the host compound and the dopant compound at the same time, an amount of the dopant compound included in the composition may be, based on 100 wt % of the host compound, about 1 wt % or more and about 5 wt % or less or about 2 wt % or more and about 4 wt % or less.

When the composition includes the quantum dot only, an amount of the quantum dot included in the composition may be, based on total 100 wt % of the composition, about 0.1 wt % or more and about 3 wt % or less or about 0.5 wt % or more and about 2 wt % or less.

In an embodiment, the forming of the third organic layer may be performed by a solution process using a composition including a first compound including a first repeating unit represented by Formula 1, a second compound represented by Formula 2, a fifth compound represented by Formula 5, or any combination thereof

The first compound, the second compound, and the fifth compound may respectively be the same as described herein.

When the composition includes the first compound only or the fifth compound only, an amount of the first compound or the fifth compound may be, based on total 100 wt % of the composition, about 0.5 wt % or more and about 4 wt % or less or about 1.5 wt % or more and about 3 wt % or less.

When the composition includes the first compound and the second compound at the same time, an amount of the second compound included in the composition may be, based on 100 wt % of the first compound, about 2 wt % or more and about 10 wt % or less or about 3 wt % or more and about 7 wt % or less.

In an embodiment, the method may further include forming a fourth organic layer between the third organic layer and the anode.

In an embodiment, the forming of the fourth organic layer may be performed by a solution process using a composition including a hole-transporting material, a fourth compound represented by Formula 4, or any combination thereof

The hole-transporting material and the fourth compound may respectively be the same as described herein.

For example, the hole-transporting material may be PEDOT:PSS, Nafion, or sulfonic acid.

The solution process may be performed by spin coating, slot coating, dip coating, bar coating, roll coating, gravure coating, microgravure coating, wire coating, spray coating, inkjet printing, nozzle printing, screen printing, flexo printing, offset printing, or casting.

For example, the solution process may be performed by spin coating.

In an embodiment, each of the forming of the first organic layer, the forming of the second organic layer, and the forming of the third organic layer may further include a step of evaporating a solvent.

In one or more embodiment, the forming of the fourth organic layer may further include a step of evaporating a solvent.

The evaporating of the solvent may be performed at a temperature in a range of about 110° C. to about 180° C.

In one or more embodiments, the method may further include, before the evaporating of the solvent, a step of irradiating UV.

In an embodiment, the forming of the first organic layer may include: coating (for example, spin coating) the composition including the third compound; irradiating the coated composition with UV; and evaporating a solvent after the UV irradiation.

In an embodiment, the forming of the second organic layer may include: coating (for example, spin coating) the composition including the host compound, the dopant compound, the delayed fluorescence material, the quantum dot, or any combination thereof; irradiating the coated composition with UV; and evaporating a solvent after the UV irradiation.

In an embodiment, the forming of the third organic layer may include: coating (for example, spin coating) the composition including the first compound, the second compound, or any combination thereof; irradiating the coated composition with UV; and evaporating a solvent after the UV irradiation.

In an embodiment, a light-emitting device including x emitting units may be manufactured by performing steps of: forming a first organic layer; forming a second organic layer; and forming a third organic layer in the stated order. Next, a step of forming a fourth organic layer may be performed. Afterwards, the light-emitting device may be manufactured by repeating the same steps as the forming of the first organic layer, the forming of the second organic layer, and the forming of the third organic layer in the stated order.

In an embodiment, a light-emitting device including x emitting units may be manufactured by performing steps of: forming a first organic layer; forming a second organic layer; and forming a third organic layer in the stated order. Next, a step of forming a fourth organic layer may be performed. Afterwards, the light-emitting device may be manufactured by repeating the same steps as the forming of the first organic layer, the forming of the second organic layer, and the forming of the third organic layer in the stated order, except for using a composition having a different component from each of the compositions for forming the first organic layer to the third organic layer.

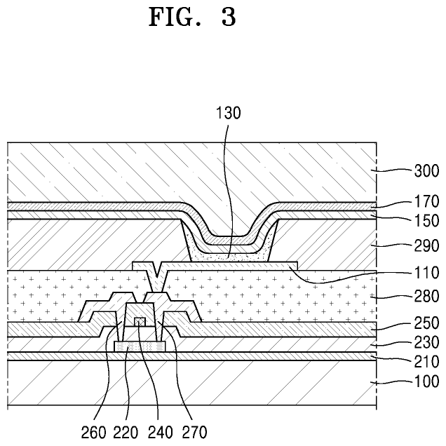

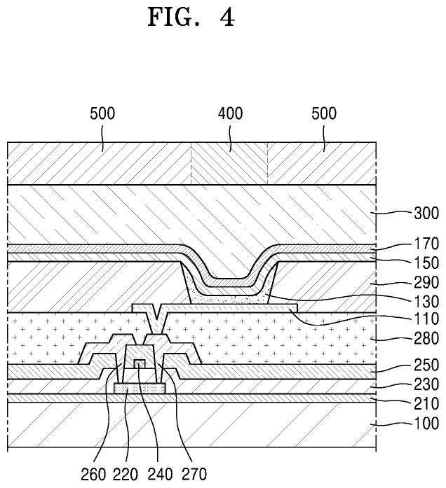

### Description of FIGS. 3 and 4

FIG. 3 is a cross-sectional view showing a light-emitting apparatus according to an embodiment.

The light-emitting apparatus of FIG. 3 includes a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be arranged on the substrate 100. The buffer layer 210 may prevent penetration of impurities through the substrate 100 and may provide a flat surface on the substrate 100.

A TFT may be arranged on the buffer layer 210. The TFT may include an activation layer 220, a gate electrode 240, a source electrode 260, and a drain electrode 270.

The activation layer 220 may include an inorganic semiconductor such as silicon or polysilicon, an organic semiconductor, or an oxide semiconductor, and may include a source region, a drain region, and a channel region.

A gate insulating film 230 for insulating the activation layer 220 from the gate electrode 240 may be arranged on the activation layer 220, and the gate electrode 240 may be arranged on the gate insulating film 230.

An interlayer insulating film 250 may be arranged on the gate electrode 240. The interlayer insulating film 250 may be arranged between the gate electrode 240 and the source electrode 260 and between the gate electrode 240 and the drain electrode 270, to insulate

The source electrode 260 and the drain electrode 270 may be arranged on the interlayer insulating film 250. The interlayer insulating film 250 and the gate insulating film 230 may be formed to expose the source region and the drain region of the activation layer 220, and the source electrode 260 and the drain electrode 270 may be arranged in contact with the exposed portions of the source region and the drain region of the activation layer 220.

The TFT may be electrically connected to a light-emitting device to drive the light-emitting device, and may be protected as being covered with a passivation layer 280. The passivation layer 280 may include an inorganic insulating film, an organic insulating film, or any combination thereof. A light-emitting device may be provided on the passivation layer 280. The light-emitting device includes a first electrode 110, an emission layer 130, and a second electrode 150.

The first electrode 110 may be arranged on the passivation layer 280. The passivation layer 280 may be arranged to expose a portion of the drain electrode 270, not fully covering the drain electrode 270, and the first electrode 110 may be arranged to be connected to the exposed portion of the drain electrode 270.

A pixel defining layer 290 including an insulating material may be arranged on the first electrode 110. The pixel-defining film 290 may expose a region of the first electrode 110, and an emission layer 130 may be formed in the exposed region of the first electrode 110. The pixel defining layer 290 may be a polyimide-based organic film or a polyacrylic-based organic film. At least some layers of the emission layer 130 may extend beyond the upper portion of the pixel defining layer 290 to be arranged in the form of a common layer.

The second electrode 150 may arranged be on the emission layer 130, and a capping layer 170 may be additionally formed on the second electrode 150. The capping layer 170 may be formed to cover the second electrode 150.

The encapsulation portion 300 may be arranged on the capping layer 170. The encapsulation portion 300 may be arranged on a light-emitting device to protect the light-emitting device from moisture or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, and the like), an epoxy-based resin (for example, aliphatic glycidyl ether (AGE), and the like), or any combination thereof; or any combination of the inorganic films and the organic films.

FIG. 4 is a cross-sectional view showing a light-emitting apparatus according to another embodiment.

The light-emitting apparatus of FIG. 4 is the same as the light-emitting apparatus of FIG. 3, except that a light-shielding pattern 500 and a functional region 400 are additionally arranged on the encapsulation portion 300. The functional region 400 may be i) a color filter area, ii) a color conversion area, or iii) a combination of the color filter area and the color conversion area. In an embodiment, the light-emitting device included in the light-emitting apparatus of FIG. 3 may be a tandem light-emitting device.

### Definition of Terms

The term “C₃-C₆₀ carbocyclic group” as used herein refers to a cyclic group consisting of carbon only as a ring-forming atom and having 3 to 60 carbon atoms, and the term “C₁-C₆₀ heterocyclic group” as used herein refers to a cyclic group that has 1 to 60 carbon atoms and further has, in addition to carbon, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. For example, the C₁-C₆₀ heterocyclic group has 3 to 61 ring-forming atoms.

The “cyclic group” as used herein may include the C₃-C₆₀ carbocyclic group and the C₁-C₆₀ heterocyclic group.

The term “π electron-rich C₃-C₆₀ cyclic group” as used herein refers to a cyclic group that has 3 to 60 carbon atoms and does not include *—N═*′ as a ring-forming moiety, and the term “π electron-deficient nitrogen-containing C₁-C₆₀ cyclic group” as used herein refers to a heterocyclicgroup that has 1 to 60 carbon atoms and includes *—N═*′ as a ring-forming moiety.

For example,

the C₃-C₆₀ carbocyclic group may be i) a T1 group or ii) a condensed cyclic group in which two or more T1 groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group), the C₁-C₆₀ heterocyclic group may be i) a T2 group, ii) a condensed cyclic group in which two or more T2 groups are condensed with each other, or iii) a condensed cyclic group in which at least one T2 group and at least one T1 group are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and the like),
the π electron-rich C₃-C₆₀ cyclic group may be i) a T1 group, ii) a condensed cyclic group in which two or more T1 groups are condensed with each other, iii) a T3 group, iv) a condensed cyclic group in which two or more T3 groups are condensed with each other, or v) a condensed cyclic group in which at least one T3 group and at least one T1 group are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and the like),
the π electron-deficient nitrogen-containing C₁-C₆₀ cyclic group may be i) a T4 group, ii) a condensed cyclic group in which two or more T4 groups are condensed with each other, iii) a condensed cyclic group in which at least one T4 group and at least one T1 group are condensed with each other, iv) a condensed cyclic group in which at least one T4 group and at least one T3 group are condensed with each other, or v) a condensed cyclic group in which at least one T4 group, at least one T1 group, and at least one T3 group are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and the like),
the T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
the T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
the T3 group may be a furan group, a thiophene group, a 1H-pyrrole group, a silole group, or a borole group, and
the T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group, the C₃-C₆₀ carbocyclic group, the C₁-C₆₀ heterocyclic group, the π electron-rich C₃-C₆₀ cyclic group, or the π electron-deficient nitrogen-containing C₁-C₆₀ cyclic group” as used herein refer to a group condensed to any cyclic group, a monovalent group, or a polyvalent group (for example, a divalent group, a trivalent group, a tetravalent group, and the like) according to the structure of a formula for which the corresponding term is used. For example, the “benzene group” may be a bengroup, a phenyl group, a phenylene group, or the like, which may be easily understood by one of ordinary skill in the art according to the structure of a formula including the “benzene group.”

Examples of the monovalent C₃-C₆₀ carbocyclic group and the monovalent C₁-C₆₀ heterocyclic group are a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of the divalent C₃-C₆₀ carbocyclic group and the divalent C₁-C₆₀ heterocyclic group are a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as used herein refers to a linear or branched aliphatic hydrocarbon monovalent group that has 1 to 60 carbon atoms, and specific examples thereof are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and the like. The term “C₁-C₆₀ alkylene group” as used herein refers to a divalent group having the same structure as the C₁-C₆₀ alkyl group.

The term “C₂-C₆₀ alkenyl group” as used herein refers to a monovalent hydrocarbon group having at least one carbon-carbon double bond in the middle or at the terminus of the C₂-C₆₀ alkyl group, and examples thereof are an ethenyl group, a propenyl group, a butenyl group, and the like. The term “C₂-C₆₀ alkenylene group” as used herein refers to a divalent group having the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of the C₂-C₆₀ alkyl group, and examples thereof are an ethynyl group, a propynyl group, and the like. The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by —OA₁₀₁ (wherein A₁₀₁ is the C₁-C₆₀ alkyl group), and examples thereof are a methoxy group, an ethoxy group, an isopropyloxy group, and the like.

The term “C₃-C₁₀ cycloalkyl group” as used herein refers to a monovalent saturated hydrocarbon cyclic group having 3 to 10 carbon atoms, and examples thereof are a cyclopropyl group, a cyclobutyl group, a cyclopentyl group, a cyclohexyl group, a cycloheptyl group, a cyclooctyl group, an adamantanyl group, a norbornanyl group (or a bicyclo[2.2.1]heptyl group), a bicyclo[1.1.1]pentyl group, a bicyclo[2.1.1]hexyl group, a bicyclo[2.2.2]octyl group, and the like. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent cyclic group of 1 to 10 carbon atoms, further including, in addition to carbon atoms, at least one heteroatom, as ring-forming atoms, and specific examples are a 1,2,3,4-oxatriazolidinyl group, a tetrahydrofuranyl group, a tetrahydrothiophenyl group, and the like. The term “C₁-C₁₀ heterocycloalkylene group” as used herein refers to a divalent group having the same structure as the C₁-C₁₀ heterocycloalkyl group.

The term C₃-C₁₀ cycloalkenyl group used herein refers to a monovalent cyclic group that has three to ten carbon atoms and at least one carbon-carbon double bond in the ring thereof and no aromaticity, and specific examples thereof are a cyclopentenyl group, a cyclohexenyl group, a cycloheptenyl group, and the like. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent cyclic group of 1 to 10 carbon atoms, further including, in addition to carbon atoms, at least one heteroatom, as ring-forming atoms, and having at least one carbon-carbon double bond in the cyclic structure thereof. Examples of the C₁-C₁₀ heterocycloalkenyl group are a 4,5-dihydro-1,2,3,4-oxatriazolyl group, a 2,3-dihydrofuranyl group, a 2,3-dihydrothiophenyl group, and the like. The term “C₁-C₁₀ heterocycloalkenylene group” as used herein refers to a divalent group having the same structure as the Ci-Cheterocycloalkenyl group.

The term “C₆-C₆₀ aryl group” as used herein refers to a monovalent group having a carbocyclic aromatic system of 6 to 60 carbon atoms, and the term “C₆-C₆₀ arylene group” as used herein refers to a divalent group having a carbocyclic aromatic system of 6 to 60 carbon atoms. Examples of the C₆-C₆₀ aryl group are a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like. When the C₆-C₆₀ aryl group and the C₆-C₆₀ arylene group each include two or more rings, the two or more rings may be condensed with each other.

The term “C₁-C₆₀ heteroaryl group” as used herein refers to a monovalent group having a heterocyclic aromatic system of 1 to 60 carbon atoms, further including, in addition to carbon atoms, at least one heteroatom, as ring-forming atoms. The term “C₁-C₆₀ heteroarylene group” as used herein refers to a divalent group having a heterocyclic aromatic system of 1 to 60 carbon atoms, further including, in addition to carbon atoms, at least one heteroatom, as ring-forming atoms. Examples of the C₁-C₆₀ heteroaryl group are a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and the like. When the C₁-C₆₀ heteroaryl group and the C₁-C₆₀ heteroarylene group each include two or more rings, the rings may be condensed with each other.

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group are an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as used herein refers to a divalent group having the same structure as the monovalent non-aromatic condensed polycyclic group described above.

The term “monovalent non-aromatic condensed heteropolycyclic group” as used herein refers to a monovalent group (for example, having 1 to 60 carbon atoms) having two or more rings condensed to each other, further including, in addition to carbon atoms, at least one heteroatom, as ring-forming atoms, and having non-aromaticity in its entire molecular structure. Examples of the monovalent non-aromatic condensed heteropolycyclic group are a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and the like. The term “divalent non-aromatic condensed heteropolycyclic group” as used herein refers to a divalent group having the same structure as the monovalent non-aromatic condensed heteropolycyclic group described above.

The term “C₆-C₆₀ aryloxy group” as used herein indicates —OA₁₀₂ (wherein A₁₀₂ is the C₆-C₆₀ aryl group), and the term “C₆-C₆₀ arylthio group” as used herein indicates —SA₁₀₃ (wherein A₁₀₃ is the C₆-C₆₀ aryl group).

The term “C₇-C₆₀ arylalkyl group” used herein refers to —A₁₀₄A₁₀₅ (where A₁₀₄ is a C₁-C₅₄ alkylene group, and A₁₀₅ is a C₆-₅₉ aryl group), and the term “C₂-C₆₀ heteroarylalkyl group” as used herein refers to —A₁₀₆A₁₀₇ (where A₁₀₆ is a C₁-C₅₉ alkylene group, and A₁₀₇ is a C₁-C₅₉ heteroaryl group).

The term “R₁₀ₐ” as used herein may be:

deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q13), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the embodiments described herein, Qi to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group.

The term “heteroatom” as used herein refers to any atom other than a carbon atom. Examples of the heteroatom are O, S, N, P, Si, B, Ge, Se, or any combinations thereof.

“Ph” as used herein refers to a phenyl group, “Me” as used herein refers to a methyl group, “Et” as used herein refers to an ethyl group, “tert-Bu” or “Bu^{t}” as used herein refers to a tert-butyl group, and “OMe” as used herein refers to a methoxy group.

The term “biphenyl group” as used herein refers to “a phenyl group substituted with a phenyl group.” In other words, the “biphenyl group” is a substituted phenyl group having a C₆-C₆₀ aryl group as a substituent.

The term “terphenyl group” as used herein refers to “a phenyl group substituted with a biphenyl group.” In other words, the “terphenyl group” is a substituted phenyl group having, as a substituent, a C₆-C₆₀ aryl group substituted with a C₆-C₆₀ aryl group.

* and *′ as used herein, unless defined otherwise, each refer to a binding site to a neighboring atom in a corresponding formula or moiety.

Hereinafter, compounds according to embodiments and light-emitting devices according to embodiments will be described in detail with reference to the following synthesis examples and examples. The wording “B was used instead of A” used in describing Synthesis Examples denotes that an identical molar equivalent of B was used in place of A.

### EXAMPLES

Preparation of ink composition

Ink compositions were prepared in the following configurations shown in Table 1.

TABLE 1

| Ink | | | |
|---|---|---|---|
| composition | Solute | Solvent | Amount of solute |
| ETL-1 | ZnO | Ethanol | 3.0 wt % |
| ETL-2 | ZnMgO | Ethanol | 3.0 wt % |
| HTL-1 | Compound 1-1 | Cyclohexylbenzene | 2.5 wt % |
| HTL-2 | Compound 1-3 | Cyclohexylbenzene | 2.5 wt % |
| HTL-3 | Compound 1-6 | Cyclohexylbenzene | 2.5 wt % |
| | Compound 2-1 | | (5 wt % of |
| | | | Compound 2-1 based |
| | | | on Compound 1-6) |
| HTL-4 | Compound 1-6 | Cyclohexylbenzene | 2.5 wt % |
| | Compound 2-2 | | (5 wt % of |
| | | | Compound 2-2 based |
| | | | on Compound 1-6) |
| HTL-5 | Compound 5-1 | Cyclohexylbenzene | 2.5 wt % |
| HTL-6 | Compound A | Cyclohexylbenzene | 2.5 wt % |
| HTL-7 | Compound | Cyclohexylbenzene | 2.5 wt % |
| | PTC-U | | |
| B EML-1 | H125 | Methyl benzoate | 3 wt % |
| | FD37 | | (3 wt % of FD37 |
| | | | based on H125) |
| B EML-2 | H125 | Methyl benzoate | 3 wt % |
| | FD38 | | (3 wt % of FD38 |
| | | | based on H125) |
| B EML-3 | H126 | Methyl benzoate | 3 wt % |
| | FD37 | | (3 wt % of FD37 |
| | | | based on H126) |
| B EML-4 | H126 | Methyl benzoate | 3 wt % |
| | FD38 | | (FD38 based on |
| | | | H126) |
| R EML-1 | InP quantum | Octane | 1 wt % |
| | dots | | |

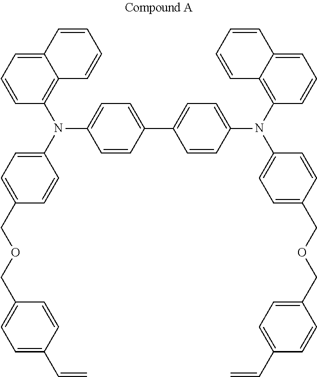 [SMILES: C=Cc1ccc(COCc2ccc(N(c3ccc(-c4ccc(N(c5ccc(COCc6ccc(C=C)cc6)cc5)c5cccc6ccccc56)cc4)cc3)c3cccc4ccccc34)cc2)cc1]

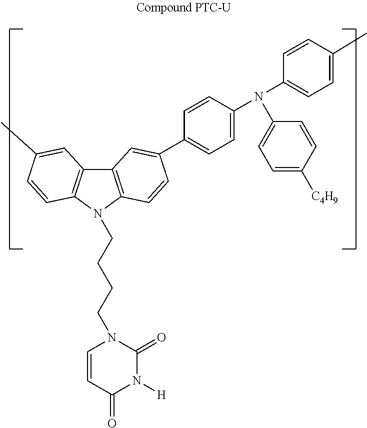

### Preparation Example 1-1

A glass substrate (50 mm×50 mm) was spin-coated with HTL-1 to form a film having a thickness of 100 nm, and a baking process was performed thereon at 150° C. for 10 minutes.

### Preparation Examples 1-2 to 1-5 and Comparative Preparation Examples 1-1 and 1-2

Films were respectively prepared in the same manner as in Preparation Example 1-1, except that ink compositions shown in Table 3 were respectively used instead of HTL-1.

### Preparation Example 2-1

A glass substrate (50 mm×50 mm) was spin-coated with HTL-3 to form a film having a thickness of 100 nm, and the film was irradiated with UV (80 mJ/cm²) having a wavelength of 254 nm. Then, a baking process was performed thereon at 150° C. for 10 minutes.

### Preparation Examples 2-2 and 2-3 and Comparative Preparation Example 2-1

Films were respectively prepared in the same manner as in Preparation Example 1-1, except that ink compositions shown in Table 3 were respectively used instead of HTL-3.

### Evaluation Example 1

The difference in UV absorbance of the films of Preparation Examples 1-1 to 1- 5 and 2-1 to 2-3 and Comparative Preparation Examples 1-1, 1-2, and 2-1 was calculated as methods described in Table 2, and the calculation results are shown in Table 3.

Table 2

1. Determination of UV absorbance of HTL: Coat more than 100 sheets in total, and measure an UV absorbance spectrum at the center of a single-layered HTL film, wherein the absorbance of the UV abs. max was set to 100 (initial state).

2. Solvent drop: Drop 50 mg of a solvent at the center of the single-layered HTL film using a syringe.

3. Leave: Leave the resultant single-layered HTL single film (for 30 min.) under the condition that the solvent drop in the hood does not move or flow.

4. Solvent removal: Remove the solvent using a microfiber wiper made of PET having a fiber diameter of 20 um or less (wiper leaving time: 10 sec.).

5. Baking: Perform baking at the actual measurement temperature of the hot plate at 140° C. for 15 min.

6. UV absorbance measurement: Measure the difference in the absorbance of the UV abs. λmax, and record the relative absorbance in % when the initial absorbance is set to 100 (for example, when the initial absorbance is 10 and the absorbance after treatment is 9, the difference in UV absorbance is calculated as 90%).

TABLE 3

| | | Difference in UV |
|---|---|---|
| Film | HTL | absorbance (%) |
| Preparation | HTL-1 | 99 |
| Example1-1 | | |
| Preparation | HTL-2 | 98 |
| Example 1-2 | | |
| Preparation | HTL-3 | 100 |
| Example 1-3 | | |
| Preparation | HTL-4 | 97 |
| Example 1-4 | | |
| Preparation | HTL-5 | 98 |
| Example 1-5 | | |
| Preparation | HTL-3 | 98 |
| Example 2-1 | | |
| Preparation | HTL-4 | 98 |
| Example 2-2 | | |
| Preparation | HTL-5 | 97 |
| Example 2-3 | | |
| Comparative | HTL-6 | 15 |
| Preparation | | |
| Example 1-1 | | |
| Comparative | HTL-7 | 85 |
| Preparation | | |
| Example 1-2 | | |
| Comparative | HTL-6 | 18 |
| Preparation | | |
| Example 2-1 | | |

Referring to Table 3, it was confirmed that the films of Preparation Examples 1-1 to 1-5 and 2-1 to 2-3 showed greater differences in the UV absorbance than the films of Comparative Preparation Examples 1-1, 1-2, and 2-1.

### Example 1-1

An ITO glass substrate (50 mm×50 mm, 15 Ω/cm², Samsung-Corning Company) was sequentially sonicated using distilled water and isopropanol, and cleaned by exposure to UV ozone for 30 minutes. Following the cleaning, the glass substrate with a transparent electrode line attached thereon was spin-coated with ETL-1 to form a film having a thickness of 60 nm. Then, a baking process was performed thereon at 120° C. for 10 minutes to form an electron injection layer and an electron transport layer. The electron injection layer and the electron transport layer were spin-coated with B EML-1 to form a film having a thickness of 30 nm, and a baking process was performed thereon at 140° C. for 10 minutes to form a blue emission layer. The blue emission layer was spin-coated with HTL-1 to form a film having a thickness of 20 nm, and a baking process was performed thereon at 150° C. for 10 minutes to form a hole transport layer. The hole transport layer was spin-coated with PEDOT:PSS (Clevios™ HIL8) to form a film having a thickness of 20 nm, and a backing process was performed thereon at 120° C. for 30 minutes to form a hole injection layer. After the resultant glass substrate was mounted on a substrate holder of a vacuum deposition apparatus, Al was deposited on the hole injection layer to form an anode having a thickness of 100 nm, thereby completing the manufacture of a light-emitting device. The deposition equipment used herein was a Suicel plus 200 evaporator manufactured by Sunic System Company.

### Examples 1-2 to 1-7 and Comparative Examples 1-1 and 1-2

Films were respectively prepared in the same manner as in Example 1-1, except that ink compositions shown in Table 4 were respectively used instead of ETL-1, B EML-1, or HTL-1.

### Example 2-1

An ITO glass substrate (50 mm×50 mm, 15 Ω/cm², Samsung-Corning Company) was sequentially sonicated using distilled water and isopropanol, and cleaned by exposure to UV ozone for 30 minutes. Following the cleaning, the glass substrate with a transparent electrode line attached thereon was spin-coated with ETL-1 to form a film having a thickness of 60 nm. Then, a baking process was performed thereon at 120° C. for 10 minutes to form an electron injection layer and an electron transport layer. The electron injection layer and the electron transport layer were spin-coated with B EML-1 to form a film having a thickness of 30 nm, and a baking process was performed thereon at 140° C. for 10 minutes to form a blue emission layer. The blue emission layer was spin-coated with HTL-3 to form a film having a thickness of 20 nm, and the film was irradiated with UV light (80 mJ/cm²) having a wavelength of 254 nm. Then, a baking process was performed thereon at 150° C. for 10 minutes to form a hole transport layer. The hole transport layer was spin-coated with PEDOT:PSS (Clevious™ HIL8) to form a film having a thickness of 20 nm, and a backing process was performed thereon at 120° C. for 30 minutes to form a hole injection layer. After the resultant glass substrate was mounted on a substrate holder of a vacuum deposition apparatus, Al was deposited on the hole injection layer to form an anode having a thickness of 100 nm, thereby completing the manufacture of a light-emitting device. The deposition equipment used herein was a Suicel plus 200 evaporator manufactured by Sunic System Company.

### Examples 2-2 to 2-5 and Comparative Example 2-1

Films were respectively prepared in the same manner as in Example 2-1, except that ink compositions shown in Table 4 were respectively used instead of ETL-1, B EML-1, or HTL-1.

### Example 3-1

An ITO glass substrate (50 mm×50 mm, 15 Ω/cm², Samsung-Corning Company) was sequentially sonicated using distilled water and isopropanol, and cleaned by exposure to UV ozone for 30 minutes. Following the cleaning, the glass substrate with a transparent electrode line attached thereon was spin-coated with ETL-1 to form a film having a thickness of 60 nm. Then, a baking process was performed thereon at 120° C. for 10 minutes to form an electron injection layer and an electron transport layer. The electron injection layer and the electron transport layer were spin-coated with B EML-1 to form a film having a thickness of 30 nm, and a baking process was performed thereon at 140° C. for 10 minutes to form a blue emission layer. The blue emission layer was spin-coated with HTL-1 to form a film having a thickness of 20 nm, and a baking process was performed thereon at 150° C. for 10 minutes to form a hole transport layer. The hole transport layer was spin-coated with PEDOT:PSS (Clevios™ HIL8) to form a film having a thickness of 20 nm, and a backing process was performed thereon at 120° C. for 30 minutes to form a hole injection layer. The hole injection layer was spin-coated with ETL-1 to form a film having a thickness of 60 nm, and a baking process was performed thereon at 120° C. for 10 minutes to form an electron injection layer and an electron transport layer. The electron injection layer and the electron transport layer were spin-coated with B EML-1 to form a film having a thickness of 30 nm, and a baking process was performed thereon at 140° C. for 10 minutes to form a blue emission layer. The blue emission layer was spin-coated with HTL-1 to form a film having a thickness of 20 nm, and a baking process was performed thereon at 150° C. for 10 minutes to form a hole transport layer. The hole transport layer was spin-coated with PEDOT:PSS (Clevios™ HIL8) to form a film having a thickness of 20 nm, and a backing process was performed thereon at 120° C. for 30 minutes to form a hole injection layer. After the resultant glass substrate was mounted on a substrate holder of a vacuum deposition apparatus, Al was deposited on the hole injection layer to form an anode having a thickness of 100 nm, thereby completing the manufacture of a light-emitting device. The deposition equipment used herein was a Suicel plus 200 evaporator manufactured by Sunic System Company.

### Examples 3-2 to 3-7 and Comparative Example 3-1

Films were respectively prepared in the same manner as in Example 3-1, except that ink compositions shown in Table 4 were respectively used instead of ETL-1, B EML-1, or

HTL-1.

TABLE 4

| | ETL | B EML | HTL |
|---|---|---|---|
| Example 1-1 | ETL-1 | B EML-1 | HTL-1 |
| Example 1-2 | ETL-2 | B EML-1 | HTL-1 |
| Example 1-3 | ETL-2 | B EML-2 | HTL-1 |
| Example 1-4 | ETL-2 | B EML-1 | HTL-2 |
| Example 1-5 | ETL-2 | B EML-1 | HTL-3 |
| Example 1-6 | ETL-2 | B EML-1 | HTL-4 |
| Example 1-7 | ETL-2 | B EML-1 | HTL-5 |
| Example 2-1 | ETL-1 | B EML-1 | HTL-3 |
| Example 2-2 | ETL-2 | B EML-1 | HTL-3 |
| Example 2-3 | ETL-2 | B EML-2 | HTL-3 |
| Example 2-4 | ETL-2 | B EML-1 | HTL-4 |
| Example 2-5 | ETL-2 | B EML-1 | HTL-5 |
| Example 3-1 | ETL-1 | B EML-1 | HTL-1 |
| Example 3-2 | ETL-2 | B EML-1 | HTL-1 |
| Example 3-3 | ETL-2 | B EML-2 | HTL-1 |
| Example 3-4 | ETL-2 | B EML-1 | HTL-2 |
| Example 3-5 | ETL-2 | B EML-1 | HTL-3 |
| Example 3-6 | ETL-2 | B EML-1 | HTL-4 |
| Example 3-7 | ETL-2 | B EML-1 | HTL-5 |
| Comparative | ETL-2 | B EML-1 | HTL-6 |
| Example 1-1 | | | |
| Comparative | ETL-2 | B EML-1 | HTL-7 |
| Example 1-2 | | | |
| Comparative | ETL-2 | B EML-1 | HTL-6 |
| Example 2-1 | | | |
| Comparative | ETL-2 | B EML-1 | HTL-6 |
| Example 3-1 | | | |

### Evaluation Example 2

Regarding the light-emitting devices of Examples 1-1 to 1-7, 2-1 to 2-5 and 3-1 to 3-7 and Comparative Examples 1-1, 1-2, 2-1, and 3-1, the driving voltage, efficiency, and color purity were measured according to the following methods, and results are shown in Table 5. Lifespan (T₉₅) represents the time (hr) it takes for the luminance to reach 95% when the initial luminance (at 10 mA/cm²) is 100%.

Color coordinates: Power was supplied from a current-voltmeter (Kethley SMU 236), and color coordinates were measured using a luminance meter PR650.

Luminance: Power was supplied from a current-voltmeter (Kethley SMU 236), and luminance was measured using a luminance meter PR650.

Efficiency: Power was supplied from a current-voltmeter (Kethley SMU 236), and efficiency was measured using a luminance meter PR650.

TABLE 5

| | Driving | | | | Lifespan |
|---|---|---|---|---|---|
| | voltage | Efficiency | Color coordinates | | (T₉₅) |
| | [symbol] | [cd/A] | CIEx | CIEy | [hr] |
| Example 1-1 | 4.3 | 5.0 | 0.15 | 0.11 | 150 |
| Example 1-2 | 4.6 | 5.2 | 0.15 | 0.11 | 150 |
| Example 1-3 | 4.8 | 5.4 | 0.15 | 0.11 | 140 |
| Example 1-4 | 4.2 | 6.0 | 0.15 | 0.11 | 180 |
| Example 1-5 | 4.4 | 6.2 | 0.15 | 0.12 | 130 |
| Example 1-6 | 4.5 | 5.2 | 0.15 | 0.11 | 140 |
| Example 1-7 | 4.4 | 5.5 | 0.15 | 0.12 | 160 |
| Example 2-1 | 4.5 | 5.3 | 0.15 | 0.10 | 160 |
| Example 2-2 | 4.4 | 5.9 | 0.15 | 0.11 | 140 |
| Example 2-3 | 4.5 | 6.2 | 0.15 | 0.11 | 160 |
| Example 2-4 | 4.7 | 6.3 | 0.14 | 0.11 | 180 |
| Example 2-5 | 4.5 | 6.0 | 0.14 | 0.12 | 150 |
| Example 3-1 | 10.2 | 11.2 | 0.15 | 0.11 | 380 |
| Example 3-2 | 10.4 | 10.6 | 0.15 | 0.11 | 350 |
| Example 3-3 | 10.3 | 12.0 | 0.14 | 0.11 | 380 |
| Example 3-4 | 10.8 | 11.5 | 0.15 | 0.11 | 420 |
| Example 3-5 | 10.7 | 11.9 | 0.13 | 0.12 | 350 |
| Example 3-6 | 10.9 | 12.5 | 0.15 | 0.11 | 440 |
| Example 3-7 | 10.4 | 14.5 | 0.15 | 0.11 | 400 |
| Comparative | 3.8 | 0.2 | 0.15 | 0.22 | 10 |
| Example 1-1 | | | | | |
| Comparative | 4.0 | 4.0 | 0.15 | 0.13 | 50 |
| Example 1-2 | | | | | |
| Comparative | 3.5 | 0.1 | 0.15 | 0.25 | 5 |
| Example 2-1 | | | | | |
| Comparative | 7.2 | 0.2 | 0.15 | 0.28 | 5 |
| Example 3-1 | | | | | |

[symbol]

indicates data missing or illegible when filed

Referring to Table 5, it was confirmed that the light-emitting devices of Examples 1-1 to 1-7, 2-1 to 2-5, and 3-1 to 3-7 had excellent luminescence efficiency and lifespan characteristics compared to the light-emitting devices of Comparative Examples 1-1, 1-2, 2-1, and 3-1.

### Example 4-1

An ITO glass substrate (50 mm×50 mm, 15 Ω/cm², Samsung-Corning Company) was sequentially sonicated using distilled water and isopropanol, and cleaned by exposure to UV ozone for 30 minutes. Following the cleaning, the glass substrate with a transparent electrode line attached thereon was spin-coated with ETL-1 to form a film having a thickness of 60 nm. Then, a baking process was performed thereon at 120° C. for 10 minutes to form an electron injection layer and an electron transport layer. The electron injection layer and the electron transport layer were spin-coated with R EML-1 to form a film having a thickness of 30 nm, and a baking process was performed thereon at 100° C. for 10 minutes to form a red emission layer. The red emission layer was spin-coated with HTL-1 to form a film having a thickness of 20 nm, and a baking process was performed thereon at 150° C. for 10 minutes to form a hole transport layer. The hole transport layer was spin-coated with PEDOT:PSS (Clevios™ HIL8) to form a film having a thickness of 20 nm, and a backing process was performed thereon at 120° C. for 30 minutes to form a hole injection layer. After the resultant glass substrate was mounted on a substrate holder of a vacuum deposition apparatus, Al was deposited on the hole injection layer to form an anode having a thickness of 100 nm, thereby completing the manufacture of a light-emitting device. The deposition equipment used herein was a Suicel plus 200 evaporator manufactured by Sunic System Company.

### Examples 4-2 to 4-6 and Comparative Examples 4-1 and 4-2

Films were respectively prepared in the same manner as in Example 4-1, except that ink compositions shown in Table 6 were respectively used instead of ETL-1, R EML-1, or HTL-1.

### Example 5-1

An ITO glass substrate (50 mm×50 mm, 15 Ω/cm², Samsung-Corning Company) was sequentially sonicated using distilled water and isopropanol, and cleaned by exposure to UV ozone for 30 minutes. Following the cleaning, the glass substrate with a transparent electrode line attached thereon was spin-coated with ETL-1 to form a film having a thickness of 60 nm. Then, a baking process was performed thereon at 120° C. for 10 minutes to form an electron injection layer and an electron transport layer. The electron injection layer and the electron transport layer were spin-coated with R EML-1 to form a film having a thickness of 30 nm, and a baking process was performed thereon at 100° C. for 10 minutes to form a red emission layer. The red emission layer was spin-coated with HTL-3 to form a film having a thickness of 20 nm, and the film was irradiated with UV light (80 mJ/cm²) having a wavelength of 254 nm. A baking process was performed thereon at 150° C. for 10 minutes to form a hole transport layer. The hole transport layer was spin-coated with PEDOT:PSS (Clevious™ HIL8) to form a film having a thickness of 20 nm, and a backing process was performed thereon at 120° C. for 30 minutes to form a hole injection layer. After the resultant glass substrate was mounted on a substrate holder of a vacuum deposition apparatus, Al was deposited on the hole injection layer to form an anode having a thickness of 100 nm, thereby completing the manufacture of a light-emitting device. The deposition equipment used herein was a Suicel plus 200 evaporator manufactured by Sunic System Company.

### Examples 5-2 to 5-4 and Comparative Example 5-1

Films were respectively prepared in the same manner as in Example 5-1, except that ink compositions shown in Table 6 were respectively used instead of ETL-1, R EML-1, or HTL-1.

### Example 6-1

An ITO glass substrate (50 mm×50 mm, 15 Ω/cm², Samsung-Corning Company) was sequentially sonicated using distilled water and isopropanol, and cleaned by exposure to UV ozone for 30 minutes. Following the cleaning, the glass substrate with a transparent electrode line attached thereon was spin-coated with ETL-1 to form a film having a thickness of 60 nm. Then, a baking process was performed thereon at 120° C. for 10 minutes to form an electron injection layer and an electron transport layer. The electron injection layer and the electron transport layer were spin-coated with R EML-1 to form a film having a thickness of 30 nm, and a baking process was performed thereon at 100° C. for 10 minutes to form a red emission layer. The red emission layer was spin-coated with HTL-1 to form a film having a thickness of 20 nm, and a baking process was performed thereon at 150° C. for 10 minutes to form a hole transport layer. PEDOT:PSS (Clevious™ HIL8) The hole transport layer was spin-coated with PEDOT:PSS (Clevious™ HIL8) to form a film having a thickness of 20 nm, and a backing process was performed thereon at 120° C. for 30 minutes to form a hole injection layer. The hole injection layer was spin-coated with ETL-1 to form a film having a thickness of 60 nm, and a baking process was performed thereon at 120° C. for 10 minutes to form an electron injection layer and an electron transport layer. The electron injection layer and the electron transport layer were spin-coated with R EML-1 to form a film having a thickness of 30 nm, and a baking process was performed thereon at 100° C. for 10 minutes to form a red emission layer. The red emission layer was spin-coated with HTL-1 to form a film having a thickness of 20 nm, and a baking process was performed thereon at 150° C. for 10 minutes to form a hole transport layer. The hole transport layer was spin-coated with PEDOT:PSS (Clevious™ HIL8) to form a film having a thickness of 20 nm, and a backing process was performed thereon at 120° C. for 30 minutes to form a hole injection layer. After the resultant glass substrate was mounted on a substrate holder of a vacuum deposition apparatus, Al was deposited on the hole injection layer to form an anode having a thickness of 100 nm, thereby completing the manufacture of a light-emitting device. The deposition equipment used herein was a Suicel plus 200 evaporator manufactured by Sunic System Company.

### Examples 6-2 to 6-6 and Comparative Example 6-1

Films were respectively prepared in the same manner as in Example 6-1, except that ink compositions shown in Table 6 were respectively used instead of ETL-1, R EML-1, or HTL-1.

TABLE 6

| | ETL | R EML | HTL |
|---|---|---|---|
| Example 4-1 | ETL-1 | R EML-1 | HTL-1 |
| Example 4-2 | ETL-2 | R EML-1 | HTL-1 |
| Example 4-3 | ETL-2 | R EML-1 | HTL-2 |
| Example 4-4 | ETL-2 | R EML-1 | HTL-3 |
| Example 4-5 | ETL-2 | R EML-1 | HTL-4 |
| Example 4-6 | ETL-2 | R EML-1 | HTL-5 |
| Example 5-1 | ETL-1 | R EML-1 | HTL-3 |
| Example 5-2 | ETL-2 | R EML-1 | HTL-3 |
| Example 5-3 | ETL-2 | R EML-1 | HTL-4 |
| Example 5-4 | ETL-2 | R EML-1 | HTL-5 |
| Example 6-1 | ETL-1 | R EML-1 | HTL-1 |
| Example 6-2 | ETL-2 | R EML-1 | HTL-1 |
| Example 6-3 | ETL-2 | R EML-1 | HTL-2 |
| Example 6-4 | ETL-2 | R EML-1 | HTL-3 |
| Example 6-5 | ETL-2 | R EML-1 | HTL-4 |
| Example 6-6 | ETL-2 | R EML-1 | HTL-5 |
| Comparative | ETL-2 | R EML-1 | HTL-6 |
| Example 4-1 | | | |
| Comparative | ETL-2 | R EML-1 | HTL-7 |
| Example 4-2 | | | |
| Comparative | ETL-2 | R EML-1 | HTL-6 |
| Example 5-1 | | | |
| Comparative | ETL-2 | R EML-1 | HTL-6 |
| Example 6-1 | | | |

### Evaluation Example 3

Regarding the light-emitting devices of Examples 4-1 to 4-6, 5-1 to 5-4, and 6-1 to 6-6 and Comparative Examples 4-1, 4-2, 5-1, and 6-1, the driving voltage, efficiency, and color purity were measured according to the following methods, and results are shown in Table 7. Lifespan (T₉₅) represents the time (hr) it takes for the luminance to reach 95% when the initial luminance (at 10 mA/cm²) is 100%.

Color coordinates: Power was supplied from a current-voltmeter (Kethley SMU 236), and color coordinates were measured using a luminance meter PR650.

Luminance: Power was supplied from a current-voltmeter (Kethley SMU 236), and luminance was measured using a luminance meter PR650.

Efficiency: Power was supplied from a current-voltmeter (Kethley SMU 236), and efficiency was measured using a luminance meter PR650.

TABLE 7

| | Driving | | | | Lifespan |
|---|---|---|---|---|---|
| | voltage | Efficiency | Color coordinates | | (T₉₀) |
| | [symbol] | [cd/A] | CIEx | CIEy | [hr] |
| Example 4-1 | 3.4 | 10.2 | 0.68 | 0.32 | 150 |
| Example 4-2 | 3.5 | 10.5 | 0.68 | 0.32 | 150 |
| Example 4-3 | 3.8 | 10.8 | 0.68 | 0.32 | 150 |
| Example 4-4 | 3.3 | 9.5 | 0.68 | 0.32 | 150 |
| Example 4-5 | 3.4 | 10.2 | 0.68 | 0.32 | 160 |
| Example 4-6 | 3.3 | 10.5 | 0.68 | 0.32 | 150 |
| Example 5-1 | 3.5 | 10.5 | 0.68 | 0.32 | 180 |
| Example 5-2 | 3.4 | 10.4 | 0.68 | 0.32 | 150 |
| Example 5-3 | 3.7 | 10.8 | 0.68 | 0.32 | 140 |
| Example 5-4 | 3.4 | 10.5 | 0.68 | 0.32 | 150 |
| Example 6-1 | 7.4 | 18.5 | 0.68 | 0.32 | 330 |
| Example 6-2 | 7.4 | 19.8 | 0.68 | 0.32 | 320 |
| Example 6-3 | 7.5 | 19.2 | 0.68 | 0.32 | 300 |
| Example 6-4 | 7.9 | 18.5 | 0.68 | 0.32 | 320 |
| Example 6-5 | 7.8 | 20.1 | 0.68 | 0.32 | 320 |
| Example 6-6 | 7.8 | 20.5 | 0.68 | 0.32 | 300 |
| Comparative | 2.8 | 0.2 | 0.65 | 0.36 | 10 |
| Example 4-1 | | | | | |
| Comparative | 3.2 | 4.8 | 0.66 | 0.34 | 60 |
| Example 4-2 | | | | | |
| Comparative | 3.0 | 0.1 | 0.64 | 0.36 | 5 |
| Example 5-1 | | | | | |
| Comparative | 5.8 | 0.2 | 0.65 | 0.36 | 10 |
| Example 6-1 | | | | | |

[symbol]

indicates data missing or illegible when filed

Referring to Table 7, it was confirmed that the light-emitting devices of Examples 4-1 to 4-6, 5-1 to 5-4, and 6-1 to 6-6 had excellent luminescence efficiency and lifespan characteristics compared to the light-emitting devices of Comparative Examples 4-1, 4-2, 5-1, and 6-1.

According to the one or more embodiments, a light-emitting device may have high efficiency and a long lifespan, and thus may be used for the manufacture of a high-quality electronic apparatus.

Although certain embodiments and implementations have been described herein, other embodiments and modifications will be apparent from this description.

Accordingly, the inventive concepts are not limited to such embodiments, but rather to the broader scope of the appended claims and various obvious modifications and equivalent arrangements as would be apparent to a person of ordinary skill in the art.

What is claimed is:

1. A light-emitting device comprising:
a substrate;
a cathode disposed on the substrate;
an anode facing the cathode; and
an organic layer arranged between the cathode and the anode and comprising an emission layer,
wherein the organic layer comprises:
an electron transport region arranged between the emission layer and the cathode; and
a hole transport region arranged between the emission layer and the anode,
wherein the hole transport region comprises a first compound comprising a first repeating unit represented by Formula 1, a second compound represented by Formula 2, a fifth compound represented by Formula 5, or any combination thereof: 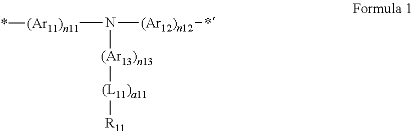 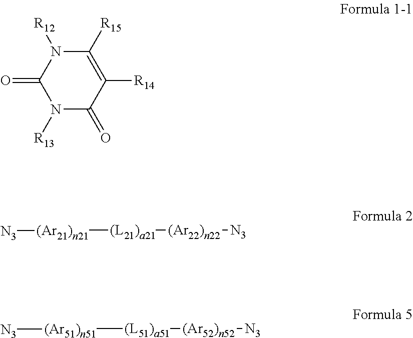
wherein, in Formulas 1, 1-1, 2, and 5,
Ar₁₁ to Ar₁₃, Ar₂₁, Ar₂₂, Ar₅₁and Ar₅₂, are each independently a single bond, a C₁-C₆₀ alkylene group unsubstituted or substituted with at least one R₁₀ₐ, a C₂-C₆₀ alkenylene group unsubstituted or substituted with at least one R₁₀ₐ, a C₂-C₆₀ alkynylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
n11 to n13, n21, n22, n51, and n52 are each independently an integer from 1 to 10,
L₁₁ and L₂₁ are each independently a single bond, *—C(R₁ₐ)(R_{1b})—*′, *—C(R₁ₐ)═*′, *═C(R₁ₐ)—*′, *—C(R₁ₐ)═C(R_{1b})—*′, *—C(═O)—*′, *—C(═S)—*′, *—C≡C—*′, *—B(R₁ₐ)—*′, *—N(R₁ₐ)—*′, *—O—*′, *—Si(R₁ₐ)(R_{1b})—*′, *—P(═O)(R₁ₐ)—*′, *—S—*′, *—S(═O)—*′, *—S(═O)₂—*′, or *—Ge(R₁ₐ)(R_{1b})—*′,
L₅₁ is the first repeating unit represented by Formula 1,
a11, a21, and a51 are each independently an integer from 1 to 20,
R₁₁ is a group represented by Formula 1-1, a C₃-C₆₀ carbocyclic group unsubstituted or substituted with at least one R₁₀ₐ, or a C₁-C₆₀ heterocyclic group unsubstituted or substituted with at least one R₁₀ₐ,
i) R₁₂ is a binding site to a neighboring atom in Formula 1, and R₁₃ is hydrogen, or ii) R₁₂ is hydrogen, and R₁₃ is a binding site to a neighboring atom in Formula 1,
R₁₄, R₁₅, R₁ₐ, and R_{1b} are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₁-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
* and *′ each indicate a binding site to a neighboring atom,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q13), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

2. The light-emitting device of claim 1, wherein Ar₁₁ to AR₁₃ are each independently:
a single bond, phenylene, naphthalene, or fluorene; or
phenylene, naphthalene, or fluorene, each substituted with deuterium, a C₁-C₁₀ alkyl group, a phenyl group, or any combination thereof.

3. The light-emitting device of claim 1, wherein Ar₂₁ and Ar₂₂ are each independently:
phenylene or naphthalene; or
phenylene or naphthalene, each substituted with deuterium, —F, or a C₁-C₁₀ alkyl group.

4. The light-emitting device of claim 1, wherein Ar₁₁ to Ar₁₃ are each independently a single bond or a group represented by one of Formulas 1A-1 to 1A-14 and 1B-1 to 1B-10: 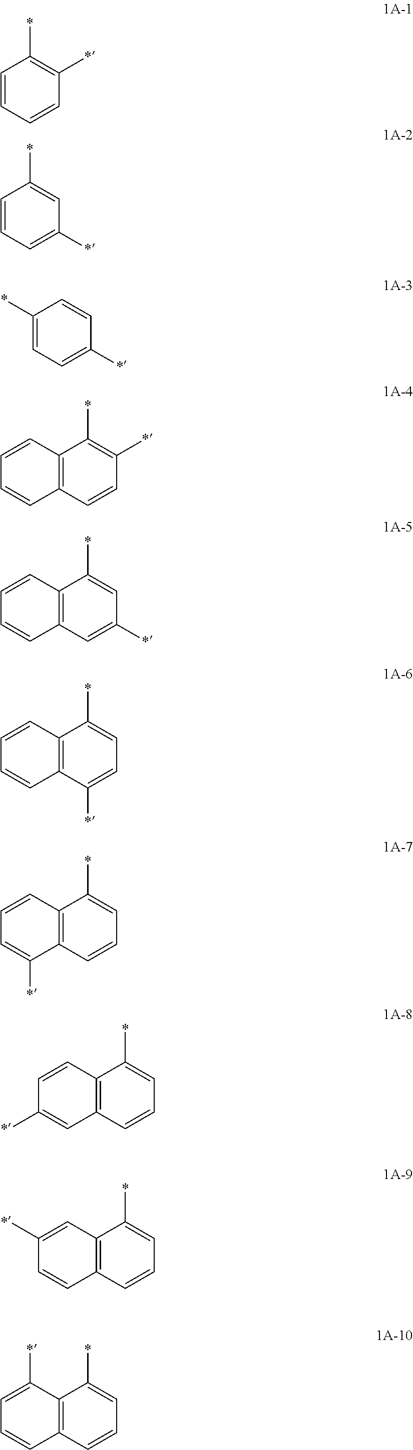 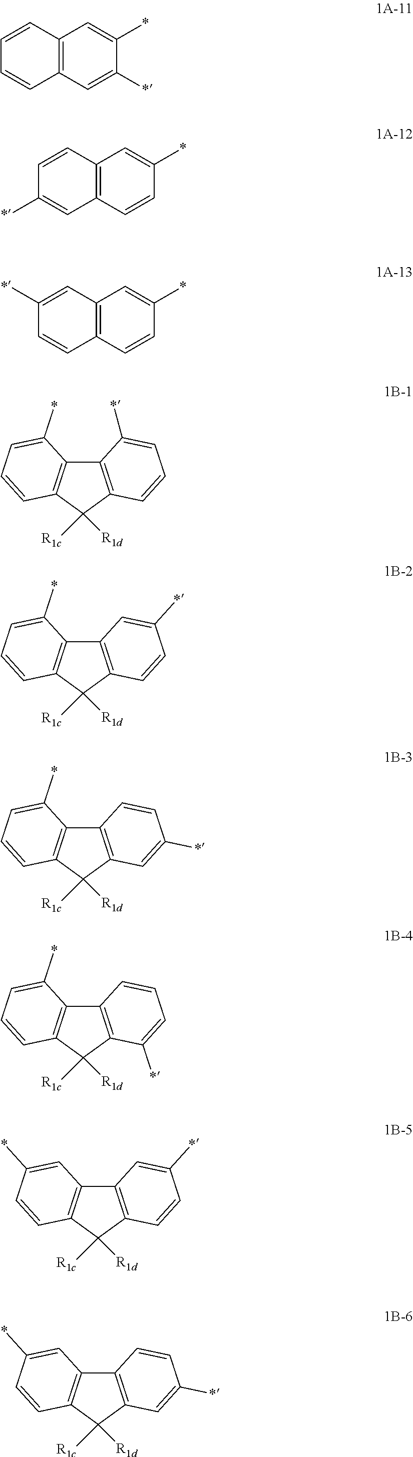 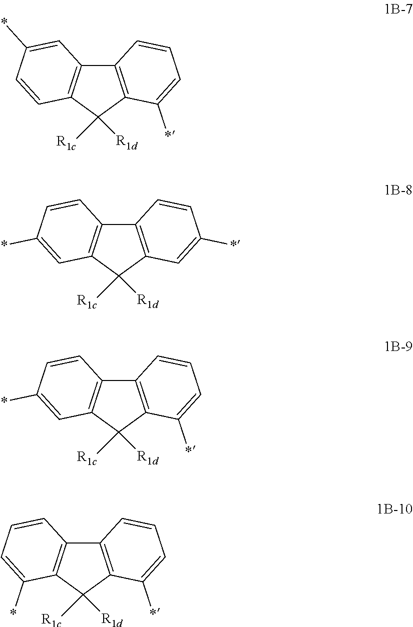
wherein, in Formulas 1A-1 to 1A-13 and 1B-1 to 1B-10,
R_{1c} and R_{1d} are each independently hydrogen, deuterium, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ group unsubstituted or substituted with at least one R₁₀ₐ,
* and *′ each indicate a binding site to a neighboring atom, and
R₁₀ₐ is as described in claim 1.

5. The light-emitting device of claim 1, wherein Ar₂₁ and Ar₂₂ are each
independently a group represented by one of Formulas 2A-1 to 2A-13: 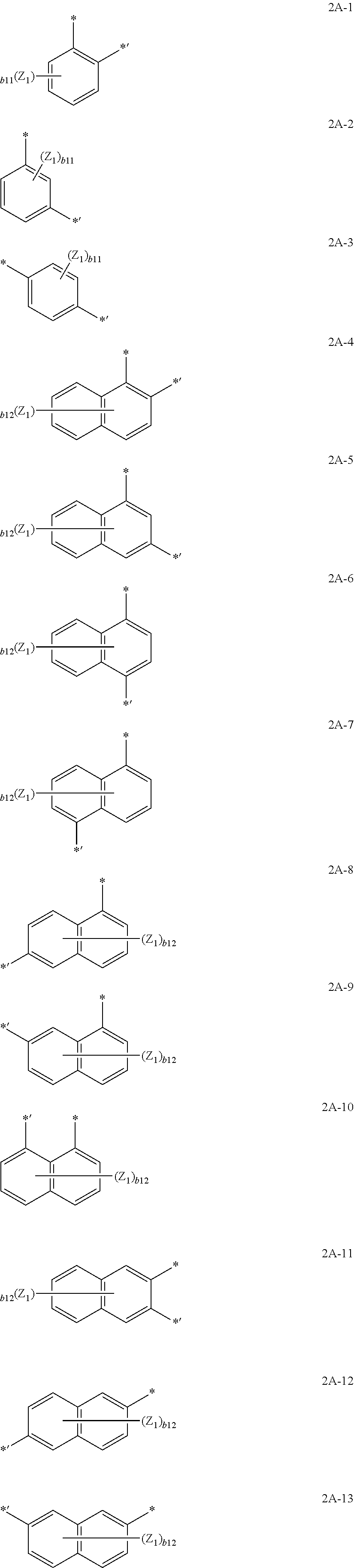
wherein, in Formulas 2A-1 to 2A-13,
Z₁ is hydrogen, deuterium, —F, —Cl, —Br, —I, a hydroxyl group, a cyano group, or a nitro group,
b 11 is an integer from 1 to 4,
b 12 is an integer from 1 to 6, and
* and *′ each indicate a binding site to a neighboring atom.

6. The light-emitting device of claim 1, wherein a moiety represented by (L₁₁)ₐ₁₁ in Formula 1 is a group represented by Formula 1L: 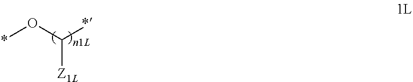
wherein, in Formula 1L,
n1L is an integer from 0 to 10,
Z_{1L} is hydrogen, deuterium, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, or a C₁-C₆₀ arylthio group unsubstituted or substituted with at least one R₁₀ₐ, and
R₁₀ₐ is as described in claim 1.

7. The light-emitting device of claim 1, wherein L₂₁ is a single bond, *—C(R₁ₐ)(R_{1b})—*′, *—C(R₁ₐ)═*′, *═C(R₁ₐ)—*′, *—C(R₁ₐ)═C(R_{1b})—*′, *—C(═O)—*′, or *—O—*′,
* and *′ each indicate a binding site to a neighboring atom, and
R₁ₐ and R_{1b} are respectively as described in claim 1.

8. The light-emitting device of claim 1, wherein R₁₁ is the group represented by Formula 1-1.

9. The light-emitting device of claim 1, wherein R₁₄, R₁₅, R₁ₐ, and R_{1b} are each independently:
hydrogen, deuterium, —F, —Cl, —Br, —I, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a C₁-C₂₀ alkyl group, or any combination thereof;
a phenyl group or a naphthyl group, each unsubstituted or substituted with deuterium, —F, —Cl, —Br, —I, —CD₃, —CD₂H, —CDH₂, —CF₃, —CF₂H, —CFH₂, a C₁-C₂₀ alkyl group, a C₁-C₂₀ alkoxy group, or any combination thereof.

10. The light-emitting device of claim 1, wherein the electron transport region comprises a third compound represented by Formula 3:
MₚO_{q} Formula 3
wherein, in Formula 3,
M is Zn, Ti, Zr, Sn, W, Ta, Ni, Mo, Cu, or V, and
p and q are each independently an integer from 1 to 5.

11. The light-emitting device of claim 10, wherein the third compound is represented by Formula 3-1:
Zn₍₁₋ᵣ₎M′ᵣO Formula 3-1
wherein, in Formula 3-1,
M′ is Mg, Co, Ni, Zr, Mn, Sn, Y, Al, or any combination thereof, and
r is a number greater than 0 and equal to or less than 0.5.

12. A light-emitting device comprising:
a substrate;
a cathode disposed on the substrate;
an anode facing the cathode;
x emitting units arranged between the cathode and the anode; and
x−1 charge generation layers, each arranged between two neighboring emitting units among the x emitting units and comprising an n-type charge generation layer and a p-type charge generation layer,
wherein x is an integer of 2 or more,
each of the x emitting units comprises an electron transport region, an emission layer, and a hole transport region that are sequentially arranged from the cathode, and
the hole transport region comprises a first compound comprising a first repeating unit represented by Formula 1, a second compound represented by Formula 2, a fifth compound represented by Formula 5, or any combination thereof: 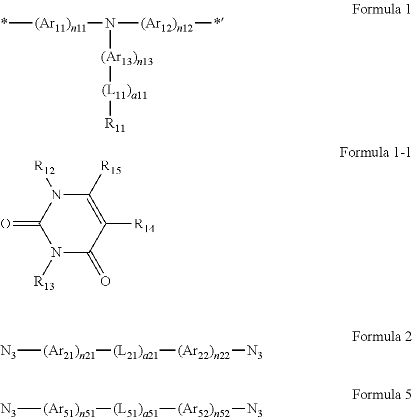
wherein, in Formulas 1, 1-1, 2, and 5,
Ar11 to Ar₁₃, Ar₂₁, Ar₅₁, and Ar₅₂, are each independently a single bond, a C₁-C₆₀ alkylene group unsubstituted or substituted with at least one R₁₀ₐ, a C₂-C₆₀ alkenylene group unsubstituted or substituted with at least one R₁₀ₐ, a C₂-C₆₀ alkynylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
n11 to n13, n21, n22, n51, and n52 are each independently an integer from 1 to 10,
L₁₁ and L₂₁ are each independently a single bond, *—C(R₁ₐ)(R_{1b})—*′, *—C(R₁ₐ)═*′, *═C(R₁ₐ)—*′, *—C(R₁ₐ)═C(R_{1b})—*′, *—C(═O)—*′, *—C(═S)—*′, *—C≡C—*′, *—B(R₁ₐ)—*′, *—N(R₁ₐ)—*′, *—O—*′, *—Si(R₁ₐ)(R_{1b})—*′, *—P(═O)(R₁ₐ)—*′, *—S—*′, *—S(═O)—*′, *—S(═O)₂—*′, or *—Ge(R₁ₐ)(R_{1b})—*′,
L₅₁ is the first repeating unit represented by Formula 1,
a11, a21, and a51 are each independently an integer from 1 to 20,
R₁₁ is a group represented by Formula 1-1, a C₃-C₆₀ carbocyclic group unsubstituted or substituted with at least one R₁₀ₐ, or a C₁-C₆₀ heterocyclic group unsubstituted or substituted with at least one R₁₀ₐ,
i) R₁₂ is a binding site to a neighboring atom in Formula 1, and R₁₃ is hydrogen, or ii) R₁₂ is hydrogen, and R₁₃ is a binding site to a neighboring atom in Formula 1,
R₁₄, R₁₅, R₁ₐ, and R_{1b} are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₁-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
* and *′ each indicate a binding site to a neighboring atom,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q13), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), group, a C₆-C₆₀ aryloxy group, a C₆-C₆₀ arylthio group, —Si(Q₂₁)(Q₂₂)(Q₂₃), —N(Q₂₁)(Q₂₂),
13 Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, deuterium, —F, a cyano group, a C₁-C₆₀ alkyl group, a C₁-C₆₀ alkoxy group, a phenyl group, a biphenyl group, or any combination thereof.

13. The light-emitting device of claim 12, wherein x is 2 or 3.

14. The light-emitting device of claim 12, wherein each of the x−1 charge generation layers comprises a hole-transporting material.

15. The light-emitting device of claim 12, wherein each of the x−1 charge generation layers comprises a fourth compound represented by Formula 4: 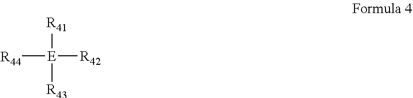
wherein, in Formula 4,
E is boron (B), Al, Ga, In, or Tl,
R₄₁ to R₄₄ are each independently a C₃-C₆₀ carbocyclic group unsubstituted or substituted with at least one R₁₀ₐ or a C₁-C₆₀ heterocyclic group unsubstituted or substituted with at least one R₁₀ₐ,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q13), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

16. A method of manufacturing a light-emitting device, the method comprising:
forming a cathode on a substrate;
forming a first organic layer between the cathode and an anode;
forming a second organic layer between the anode and the first organic layer; and
forming a third organic layer between the second organic layer and the anode,
wherein the forming of the third organic layer is performed by a solution process using a composition including a first compound including a first repeating unit represented by Formula 1, a second compound represented by Formula 2, a fifth compound represented by Formula 5, or any combination thereof: 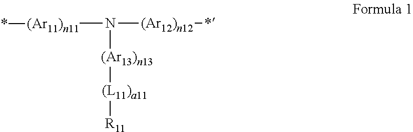 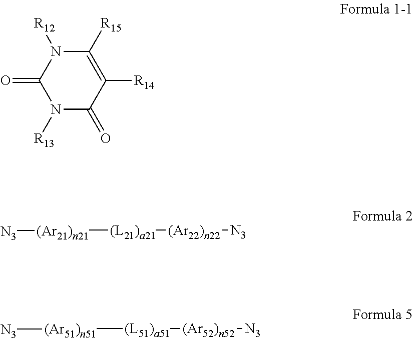
wherein, in Formulas 1, 1-1, 2, and 5,
Ar₁₁ to Ar₁₃, Ar₂₁, Ar₂₂, Ar₅₁and Ar₅₂, are each independently a single bond, a C₁-C₆₀ alkylene group unsubstituted or substituted with at least one R₁₀ₐ, a C₂-C₆₀ alkenylene group unsubstituted or substituted with at least one R₁₀ₐ, a C₂-C₆₀ alkynylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
n11 to n13, n21, n22, n51, and n52 are each independently an integer from 1 to 10,
L₁₁ and L₂₁ are each independently a single bond, *—C(R₁ₐ)(R_{1b})—*′, *—C(R₁ₐ)═*′, *═C(R₁ₐ)—*′, *—C(R₁ₐ)═C(R_{1b})—*′, *—C(═O)—*′, *—C(═S)—*′, *—C≡C—*′, *—B(R₁ₐ)—*′, *—N(R₁ₐ)—*′, *—O—*′, *—Si(R₁ₐ)(R_{1b})—*′, *—P(═O)(R₁ₐ)—*′, *—S—*′, *—S(═O)—*′, *—S(═O)₂—*′, or *—Ge(R₁ₐ)(R_{1b})—*′,
L₅₁ is the first repeating unit represented by Formula 1,
a11, a21, and a51 are each independently an integer from 1 to 20,
R₁₁ is a group represented by Formula 1-1, a C₃-C₆₀ carbocyclic group unsubstituted or substituted with at least one R₁₀ₐ, or a C₁-C₆₀ heterocyclic group unsubstituted or substituted with at least one R₁₀ₐ,
i) R₁₂ is a binding site to a neighboring atom in Formula 1, and R₁₃ is hydrogen, or ii) R₁₂ is hydrogen, and R₁₃ is a binding site to a neighboring atom in Formula 1,
R₁₄, R₁₅, R₁ₐ, and R_{1b} are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₁-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
* and *′ each indicate a binding site to a neighboring atom,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q13), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

17. The method of claim 16, wherein the forming of the first organic layer is performed by a solution process using a composition including a third compound represented by Formula 3:
MₚO_{q} Formula 3
wherein, in Formula 3,
M is Zn, Ti, Zr, Sn, W, Ta, Ni, Mo, Cu, or V, and
p and q are each independently an integer from 1 to 5.

18. The method of claim 16, wherein the forming of the first organic layer, the forming of the second organic layer, and the forming of the third organic layer each comprise evaporating a solvent.

19. The method of claim 18, wherein the evaporating of the solvent is performed at a temperature in a range of about 110° C. to about 180° C.

20. The method of claim 18, wherein the method further comprises irradiating the composition with UV before the evaporating of the solvent.
